(19) United States
(12) Patent Application Publication
(10) Pub. No.: US 2026/0277802 A1
(43) Pub. Date: Sep. 17, 2026

(54) Dynamic Data Block Grouping Based On Garbage Collection Performance Parameters

(71) Applicant: EVERPURE, INC.

(72) Inventors: VIPIN AGRAWAL, SAN JOSE, CA (US); BRIAN GOLD, LOS ALTOS, CA (US); YUHONG MAO, FREMONT, CA (US)

(21) Appl. No.: 19/669,587

(22) Filed: May 6, 2026

Related U.S. Application Data
(63) Continuation-in-part of application No. 19/388,411, filed on Nov. 13, 2025.
Application No. 19/388,411 is a continuation of application No. 17/877,737, filed on Jul. 29, 2022, now Pat. No. 12,475,041.
Application No. 17/877,737 is a continuation-in-part of application No. 16/653,491, filed on Oct. 15, 2019, now Pat. No. 11,403,043.

(51) Int. Cl. G06F 12/02; G06F 3/06

(52) U.S. Cl. CPC G06F 12/0253; G06F 3/0604; G06F 3/064; G06F 3/0655; G06F 3/0679; G06F 2212/7205

(57) ABSTRACT

Systems and methods are disclosed for improving garbage collection efficiency through adaptive grouping of data blocks. A storage system controller determines a group size for batching data blocks based on one or more garbage collection performance parameters, such as data block occupancy and historical eviction patterns. The storage system controller groups data blocks according to corresponding lifespans, which may be derived from data block age, and assigns the data blocks to groups having defined lifespan ranges. Groups of data blocks are then selectively chosen for garbage collection. The group size may be dynamically adjusted based on observed garbage collection behavior to optimize system performance.

### CROSS REFERENCE TO RELATED APPLICATION

This application is a continuation-in-part application for patent entitled to a filing date and claiming the benefit of earlier-filed U.S. Patent Application No. 19/388,411, filed November 13, 2025, which is a continuation of U.S. Patent Application No. 17/877,737, filed July 29, 2022, now U.S. Patent No. 12,475,041, issued November 18, 2025, which is a continuation-in-part of U.S. Patent Application No. 16/653,491, filed October 15, 2019, now U.S. Patent No. 11,403,043, issued August 2, 2022, all of which are hereby incorporated herein by reference in their entirety.

### BACKGROUND

Storage systems, such as enterprise storage systems, may include a centralized or de-centralized repository for data that provides common data management, data protection, and data sharing functions, for example, through connections to computer systems.

### BRIEF DESCRIPTION OF DRAWINGS

FIG. 1A illustrates a first example system for data storage.

FIG. 1B illustrates a second example system for data storage.

FIG. 1C illustrates a third example system for data storage.

FIG. 1D illustrates a fourth example system for data storage.

FIG. 2A is a perspective view of a storage cluster with multiple storage nodes and internal storage coupled to each storage node to provide network attached storage.

FIG. 2B is a block diagram showing an interconnect switch coupling multiple storage nodes in accordance with some embodiments.

FIG. 2C is a multiple level block diagram, showing contents of a storage node and contents of one of the non-volatile solid state storage units.

FIG. 2D shows a storage server environment, which uses embodiments of the storage nodes and storage units of some previous figures in accordance with some embodiments.

FIG. 2E is a blade hardware block diagram, showing a control plane, compute and storage planes, and authorities interacting with underlying physical resources.

FIG. 2F depicts elasticity software layers in blades of a storage cluster.

FIG. 2G depicts authorities and storage resources in blades of a storage cluster.

FIG. 3A sets forth a diagram of a storage system that is coupled for data communications with a cloud services provider in accordance with some embodiments of the present disclosure.

FIG. 3B sets forth a diagram of a storage system.

FIG. 3C sets forth an example of a cloud-based storage system.

FIG. 3D illustrates an exemplary computing device that may be specifically configured to perform one or more of the processes described herein.

FIG. 3E illustrates an example of a fleet of storage systems for providing storage services (also referred to herein as ‘data services’).

FIG. 3F illustrates an example of a container system.

FIG. 3G illustrates an example of a storage node for a large-scale storage platform, in accordance with embodiments of the disclosure.

FIG. 4A is an illustration of an example of storing data blocks to data segments based on languages associated with the data blocks in accordance with embodiments of the disclosure.

FIG. 4B is an illustration of an example of a storage controller assigning data blocks to data segments based on an associated property in accordance with embodiments of the disclosure.

FIG. 4C is an illustration of an example of storing data blocks within data segments in accordance with embodiments of the present disclosure.

FIG. 5 is an example method to store data blocks having similar properties within a data segment in accordance with embodiments of the disclosure.

FIG. 6 is an example method to allocate received data blocks to data segments based on associated properties in accordance with embodiments of the disclosure.

FIG. 7 is a block diagram illustrating an example system architecture for storing data based on properties, in accordance with embodiments of the present disclosure.

FIG. 8 is an example method to store data blocks in a storage system, in accordance with embodiments of the disclosure.

FIG. 9 is an example block diagram of a system determining group size of data blocks based on one or more garbage collection performance parameters in accordance with embodiments of the disclosure.

FIG. 10 is an example method for determining group size of data blocks based on one or more garbage collection performance parameters in accordance with embodiments of the disclosure.

FIG. 11 is an example method for determining group size of data blocks based on one or more garbage collection performance parameters including lifespans of data block ages in accordance with embodiments of the disclosure.

### DESCRIPTION OF EMBODIMENTS

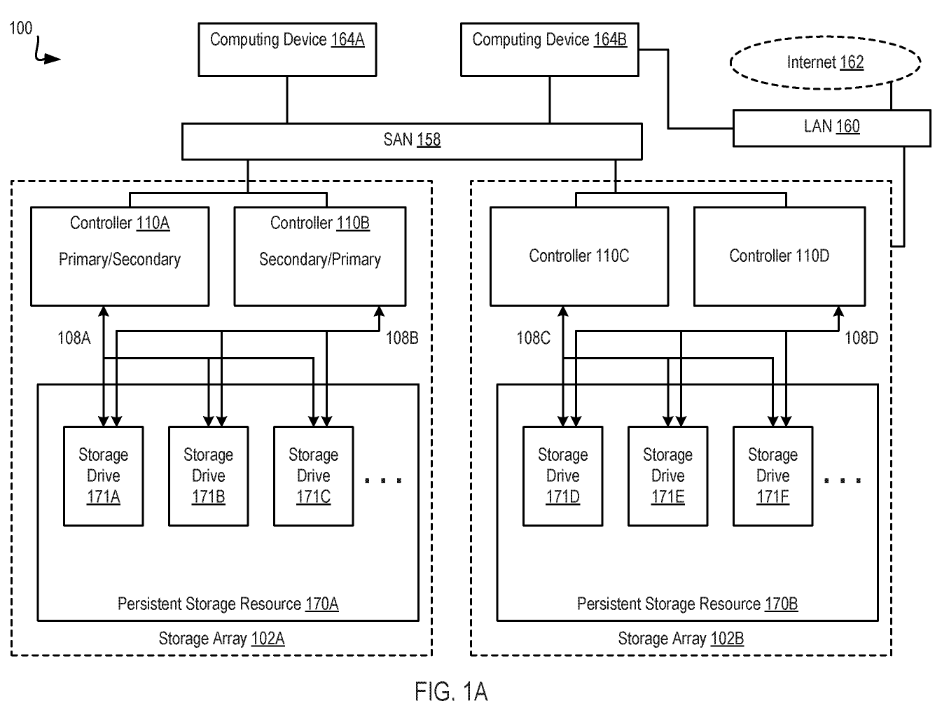

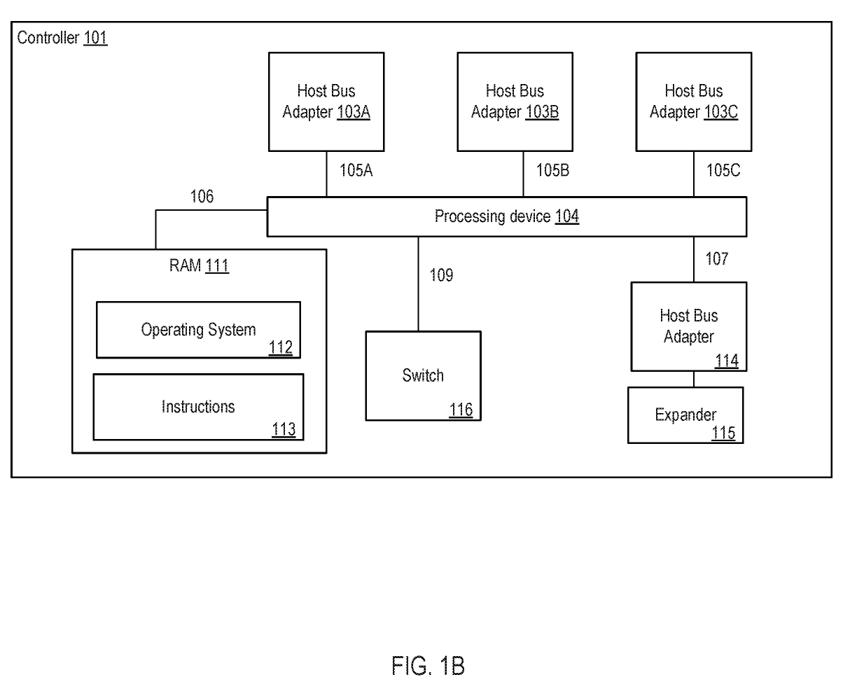

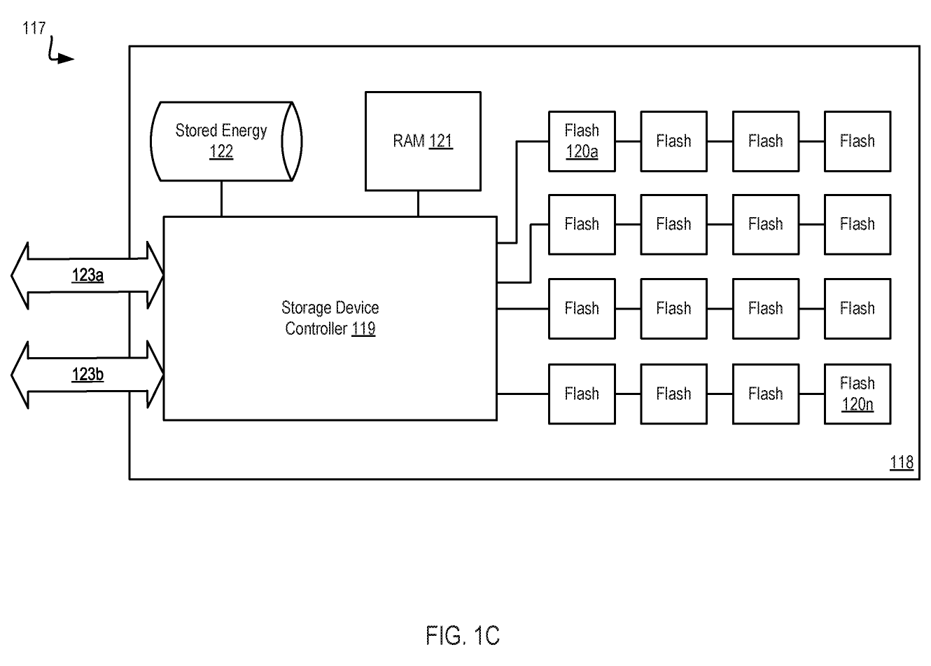

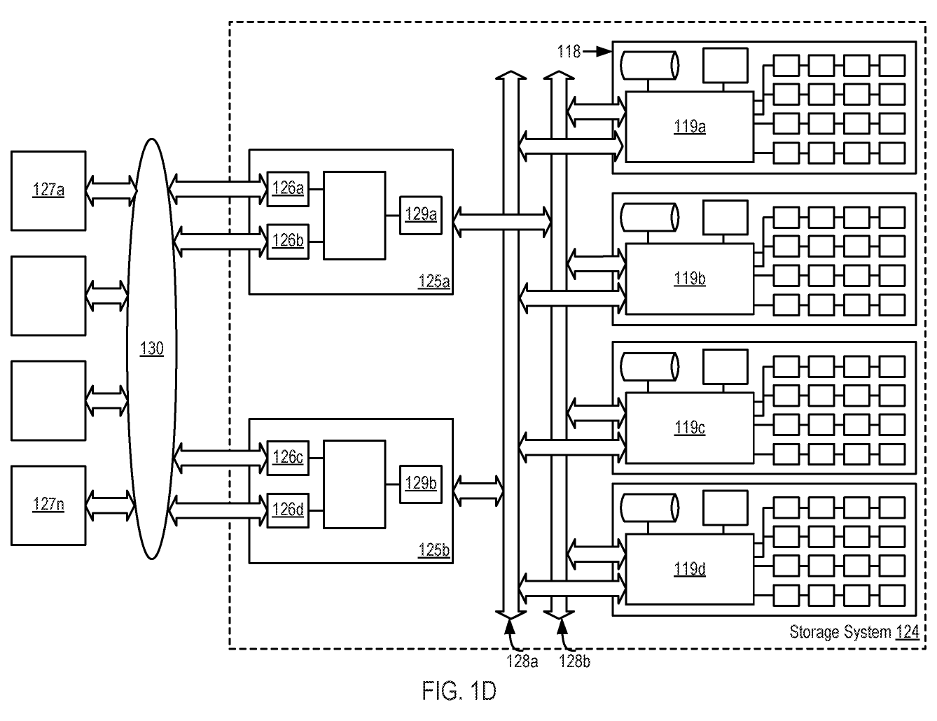

Example methods, apparatus, and products for a system configured to determine group size of data blocks based on one or more garbage collection performance parameters in accordance with embodiments of the present disclosure are described with reference to the accompanying drawings, beginning with FIG. 1A. FIG. 1A illustrates an example system for data storage, in accordance with some implementations. System 100 (also referred to as "storage system" herein) includes numerous elements for purposes of illustration rather than limitation. It may be noted that system 100 may include the same, more, or fewer elements configured in the same or different manner in other implementations.

System 100 includes a number of computing devices 164A-B. Computing devices (also referred to as "client devices" herein) may be embodied, for example, a server in a data center, a workstation, a personal computer, a notebook, or the like. Computing devices 164A-B may be coupled for data communications to one or more storage arrays 102A-B through a storage area network ('SAN') 158 or a local area network ('LAN') 160.

The SAN 158 may be implemented with a variety of data communications fabrics, devices, and protocols. For example, the fabrics for SAN 158 may include Fibre Channel, Ethernet, Infiniband, Serial Attached Small Computer System Interface ('SAS'), or the like. Data communications protocols for use with SAN 158 may include Advanced Technology Attachment ('ATA'), Fibre Channel Protocol, SCSI, iSCSI, HyperSCSI, Non-Volatile Memory Express ('NVMe') over Fabrics, or the like. Other data communication couplings may be implemented between computing devices 164A-B and storage arrays 102A-B.

The LAN 160 may also be implemented with a variety of fabrics, devices, and protocols. For example, the fabrics for LAN 160 may include Ethernet (802.3), wireless (802.11), or the like. Data communication protocols for use in LAN 160 may include Transmission Control Protocol ('TCP'), User Datagram Protocol ('UDP'), Internet Protocol ('IP'), HyperText Transfer Protocol ('HTTP'), or the like. The LAN 160 may also connect to the Internet 162.

Storage arrays 102A-B may provide persistent data storage for the computing devices 164A-B. Storage array 102A may be contained in a chassis (not shown), and storage array 102B may be contained in another chassis (not shown), in some implementations. Storage array 102A and 102B may include one or more storage array controllers 110A-D (also referred to as "controller" herein). A storage array controller bA-D may be embodied as a module of automated computing machinery comprising computer hardware, computer software, or a combination of computer hardware and software. In some implementations, the storage array controllers 110A-D may be configured to carry out various storage tasks. Storage tasks may include writing data received from the computing devices 164A-B to storage array 102A-B, erasing data from storage array 102A-B, retrieving data from storage array 102A-B and providing data to computing devices 164A-B, monitoring and reporting of storage device utilization and performance, performing redundancy operations, such as Redundant Array of Independent Drives ('RAID') or RAID-like data redundancy operations, compressing data, encrypting data, and so forth.

Storage array controller 110A-D may be implemented in a variety of ways, including as a Field Programmable Gate Array ('FPGA'), a Programmable Logic Chip ('PLC'), an Application Specific Integrated Circuit ('ASIC'), System-on-Chip ('SOC'), or any computing device that includes discrete components such as a processing device, central processing unit, computer memory, or various adapters. Storage array controller 110A-D may include, for example, a data communications adapter configured to support communications via the SAN 158 or LAN 160. In some implementations, storage array controller 110A-D may be independently coupled to the LAN 160. In some implementations, storage array controller 110A-D may include an I/O controller or the like that couples the storage array controller 110A-D for data communications, through a midplane (not shown), to a persistent storage resource 170A-B (also referred to as a "storage resource" herein). The persistent storage resource 170A-B may include any number of storage drives 171A-F (also referred to as "storage devices" herein) and any number of non-volatile Random Access Memory ('NVRAM') devices (not shown).

In some embodiments, one or more of the storage drives 171A-F may be managed flash storage devices. A managed flash storage device (which may also be referred to as directly managed flash storage device, directly managed storage device, managed storage device, etc.) may provide functions, operations, commands, APIs or some other appropriate mechanism for an external device, such as a processing device of a storage array controller (e.g., storage array controller 110A-D) to control, manage, and/or interact with the flash memory of the managed flash storage device. This may leave a storage device controller with fewer operations to perform (e.g., handling queues, bust transfers, internal error correction, encryption, voltage level adjusts for lines/pages of flash, etc.). Because the storage devices may be directly managed, this allows the storage system to optimize, manage, and/or improve various aspects, characteristics, etc., of the flash memory to improve performance, reliability, and/or lifespan of the flash memory, as discussed in more detail below.

In embodiments, storage arrays 102A-B may be configured to support the erasure of sub-blocks of erase blocks of flash memory of storage drives 171A-F. Some flash memory supports sub-blocks, which operate like erase blocks with a modest potential loss to capacity and a variety of vendor-specific behaviors and stresses, as well as limits on patterns of sub-block erases and reprograms that may sometimes require erasing an entire full block. For many inventive purposes, these sub-blocks can be treated the same as full erase blocks, just as matching erase blocks across multiple planes of a flash die can be treated for many inventive purposes as the same as simple erase blocks. But, any implementation may have to be augmented somewhat to account for these nuanced behaviors, stresses, and program/erase pattern limitations.

In some implementations, the NVRAM devices of a persistent storage resource 170A-B may be configured to receive, from the storage array controller 110A-D, data to be stored in the storage drives 171A-F. In some examples, the data may originate from computing devices 164A-B. In some examples, writing data to the NVRAM device may be carried out more quickly than directly writing data to the storage drive 171A-F. In some implementations, the storage array controller 110A-D may be configured to utilize the NVRAM devices as a quickly accessible buffer for data destined to be written to the storage drives 171A-F. Latency for write requests using NVRAM devices as a buffer may be improved relative to a system in which a storage array controller 110A-D writes data directly to the storage drives 171A-F. In some implementations, the NVRAM devices may be implemented with computer memory in the form of high bandwidth, low latency RAM. The NVRAM device is referred to as "non-volatile" because the NVRAM device may receive or include a unique power source that maintains the state of the RAM after main power loss to the NVRAM device. Such a power source may be a battery, one or more capacitors, or the like. In response to a power loss, the NVRAM device may be configured to write the contents of the RAM to a persistent storage (e.g., storage drives 171A-F).

In some implementations, storage drive 171A-F may refer to any device configured to record data persistently. In some implementations, storage drive 171A-F may correspond to non-disk storage media. For example, the storage drive 171A-F may be one or more solid-state drives ('SSDs'), flash memory based storage, any type of solid-state non-volatile memory, or any other type of non-mechanical storage device. In other implementations, storage drive 171A-F may include mechanical or spinning hard disk, such as hard-disk drives ('HDD').

In some implementations, the storage array controllers 110A-D may be configured for offloading device management responsibilities from storage drive 171A-F in storage array 102A-B. For example, storage array controllers 110A-D may manage control information that may describe the state of one or more memory blocks in the storage drives 171A-F.

In some implementations, storage array 102A-B may implement two or more storage array controllers 110A-D. At a given instant, a single storage array controller 110A-D (e.g., storage array controller 110A) of a storage system 100 may be designated with primary status (also referred to as "primary controller" herein), and other storage array controllers 110A-D (e.g., storage array controller 110B) may be designated with secondary status (also referred to as "secondary controller" herein). The primary controller may have particular rights, such as permission to alter data in persistent storage resource 170A-B (e.g., writing data to persistent storage resource 170A-B). At least some of the rights of the primary controller may supersede the rights of the secondary controller. For instance, the secondary controller may not have permission to alter data in persistent storage resource 170A-B when the primary controller has the right. The status of storage array controllers 110A-D may change. For example, storage array controller 110A may be designated with secondary status, and storage array controller 110B may be designated with primary status.

In some implementations, a primary controller, such as storage array controller 110A, may serve as the primary controller for one or more storage arrays 102A-B, and a second controller, such as storage array controller 110B, may serve as the secondary controller for the one or more storage arrays 102A-B. In some implementations, storage array controllers 110C and 110D (also referred to as "storage processing modules") may neither have primary or secondary status. Storage array controllers 110C and 110D, implemented as storage processing modules, may act as a communication interface between the primary and secondary controllers (e.g., storage array controllers 110A and 110B, respectively) and storage array 102B. For example, storage array controller 110A of storage array 102A may send a write request, via SAN 158, to storage array 102B. The write request may be received by both storage array controllers 110C and 110D of storage array 102B. Storage array controllers 110C and 110D facilitate the communication, e.g., send the write request to the appropriate storage drive 171A-F. It may be noted that in some implementations storage processing modules may be used to increase the number of storage drives controlled by the primary and secondary controllers.

In some implementations, storage array controllers 110A-D are communicatively coupled, via a midplane (not shown), to one or more storage drives 171A-F and to one or more NVRAM devices (not shown) that are included as part of a storage array 102A-B. The storage array controllers 110A-D may be coupled to the midplane via one or more data communication links and the midplane may be coupled to the storage drives 171A-F and the NVRAM devices via one or more data communications links. The data communications links described herein are collectively illustrated by data communications links 108A-D and may include a Peripheral Component Interconnect Express ('PCIe') bus, for example.

FIG. 1B illustrates an example system for data storage, in accordance with some implementations. Storage array controller 101 illustrated in FIG. 1B may be similar to the storage array controllers 110A-D described with respect to FIG. 1A. It may be noted that storage array controller 101 may include the same, more, or fewer elements configured in the same or different manner in other implementations. It may be noted that elements of FIG. 1A may be included below to help illustrate features of storage array controller 101.

Storage array controller 101 may include one or more processing devices 104 and random access memory ('RAM') 111. Processing device 104 (or controller 101) represents one or more general-purpose processing devices such as a microprocessor or CPU. The processing device 104 (or controller 101) may also be one or more special-purpose processing devices (e.g., an ASIC, an FPGA, a digital signal processor ('DSP'), network processor).

The processing device 104 may be connected to the RAM 111 via a data communications link 106, which may be embodied as a high-speed memory bus such as a Double-Data Rate 4 ('DDR4') bus. Stored in RAM 111 is an operating system 112. In some implementations, instructions 113 are stored in RAM 111. Instructions 113 may include computer program instructions for performing operations in a direct-mapped flash storage system. In one embodiment, a direct-mapped flash storage system is one that addresses data blocks within flash drives directly and without an address translation performed by the flash drives.

In some implementations, storage array controller 101 includes one or more host bus adapters 103A-C coupled to the processing device 104 via a data communications link 105A-C. In some examples, host bus adapters 103A-C may be a Fibre Channel adapter that enables the storage array controller 101 to connect to a SAN, an Ethernet adapter that enables the storage array controller 101 to connect to a LAN, or the like. Host bus adapters 103A-C may be coupled to the processing device 104 via a data communications link 105A-C such as a PCIe bus.

In some implementations, storage array controller 101 may include a host bus adapter 114 that is coupled to an expander 115. The expander 115 may be used to attach a host system to a larger number of storage drives. The expander 115 may, for example, be a SAS expander utilized to enable the host bus adapter 114 to attach to storage drives in an implementation where the host bus adapter 114 is embodied as a SAS controller.

In some implementations, storage array controller 101 may include a switch 116 coupled to the processing device 104 via a data communications link 109. The switch 116 may be a computer hardware device that can create multiple endpoints out of a single endpoint, thereby enabling multiple devices to share a single endpoint. The switch 116 may, for example, be a PCIe switch that is coupled to a PCIe bus (e.g., data communications link 109) and presents multiple PCIe connection points to the midplane. In some implementations, storage array controller 101 includes a data communications link 107 for coupling the storage array controller 101 to other storage array controllers. In some examples, data communications link 107 may be a QuickPath Interconnect (QPI) interconnect.

A storage system that uses flash drives may implement a process across the flash drives that are part of the storage system. For example, a higher-level process of the storage system may initiate and control a process across the flash drives. However, a flash drive of the storage system may include its own storage controller that also performs the process. Thus, for the storage system, a higher-level process (e.g., initiated by the storage system) and a lower-level process (e.g., initiated by a storage controller of the storage system) may both be performed.

In other embodiments, operations may be performed by higher-level processes and not by the lower-level processes. For example, the flash storage system may include flash drives that do not include storage controllers that provide the process. Thus, the operating system of the flash storage system itself may initiate and control the process. This may be accomplished by a direct-mapped flash storage system that addresses data blocks within the flash drives directly and without an address translation performed by the storage controllers of the flash drives.

In some implementations, storage drive 171A-F may be one or more zoned storage devices. In some implementations, the one or more zoned storage devices may be a shingled HDD. In some implementations, the one or more storage devices may be a flash-based SSD. In a zoned storage device, a zoned namespace on the zoned storage device can be addressed by groups of blocks that are grouped and aligned by a natural size, forming a number of addressable zones. In some implementations utilizing an SSD, the natural size may be based on the erase block size of the SSD. In some implementations, the zones of the zoned storage device may be defined during initialization of the zoned storage device. In some implementations, the zones may be defined dynamically as data is written to the zoned storage device.

In some implementations, zones may be heterogeneous, with some zones each being a page group and other zones being multiple page groups. In some implementations, some zones may correspond to an erase block and other zones may correspond to multiple erase blocks. In an implementation, zones may be any combination of differing numbers of pages in page groups and/or erase blocks, for heterogeneous mixes of programming modes, manufacturers, product types and/or product generations of storage devices, as applied to heterogeneous assemblies, upgrades, distributed storages, etc. In some implementations, zones may be defined as having usage characteristics, such as a property of supporting data with particular kinds of longevity (very short lived or very long lived, for example). These properties could be used by a zoned storage device to determine how the zone will be managed over the zone’s expected lifetime.

It should be appreciated that a zone is a virtual construct. Any particular zone may not have a fixed location at a storage device. Until allocated, a zone may not have any location at a storage device. A zone may correspond to a number representing a chunk of virtually allocatable space that is the size of an erase block or other block size in various implementations. When the system allocates or opens a zone, zones get allocated to flash or other solid-state storage memory and, as the system writes to the zone, pages are written to that mapped flash or other solid-state storage memory of the zoned storage device. When the system closes the zone, the associated erase block(s) or other sized block(s) are completed. At some point, the system may delete a zone to free up the zone's allocated space. A zone may be moved around to different locations of the zoned storage device, e.g., as the zoned storage device does internal maintenance.

In some implementations, the zones of the zoned storage device may be in different states. A zone may be in an empty state in which data has not been stored at the zone. An empty zone may be opened explicitly, or implicitly by writing data to the zone. This is the initial state for zones on a fresh zoned storage device, but may also be the result of a zone reset. In some implementations, an empty zone may have a designated location within the flash memory of the zoned storage device. In an implementation, the location of the empty zone may be chosen when the zone is first opened or first written to (or later if writes are buffered into memory). A zone may be in an open state either implicitly or explicitly, where a zone that is in an open state may be written to store data with write or append commands. In an implementation, a zone that is in an open state may also be written to using a copy command that copies data from a different zone. In some implementations, a zoned storage device may have a limit on the number of open zones at a particular time.

A zone in a closed state is a zone that has been partially written to, but has entered a closed state after issuing an explicit close operation. A zone in a closed state may be left available for future writes, but may reduce some of the run-time overhead consumed by keeping the zone in an open state. In some implementations, a zoned storage device may have a limit on the number of closed zones at a particular time. A zone in a full state is a zone that is storing data and can no longer be written to. A zone may be in a full state either after writes have written data to the entirety of the zone or as a result of a zone finish operation. Prior to a finish operation, a zone may or may not have been completely written. After a finish operation, however, the zone may not be opened a written to further without first performing a zone reset operation.

The mapping from a zone to an erase block (or to a shingled track in an HDD) may be arbitrary, dynamic, and hidden from view. The process of opening a zone may be an operation that allows a new zone to be dynamically mapped to underlying storage of the zoned storage device, and then allows data to be written through appending writes into the zone until the zone reaches capacity. The zone can be finished at any point, after which further data may not be written into the zone. When the data stored at the zone is no longer needed, the zone can be reset which effectively deletes the zone's content from the zoned storage device, making the physical storage held by that zone available for the subsequent storage of data. Once a zone has been written and finished, the zoned storage device ensures that the data stored at the zone is not lost until the zone is reset. In the time between writing the data to the zone and the resetting of the zone, the zone may be moved around between shingle tracks or erase blocks as part of maintenance operations within the zoned storage device, such as by copying data to keep the data refreshed or to handle memory cell aging in an SSD.

In some implementations utilizing an HDD, resetting a zone may allow the shingle tracks to be allocated to a new, opened zone that may be opened at some point in the future. In some implementations utilizing an SSD, the resetting of the zone may cause the associated physical erase block(s) of the zone to be erased and subsequently reused for the storage of data. In some implementations, the zoned storage device may have a limit on the number of open zones at a point in time to reduce the amount of overhead dedicated to keeping zones open.

The operating system of the flash storage system may identify and maintain a list of allocation units across multiple flash drives of the flash storage system. The allocation units may be entire erase blocks or multiple erase blocks. The operating system may maintain a map or address range that maps addresses to erase blocks of the flash drives of the flash storage system.

Direct mapping to the erase blocks of the flash drives may be used to rewrite data and erase data. For example, the operations may be performed on one or more allocation units that include a first data and a second data where the first data is to be retained and the second data is no longer being used by the flash storage system. The operating system may initiate the process to write the first data to new locations within other allocation units and erasing the second data and marking the allocation units as being available for use for subsequent data. Thus, the process may only be performed by the higher-level operating system of the flash storage system without an additional lower-level process being performed by controllers of the flash drives.

Advantages of the process being performed only by the operating system of the flash storage system include increased reliability of the flash drives of the flash storage system as unnecessary or redundant write operations are not being performed during the process. One possible point of novelty here is the concept of initiating and controlling the process at the operating system of the flash storage system. In addition, the process can be controlled by the operating system across multiple flash drives. This is in contrast to the process being performed by a storage controller of a flash drive.

A storage system can consist of two storage array controllers that share a set of drives for failover purposes, or it could consist of a single storage array controller that provides a storage service that utilizes multiple drives, or it could consist of a distributed network of storage array controllers each with some number of drives or some amount of Flash storage where the storage array controllers in the network collaborate to provide a complete storage service and collaborate on various aspects of a storage service including storage allocation and garbage collection.

FIG. 1C illustrates a third example system 117 for data storage in accordance with some implementations. System 117 (also referred to as "storage system" herein) includes numerous elements for purposes of illustration rather than limitation. It may be noted that system 117 may include the same, more, or fewer elements configured in any manner in other implementations.

In one embodiment, system 117 includes a dual Peripheral Component Interconnect ('PCI') flash storage device 118 with separately addressable fast write storage. System 117 may include a storage device controller 119. In one embodiment, storage device controller 119A-D may be a CPU, ASIC, FPGA, or any other circuitry that implements control structures according to the present disclosure. In one embodiment, system 117 includes flash memory devices (e.g., including flash memory devices 120a-n), operatively coupled to various channels of the storage device controller 119. Flash memory devices 120a-n may be presented to the controller 119A-D as an addressable collection of Flash pages, erase blocks, and/or control elements sufficient to allow the storage device controller 119A-D to program and retrieve various aspects of the Flash. In one embodiment, storage device controller 119A-D may perform operations on flash memory devices 120a-n including storing and retrieving data content of pages, arranging and erasing any blocks, tracking statistics related to the use and reuse of Flash memory pages, erase blocks, and cells, tracking and predicting error codes and faults within the Flash memory, controlling voltage levels associated with programming and retrieving contents of Flash cells, etc.

In one embodiment, system 117 may include RAM 121 to store separately addressable fast-write data. In one embodiment, RAM 121 may be one or more separate discrete devices. In another embodiment, RAM 121 may be integrated into one or more storage device controllers 119A-D. The RAM 121 may be utilized for other purposes as well, such as temporary program memory for a processing device (e.g., a CPU) in the storage device controller 119.

In one embodiment, system 117 may include a stored energy device 122, such as a rechargeable battery or a capacitor. Stored energy device 122 may store energy sufficient to power the storage device controller 119, some amount of the RAM (e.g., RAM 121), and some amount of Flash memory (e.g., Flash memory 120a-120n) for sufficient time to write the contents of RAM to Flash memory. In one embodiment, storage device controller 119A-D may write the contents of RAM to Flash Memory if the storage device controller detects loss of external power.

In one embodiment, system 117 includes two data communications links 123a, 123b. In one embodiment, data communications links 123a, 123b may be PCI interfaces. In another embodiment, data communications links 123a, 123b may be based on other communications standards (e.g., HyperTransport, InfiniBand, etc.). Data communications links 123a, 123b may be based on NVMe or NVMe over fabrics ('NVMf') specifications that allow external connection to the storage device controller 119A-D from other components in the storage system 117. It should be noted that data communications links may be interchangeably referred to herein as PCI buses.

System 117 may also include an external power source (not shown), which may be provided over one or both data communications links 123a, 123b, or which may be provided separately. An alternative embodiment includes a separate Flash memory (not shown) dedicated for use in storing the content of RAM 121. The storage device controller 119A-D may present a logical device over a PCI bus which may include an addressable fast-write logical device, or a distinct part of the logical address space of the storage device 118, which may be presented as PCI memory or as persistent storage. In one embodiment, operations to store into the device are directed into the RAM 121. On power failure, the storage device controller 119A-D may write stored content associated with the addressable fast-write logical storage to Flash memory (e.g., Flash memory 120a-n) for long-term persistent storage.

In one embodiment, the logical device may include some presentation of some or all of the content of the Flash memory devices 120a-n, where that presentation allows a storage system including a storage device 118 (e.g., storage system 117) to directly address Flash memory pages and directly reprogram erase blocks from storage system components that are external to the storage device through the PCI bus. The presentation may also allow one or more of the external components to control and retrieve other aspects of the Flash memory including some or all of: tracking statistics related to use and reuse of Flash memory pages, erase blocks, and cells across all the Flash memory devices; tracking and predicting error codes and faults within and across the Flash memory devices; controlling voltage levels associated with programming and retrieving contents of Flash cells; etc.

In one embodiment, the stored energy device 122 may be sufficient to ensure completion of in-progress operations to the Flash memory devices 120a-120n. The stored energy device 122 may power storage device controller 119A-D and associated Flash memory devices (e.g., 120a-n) for those operations, as well as for the storing of fast-write RAM to Flash memory. Stored energy device 122 may be used to store accumulated statistics and other parameters kept and tracked by the Flash memory devices 120a-n and/or the storage device controller 119. Separate capacitors or stored energy devices (such as smaller capacitors near or embedded within the Flash memory devices themselves) may be used for some or all of the operations described herein.

Various schemes may be used to track and optimize the life span of the stored energy component, such as adjusting voltage levels over time, partially discharging the stored energy device 122 to measure corresponding discharge characteristics, etc. If the available energy decreases over time, the effective available capacity of the addressable fast-write storage may be decreased to ensure that it can be written safely based on the currently available stored energy.

FIG. 1D illustrates a third example storage system 124 for data storage in accordance with some implementations. In one embodiment, storage system 124 includes storage controllers 125a, 125b. In one embodiment, storage controllers 125a, 125b are operatively coupled to Dual PCI storage devices. Storage controllers 125a, 125b may be operatively coupled (e.g., via a storage network 130) to some number of host computers 127a-n.

In one embodiment, two storage controllers (e.g., 125a and 125b) provide storage services, such as a SCS block storage array, a file server, an object server, a database or data analytics service, etc. The storage controllers 125a, 125b may provide services through some number of network interfaces (e.g., 126a-d) to host computers 127a-n outside of the storage system 124. Storage controllers 125a, 125b may provide integrated services or an application entirely within the storage system 124, forming a converged storage and compute system. The storage controllers 125a, 125b may utilize the fast write memory within or across storage devices119a-d to journal in progress operations to ensure the operations are not lost on a power failure, storage controller removal, storage controller or storage system shutdown, or some fault of one or more software or hardware components within the storage system 124.

In one embodiment, storage controllers 125a, 125b operate as PCI masters to one or the other PCI buses 128a, 128b. In another embodiment, 128a and 128b may be based on other communications standards (e.g., HyperTransport, InfiniBand, etc.). Other storage system embodiments may operate storage controllers 125a, 125b as multi-masters for both PCI buses 128a, 128b. Alternately, a PCI/NVMe/NVMf switching infrastructure or fabric may connect multiple storage controllers. Some storage system embodiments may allow storage devices to communicate with each other directly rather than communicating only with storage controllers. In one embodiment, a storage device controller 119a may be operable under direction from a storage controller 125a to synthesize and transfer data to be stored into Flash memory devices from data that has been stored in RAM (e.g., RAM 121 of FIG. 1C). For example, a recalculated version of RAM content may be transferred after a storage controller has determined that an operation has fully committed across the storage system, or when fast-write memory on the device has reached a certain used capacity, or after a certain amount of time, to ensure improved safety of the data or to release addressable fast-write capacity for reuse. This mechanism may be used, for example, to avoid a second transfer over a bus (e.g., 128a, 128b) from the storage controllers 125a, 125b. In one embodiment, a recalculation may include compressing data, attaching indexing or other metadata, combining multiple data segments together, performing erasure code calculations, etc.

In one embodiment, under direction from a storage controller 125a, 125b, a storage device controller 119a, 119b may be operable to calculate and transfer data to other storage devices from data stored in RAM (e.g., RAM 121 of FIG. 1C) without involvement of the storage controllers 125a, 125b. This operation may be used to mirror data stored in one storage controller 125a to another storage controller 125b, or it could be used to offload compression, data aggregation, and/or erasure coding calculations and transfers to storage devices to reduce load on storage controllers or the storage controller interface 129a, 129b to the PCI bus 128a, 128b.

A storage device controller 119A-D may include mechanisms for implementing high availability primitives for use by other parts of a storage system external to the Dual PCI storage device 118. For example, reservation or exclusion primitives may be provided so that, in a storage system with two storage controllers providing a highly available storage service, one storage controller may prevent the other storage controller from accessing or continuing to access the storage device. This could be used, for example, in cases where one controller detects that the other controller is not functioning properly or where the interconnect between the two storage controllers may itself not be functioning properly.

In one embodiment, a storage system for use with Dual PCI direct mapped storage devices with separately addressable fast write storage includes systems that manage erase blocks or groups of erase blocks as allocation units for storing data on behalf of the storage service, or for storing metadata (e.g., indexes, logs, etc.) associated with the storage service, or for proper management of the storage system itself. Flash pages, which may be a few kilobytes in size, may be written as data arrives or as the storage system is to persist data for long intervals of time (e.g., above a defined threshold of time). To commit data more quickly, or to reduce the number of writes to the Flash memory devices, the storage controllers may first write data into the separately addressable fast write storage on one or more storage devices.

In one embodiment, the storage controllers 125a, 125b may initiate the use of erase blocks within and across storage devices (e.g., 118) in accordance with an age and expected remaining lifespan of the storage devices, or based on other statistics. The storage controllers 125a, 125b may initiate garbage collection and data migration between storage devices in accordance with pages that are no longer needed as well as to manage Flash page and erase block lifespans and to manage overall system performance.

In one embodiment, the storage system 124 may utilize mirroring and/or erasure coding schemes as part of storing data into addressable fast write storage and/or as part of writing data into allocation units associated with erase blocks. Erasure codes may be used across storage devices, as well as within erase blocks or allocation units, or within and across Flash memory devices on a single storage device, to provide redundancy against single or multiple storage device failures or to protect against internal corruptions of Flash memory pages resulting from Flash memory operations or from degradation of Flash memory cells. Mirroring and erasure coding at various levels may be used to recover from multiple types of failures that occur separately or in combination.

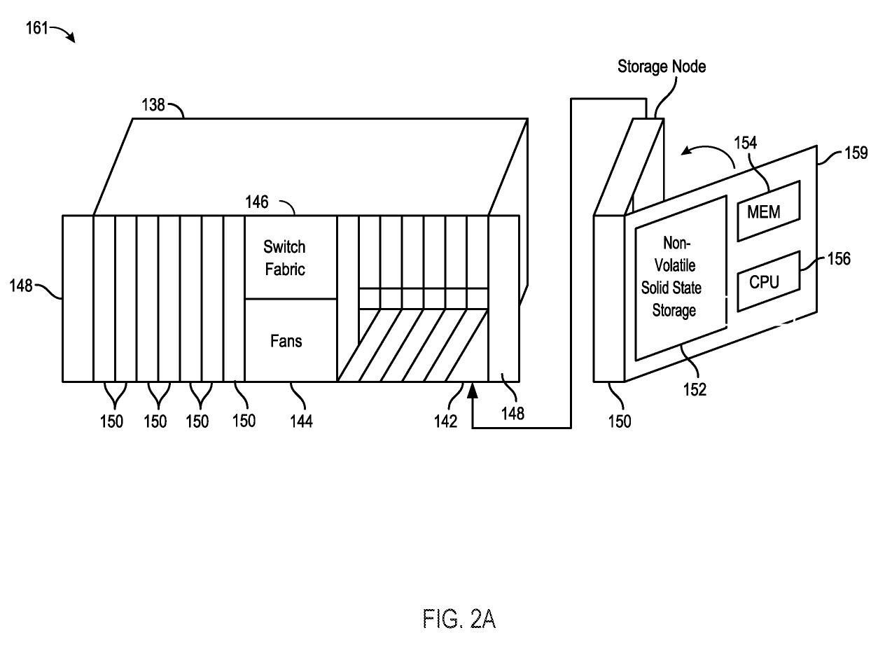

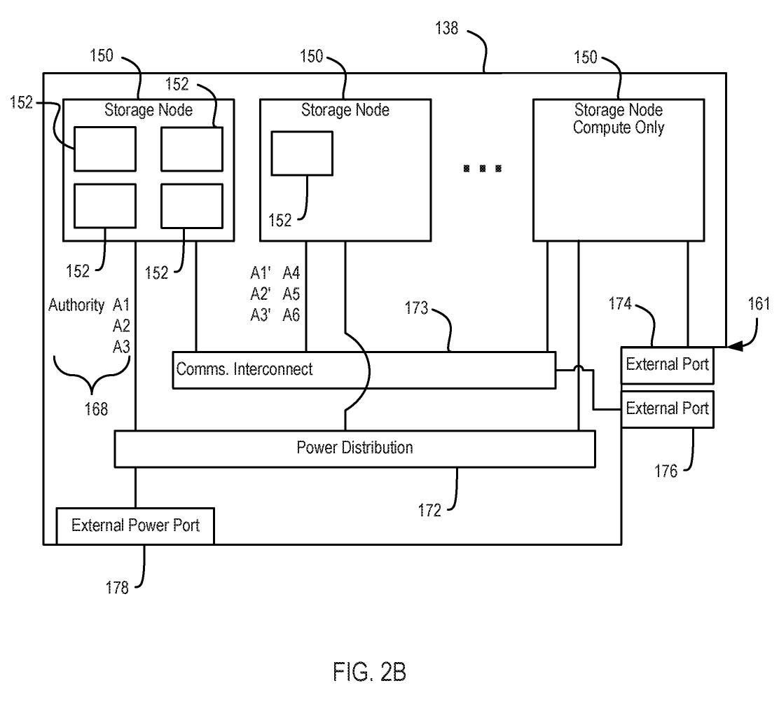

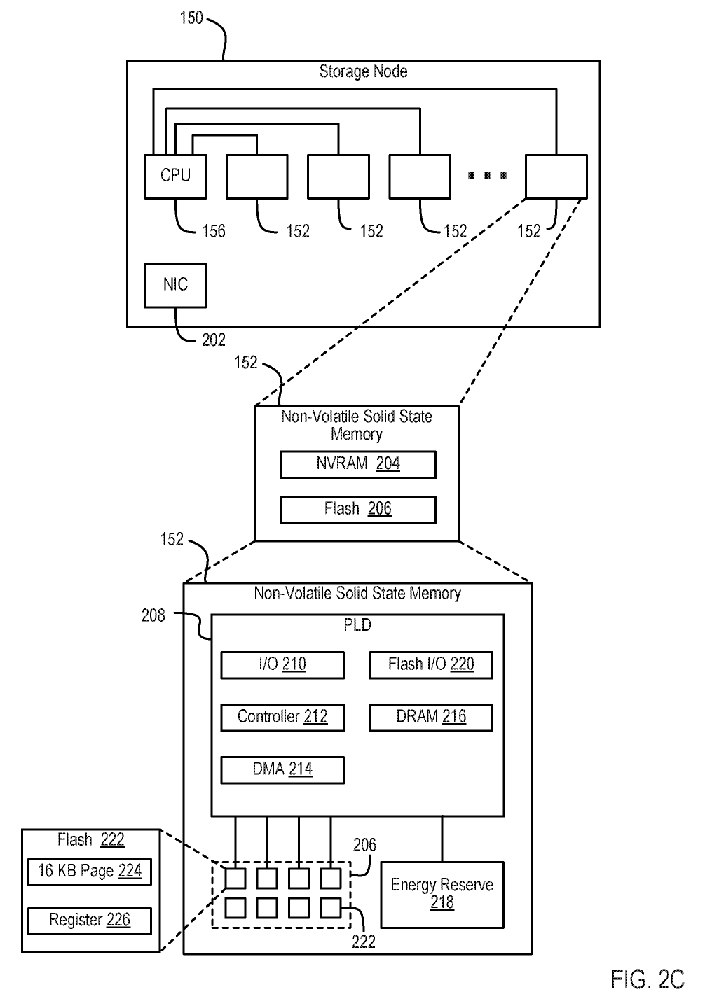

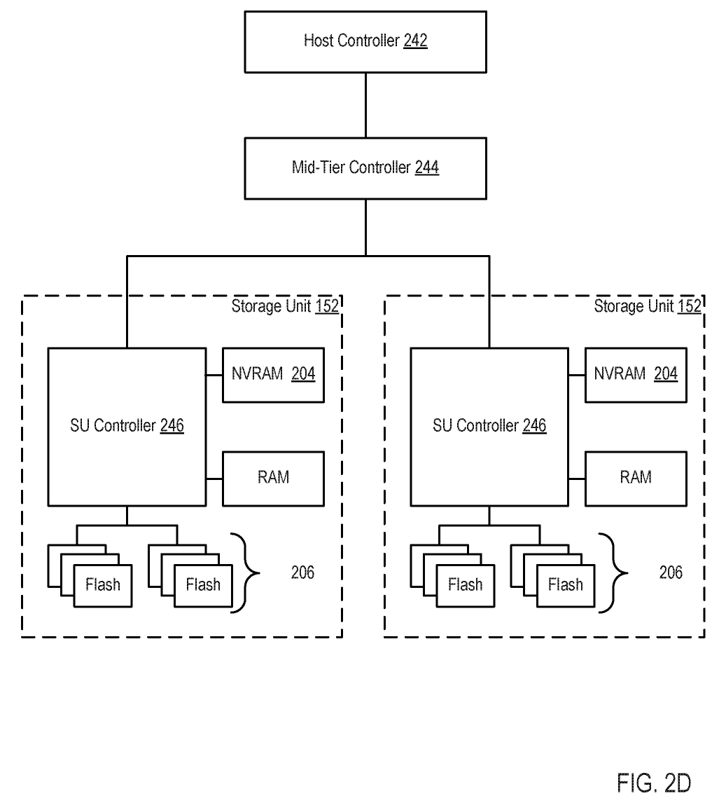

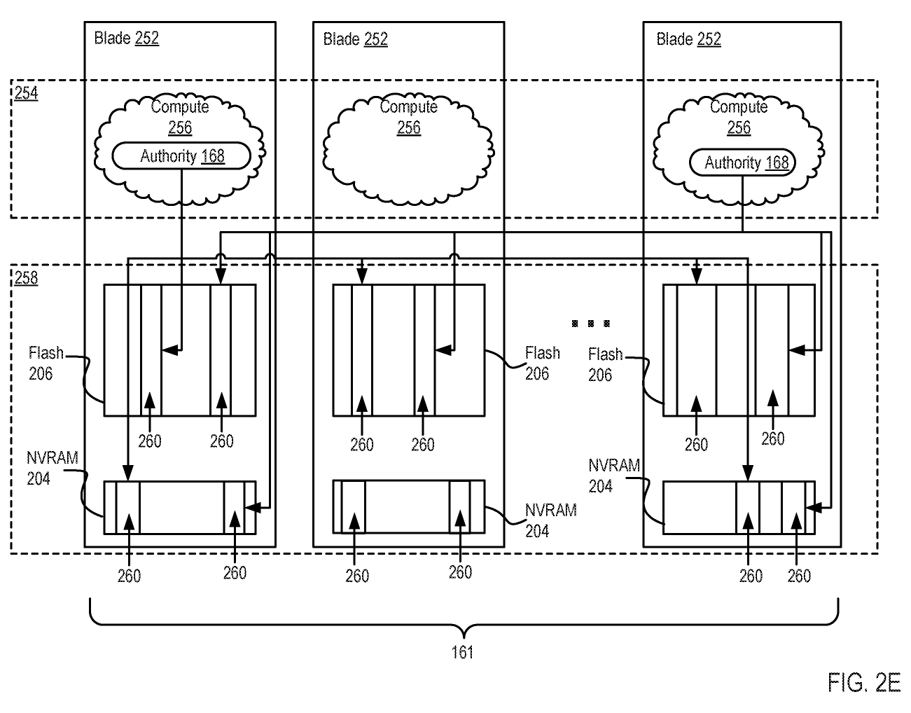

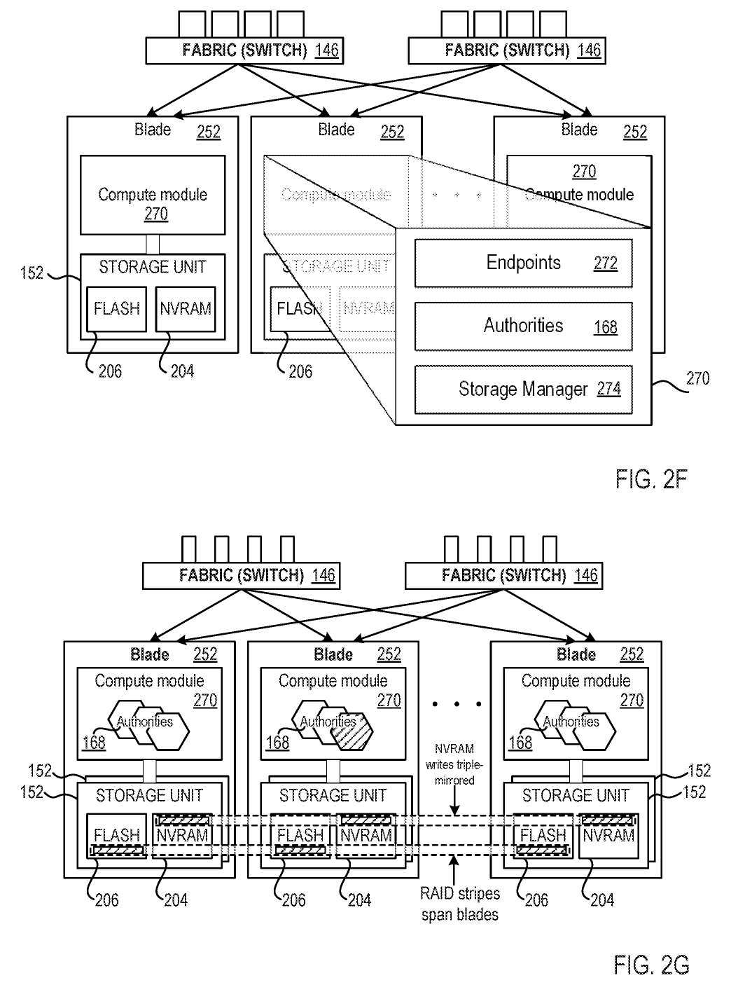

The embodiments depicted with reference to FIGS. 2A-G illustrate a storage cluster that stores user data, such as user data originating from one or more user or client systems or other sources external to the storage cluster. The storage cluster distributes user data across storage nodes housed within a chassis, or across multiple chassis, using erasure coding and redundant copies of metadata. Erasure coding refers to a method of data protection or reconstruction in which data is stored across a set of different locations, such as disks, storage nodes or geographic locations. Flash memory is one type of solid-state memory that may be integrated with the embodiments, although the embodiments may be extended to other types of solid-state memory or other storage medium, including non- solid state memory. Control of storage locations and workloads are distributed across the storage locations in a clustered peer-to-peer system. Tasks such as mediating communications between the various storage nodes, detecting when a storage node has become unavailable, and balancing I/Os (inputs and outputs) across the various storage nodes, are all handled on a distributed basis. Data is laid out or distributed across multiple storage nodes in data fragments or stripes that support data recovery in some embodiments. Ownership of data can be reassigned within a cluster, independent of input and output patterns. This architecture described in more detail below allows a storage node in the cluster to fail, with the system remaining operational, since the data can be reconstructed from other storage nodes and thus remain available for input and output operations. In various embodiments, a storage node may be referred to as a cluster node, a blade, or a server.

The storage cluster may be contained within a chassis, i.e., an enclosure housing one or more storage nodes. A mechanism to provide power to each storage node, such as a power distribution bus, and a communication mechanism, such as a communication bus that enables communication between the storage nodes are included within the chassis. The storage cluster can run as an independent system in one location according to some embodiments. In one embodiment, a chassis contains at least two instances of both the power distribution and the communication bus which may be enabled or disabled independently. The internal communication bus may be an Ethernet bus, however, other technologies such as PCIe, InfiniBand, and others, are equally suitable. The chassis provides a port for an external communication bus for enabling communication between multiple chassis, directly or through a switch, and with client systems. The external communication may use a technology such as Ethernet, InfiniBand, Fibre Channel, etc. In some embodiments, the external communication bus uses different communication bus technologies for inter-chassis and client communication. If a switch is deployed within or between chassis, the switch may act as a translation between multiple protocols or technologies. When multiple chassis are connected to define a storage cluster, the storage cluster may be accessed by a client using either proprietary interfaces or standard interfaces such as network file system ('NFS'), common internet file system ('CIFS'), small computer system interface ('SCSI') or hypertext transfer protocol ('HTTP'). Translation from the client protocol may occur at the switch, chassis external communication bus or within each storage node. In some embodiments, multiple chassis may be coupled or connected to each other through an aggregator switch. A portion and/or all of the coupled or connected chassis may be designated as a storage cluster. As discussed above, each chassis can have multiple blades, each blade has a media access control ('MAC') address, but the storage cluster is presented to an external network as having a single cluster IP address and a single MAC address.

Each storage node may be one or more storage servers and each storage server is connected to one or more non-volatile solid state memory units, which may be referred to as storage units or storage devices. One embodiment includes a single storage server in each storage node and between one to eight non-volatile solid state memory units, however this one example is not meant to be limiting. The storage server may include a processor, DRAM and interfaces for the internal communication bus and power distribution for each of the power buses. Inside the storage node, the interfaces and storage unit share a communication bus, e.g., PCIe, in some embodiments. The non-volatile solid state memory units may directly access the internal communication bus interface through a storage node communication bus, or request the storage node to access the bus interface. The non-volatile solid state memory unit contains an embedded CPU, solid state storage controller, and a quantity of solid state mass storage, e.g., between 2-32 terabytes ('TB') in some embodiments. An embedded volatile storage medium, such as DRAM, and an energy reserve apparatus are included in the non-volatile solid state memory unit. In some embodiments, the energy reserve apparatus is a capacitor, super-capacitor, or battery that enables transferring a subset of DRAM contents to a stable storage medium in the case of power loss. In some embodiments, the non-volatile solid state memory unit is constructed with a storage class memory, such as phase change or magnetoresistive random access memory ('MRAM') that substitutes for DRAM and enables a reduced power hold-up apparatus.

One of many features of the storage nodes and non-volatile solid state storage is the ability to proactively rebuild data in a storage cluster. The storage nodes and non-volatile solid state storage can determine when a storage node or non-volatile solid state storage in the storage cluster is unreachable, independent of whether there is an attempt to read data involving that storage node or non-volatile solid state storage. The storage nodes and non-volatile solid state storage then cooperate to recover and rebuild the data in at least partially new locations. This constitutes a proactive rebuild, in that the system rebuilds data without waiting until the data is needed for a read access initiated from a client system employing the storage cluster. These and further details of the storage memory and operation thereof are discussed below.

FIG. 2A is a perspective view of a storage cluster 161, with multiple storage nodes 150 and internal solid-state memory coupled to each storage node to provide network attached storage or storage area network, in accordance with some embodiments. A network attached storage, storage area network, or a storage cluster, or other storage memory, could include one or more storage clusters 161, each having one or more storage nodes 150, in a flexible and reconfigurable arrangement of both the physical components and the amount of storage memory provided thereby. The storage cluster 161 is designed to fit in a rack, and one or more racks can be set up and populated as desired for the storage memory. The storage cluster 161 has a chassis 138 having multiple slots 142. It should be appreciated that chassis 138 may be referred to as a housing, enclosure, or rack unit. In one embodiment, the chassis 138 has fourteen slots 142, although other numbers of slots are readily devised. Each slot 142 can accommodate one storage node 150 in some embodiments. Chassis 138 includes flaps 148 that can be utilized to mount the chassis 138 on a rack. Fans 144 provide air circulation for cooling of the storage nodes 150 and components thereof, although other cooling components could be used, or an embodiment could be devised without cooling components. A switch fabric 146 couples storage nodes 150 within chassis 138 together and to a network for communication to the memory. In an embodiment depicted in herein, the slots 142 to the left of the switch fabric 146 and fans 144 are shown occupied by storage nodes 150, while the slots 142 to the right of the switch fabric 146 and fans 144 are empty and available for insertion of storage node 150 for illustrative purposes. This configuration is one example, and one or more storage nodes 150 could occupy the slots 142 in various further arrangements. The storage node arrangements need not be sequential or adjacent in some embodiments. Storage nodes 150 are hot pluggable, meaning that a storage node 150 can be inserted into a slot 142 in the chassis 138, or removed from a slot 142, without stopping or powering down the system. Upon insertion or removal of storage node 150 from slot 142, the system automatically reconfigures in order to recognize and adapt to the change. Reconfiguration can include restoring redundancy and/or rebalancing data or load.

Each storage node 150 can have multiple components such as, for example, a printed circuit board 159 populated by a CPU 156, a memory 154 coupled to the CPU 156, and a non-volatile solid state storage 152 coupled to the CPU 156, although other mountings and/or components could be used in further embodiments. The memory 154 has instructions which are executed by the CPU 156 and/or data operated on by the CPU 156. As further explained below, the non-volatile solid state storage 152 includes flash or, in further embodiments, other types of solid-state memory. In some embodiments, the non-volatile solid state storage 152 may include one or more managed flash storage devices, as previously described.

Referring to FIG. 2A, storage cluster 161 is scalable, meaning that storage capacity with non-uniform storage sizes is readily added, as described above. One or more storage nodes 150 can be plugged into or removed from each chassis and the storage cluster self-configures in some embodiments. Plug-in storage nodes 150, whether installed in a chassis as delivered or later added, can have different sizes. For example, in one embodiment a storage node 150 can have any multiple of 4 TB. In further embodiments, a storage node 150 could have any multiple of other storage amounts or capacities. Storage capacity of each storage node 150 is broadcast, and influences decisions of how to stripe the data. Some embodiments can self-configure as wide as possible in the stripe, subject to a predetermined requirement of continued operation with loss of up to one, or up to two, non-volatile solid state storage 152 units or storage nodes 150.

FIG. 2B is a block diagram showing a communications interconnect 173 and power distribution bus 172 coupling multiple storage nodes 150. Referring back to FIG. 2A, the communications interconnect 173 can be included in or implemented with the switch fabric 146 in some embodiments. Where multiple storage clusters 161 occupy a rack, the communications interconnect 173 can be included in or implemented with a top of rack switch, in some embodiments. As illustrated in FIG. 2B, storage cluster 161 is enclosed within a single chassis 138. External port 176 is coupled to storage nodes 150 through communications interconnect 173, while external port 174 is coupled directly to a storage node. External power port 178 is coupled to power distribution bus 172. Storage nodes 150 may include varying amounts and differing capacities of non-volatile solid state storage 152 as described with reference to FIG. 2A. In addition, one or more storage nodes 150 may be a compute only storage node as illustrated in FIG. 2B. Authorities 168 are implemented on the non-volatile solid state storage 152, for example as lists or other data structures stored in memory. In some embodiments the authorities are stored within the non-volatile solid state storage 152 and supported by software executing on a controller or other processor of the non-volatile solid state storage 152. In a further embodiment, authorities 168 are implemented on the storage nodes 150, for example as lists or other data structures stored in the memory 154 and supported by software executing on the CPU 156 of the storage node 150. Authorities 168 control how and where data is stored in the non-volatile solid state storage 152 in some embodiments. This control assists in determining which type of erasure coding scheme is applied to the data, and which storage nodes 150 have which portions of the data. Each authority 168 may be assigned to a non-volatile solid state storage 152. Each authority may control a range of inode numbers, segment numbers, or other data identifiers which are assigned to data by a file system, by the storage nodes 150, or by the non-volatile solid state storage 152, in various embodiments.

Every piece of data, and every piece of metadata, has redundancy in the system in some embodiments. In addition, every piece of data and every piece of metadata has an owner, which may be referred to as an authority. If that authority is unreachable, for example through failure of a storage node, there is a plan of succession for how to find that data or that metadata. In various embodiments, there are redundant copies of authorities 168. Authorities 168 have a relationship to storage nodes 150 and non-volatile solid state storage 152 in some embodiments. Each authority 168, covering a range of data segment numbers or other identifiers of the data, may be assigned to a specific non-volatile solid state storage 152. In some embodiments the authorities 168 for all of such ranges are distributed over the non-volatile solid state storage 152 of a storage cluster. Each storage node 150 has a network port that provides access to the non-volatile solid state storage(s) 152 of that storage node 150. Data can be stored in a segment, which is associated with a segment number and that segment number is an indirection for a configuration of a RAID stripe in some embodiments. The assignment and use of the authorities 168 thus establishes an indirection to data. Indirection may be referred to as the ability to reference data indirectly, in this case via an authority 168, in accordance with some embodiments. A segment identifies a set of non-volatile solid state storage 152 and a local identifier into the set of non-volatile solid state storage 152 that may contain data. In some embodiments, the local identifier is an offset into the device and may be reused sequentially by multiple segments. In other embodiments the local identifier is unique for a specific segment and never reused. The offsets in the non-volatile solid state storage 152 are applied to locating data for writing to or reading from the non-volatile solid state storage 152 (in the form of a RAID stripe). Data is striped across multiple units of non-volatile solid state storage 152, which may include or be different from the non-volatile solid state storage 152 having the authority 168 for a particular data segment.

If there is a change in where a particular segment of data is located, e.g., during a data move or a data reconstruction, the authority 168 for that data segment should be consulted, at that non-volatile solid state storage 152 or storage node 150 having that authority 168. In order to locate a particular piece of data, embodiments calculate a hash value for a data segment or apply an inode number or a data segment number. The output of this operation points to a non-volatile solid state storage 152 having the authority 168 for that particular piece of data. In some embodiments there are two stages to this operation. The first stage maps an entity identifier (ID), e.g., a segment number, inode number, or directory number to an authority identifier. This mapping may include a calculation such as a hash or a bit mask. The second stage is mapping the authority identifier to a particular non-volatile solid state storage 152, which may be done through an explicit mapping. The operation is repeatable, so that when the calculation is performed, the result of the calculation repeatably and reliably points to a particular non-volatile solid state storage 152 having that authority 168. The operation may include the set of reachable storage nodes as input. If the set of reachable non-volatile solid state storage units changes the optimal set changes. In some embodiments, the persisted value is the current assignment (which is always true) and the calculated value is the target assignment the cluster will attempt to reconfigure towards. This calculation may be used to determine the optimal non-volatile solid state storage 152 for an authority in the presence of a set of non-volatile solid state storage 152 that are reachable and constitute the same cluster. The calculation also determines an ordered set of peer non-volatile solid state storage 152 that will also record the authority to non-volatile solid state storage mapping so that the authority may be determined even if the assigned non-volatile solid state storage is unreachable. A duplicate or substitute authority 168 may be consulted if a specific authority 168 is unavailable in some embodiments.

With reference to FIG. 2A and 2B, two of the many tasks of the CPU 156 on a storage node 150 are to break up write data, and reassemble read data. When the system has determined that data is to be written, the authority 168 for that data is located as above. When the segment ID for data is already determined the request to write is forwarded to the non-volatile solid state storage 152 currently determined to be the host of the authority 168 determined from the segment. The host CPU 156 of the storage node 150, on which the non-volatile solid state storage 152 and corresponding authority 168 reside, then breaks up or shards the data and transmits the data out to various non-volatile solid state storage 152. The transmitted data is written as a data stripe in accordance with an erasure coding scheme. In some embodiments, data is requested to be pulled, and in other embodiments, data is pushed. In reverse, when data is read, the authority 168 for the segment ID containing the data is located as described above. The host CPU 156 of the storage node 150 on which the non-volatile solid state storage 152 and corresponding authority 168 reside requests the data from the non-volatile solid state storage and corresponding storage nodes pointed to by the authority. In some embodiments the data is read from flash storage as a data stripe. The host CPU 156 of storage node 150 then reassembles the read data, correcting any errors (if present) according to the appropriate erasure coding scheme, and forwards the reassembled data to the network. In further embodiments, some or all of these tasks can be handled in the non-volatile solid state storage 152. In some embodiments, the segment host requests the data be sent to storage node 150 by requesting pages from storage and then sending the data to the storage node making the original request.

In embodiments, authorities 168 operate to determine how operations will proceed against particular logical elements. Each of the logical elements may be operated on through a particular authority across a plurality of storage controllers of a storage system. The authorities 168 may communicate with the plurality of storage controllers so that the plurality of storage controllers collectively perform operations against those particular logical elements.

In embodiments, logical elements could be, for example, files, directories, object buckets, individual objects, delineated parts of files or objects, other forms of key-value pair databases, or tables. In embodiments, performing an operation can involve, for example, ensuring consistency, structural integrity, and/or recoverability with other operations against the same logical element, reading metadata and data associated with that logical element, determining what data should be written durably into the storage system to persist any changes for the operation, or where metadata and data can be determined to be stored across modular storage devices attached to a plurality of the storage controllers in the storage system.

In some embodiments the operations are token based transactions to efficiently communicate within a distributed system. Each transaction may be accompanied by or associated with a token, which gives permission to execute the transaction. The authorities 168 are able to maintain a pre-transaction state of the system until completion of the operation in some embodiments. The token based communication may be accomplished without a global lock across the system, and also enables restart of an operation in case of a disruption or other failure.

In some systems, for example in UNIX-style file systems, data is handled with an index node or inode, which specifies a data structure that represents an object in a file system. The object could be a file or a directory, for example. Metadata may accompany the object, as attributes such as permission data and a creation timestamp, among other attributes. A segment number could be assigned to all or a portion of such an object in a file system. In other systems, data segments are handled with a segment number assigned elsewhere. For purposes of discussion, the unit of distribution is an entity, and an entity can be a file, a directory or a segment. That is, entities are units of data or metadata stored by a storage system. Entities are grouped into sets called authorities. Each authority has an authority owner, which is a storage node that has the exclusive right to update the entities in the authority. In other words, a storage node contains the authority, and that the authority, in turn, contains entities.

A segment is a logical container of data in accordance with some embodiments. A segment is an address space between medium address space and physical flash locations, i.e., the data segment number, are in this address space. Segments may also contain meta-data, which enable data redundancy to be restored (rewritten to different flash locations or devices) without the involvement of higher level software. In one embodiment, an internal format of a segment contains client data and medium mappings to determine the position of that data. Each data segment is protected, e.g., from memory and other failures, by breaking the segment into a number of data and parity shards, where applicable. The data and parity shards are distributed, i.e., striped, across non-volatile solid state storage 152 coupled to the host CPUs 156 (See FIGS. 2E and 2G) in accordance with an erasure coding scheme. Usage of the term segments refers to the container and its place in the address space of segments in some embodiments. Usage of the term stripe refers to the same set of shards as a segment and includes how the shards are distributed along with redundancy or parity information in accordance with some embodiments.

A series of address-space transformations takes place across an entire storage system. At the top are the directory entries (file names) which link to an inode. Inodes point into medium address space, where data is logically stored. Medium addresses may be mapped through a series of indirect mediums to spread the load of large files, or implement data services like deduplication or snapshots. Segment addresses are then translated into physical flash locations. Physical flash locations have an address range bounded by the amount of flash in the system in accordance with some embodiments. Medium addresses and segment addresses are logical containers, and in some embodiments use a 128 bit or larger identifier so as to be practically infinite, with a likelihood of reuse calculated as longer than the expected life of the system. Addresses from logical containers are allocated in a hierarchical fashion in some embodiments. Initially, each non-volatile solid state storage 152 unit may be assigned a range of address space. Within this assigned range, the non-volatile solid state storage 152 is able to allocate addresses without synchronization with other non-volatile solid state storage 152.

Data and metadata is stored by a set of underlying storage layouts that are optimized for varying workload patterns and storage devices. These layouts incorporate multiple redundancy schemes, compression formats and index algorithms. Some of these layouts store information about authorities and authority masters, while others store file metadata and file data. The redundancy schemes include error correction codes that tolerate corrupted bits within a single storage device (such as a NAND flash chip), erasure codes that tolerate the failure of multiple storage nodes, and replication schemes that tolerate data center or regional failures. In some embodiments, low density parity check ('LDPC') code is used within a single storage unit. Reed-Solomon encoding is used within a storage cluster, and mirroring is used within a storage grid in some embodiments. Metadata may be stored using an ordered log structured index (such as a Log Structured Merge Tree), and large data may not be stored in a log structured layout.

In order to maintain consistency across multiple copies of an entity, the storage nodes agree implicitly on two things through calculations: (1) the authority that contains the entity, and (2) the storage node that contains the authority. The assignment of entities to authorities can be done by pseudo randomly assigning entities to authorities, by splitting entities into ranges based upon an externally produced key, or by placing a single entity into each authority. Examples of pseudorandom schemes are linear hashing and the Replication Under Scalable Hashing ('RUSH') family of hashes, including Controlled Replication Under Scalable Hashing ('CRUSH'). In some embodiments, pseudo-random assignment is utilized only for assigning authorities to nodes because the set of nodes can change. The set of authorities cannot change so any subjective function may be applied in these embodiments. Some placement schemes automatically place authorities on storage nodes, while other placement schemes rely on an explicit mapping of authorities to storage nodes. In some embodiments, a pseudorandom scheme is utilized to map from each authority to a set of candidate authority owners. A pseudorandom data distribution function related to CRUSH may assign authorities to storage nodes and create a list of where the authorities are assigned. Each storage node has a copy of the pseudorandom data distribution function, and can arrive at the same calculation for distributing, and later finding or locating an authority. Each of the pseudorandom schemes requires the reachable set of storage nodes as input in some embodiments in order to conclude the same target nodes. Once an entity has been placed in an authority, the entity may be stored on physical devices so that no expected failure will lead to unexpected data loss. In some embodiments, rebalancing algorithms attempt to store the copies of all entities within an authority in the same layout and on the same set of machines.

Examples of expected failures include device failures, stolen machines, datacenter fires, and regional disasters, such as nuclear or geological events. Different failures lead to different levels of acceptable data loss. In some embodiments, a stolen storage node impacts neither the security nor the reliability of the system, while depending on system configuration, a regional event could lead to no loss of data, a few seconds/minutes of lost updates, or complete data loss.

In the embodiments, the placement of data for storage redundancy is independent of the placement of authorities for data consistency. In some embodiments, storage nodes that contain authorities do not contain any persistent storage. Instead, the storage nodes are connected to non-volatile solid state storage units that do not contain authorities. The communications interconnect between storage nodes and non-volatile solid state storage units consists of multiple communication technologies and has non-uniform performance and fault tolerance characteristics. In some embodiments, as mentioned above, non-volatile solid state storage units are connected to storage nodes via PCIe, storage nodes are connected together within a single chassis using Ethernet backplane, and chassis are connected together to form a storage cluster. Storage clusters are connected to clients using Ethernet or fiber channel in some embodiments. If multiple storage clusters are configured into a storage grid, the multiple storage clusters are connected using the Internet or other long-distance networking links, such as a "metro scale" link or private link that does not traverse the internet.

Authority owners have the exclusive right to modify entities, to migrate entities from one non-volatile solid state storage unit to another non-volatile solid state storage unit, and to add and remove copies of entities. This allows for maintaining the redundancy of the underlying data. When an authority owner fails, is going to be decommissioned, or is overloaded, the authority is transferred to a new storage node. Transient failures make it non-trivial to ensure that all non-faulty machines agree upon the new authority location. The ambiguity that arises due to transient failures can be achieved automatically by a consensus protocol such as Paxos, hot-warm failover schemes, via manual intervention by a remote system administrator, or by a local hardware administrator (such as by physically removing the failed machine from the cluster, or pressing a button on the failed machine). In some embodiments, a consensus protocol is used, and failover is automatic. If too many failures or replication events occur in too short a time period, the system goes into a self-preservation mode and halts replication and data movement activities until an administrator intervenes in accordance with some embodiments.

As authorities are transferred between storage nodes and authority owners update entities in their authorities, the system transfers messages between the storage nodes and non-volatile solid state storage units. With regard to persistent messages, messages that have different purposes are of different types. Depending on the type of the message, the system maintains different ordering and durability guarantees. As the persistent messages are being processed, the messages are temporarily stored in multiple durable and non-durable storage hardware technologies. In some embodiments, messages are stored in RAM, NVRAM and on NAND flash devices, and a variety of protocols are used in order to make efficient use of each storage medium. Latency-sensitive client requests may be persisted in replicated NVRAM, and then later NAND, while background rebalancing operations are persisted directly to NAND.

Persistent messages are persistently stored prior to being transmitted. This allows the system to continue to serve client requests despite failures and component replacement. Although many hardware components contain unique identifiers that are visible to system administrators, manufacturer, hardware supply chain and ongoing monitoring quality control infrastructure, applications running on top of the infrastructure address virtualize addresses. These virtualized addresses do not change over the lifetime of the storage system, regardless of component failures and replacements. This allows each component of the storage system to be replaced over time without reconfiguration or disruptions of client request processing, i.e., the system supports non-disruptive upgrades.

In some embodiments, the virtualized addresses are stored with sufficient redundancy. A continuous monitoring system correlates hardware and software status and the hardware identifiers. This allows detection and prediction of failures due to faulty components and manufacturing details. The monitoring system also enables the proactive transfer of authorities and entities away from impacted devices before failure occurs by removing the component from the critical path in some embodiments.

FIG. 2C is a multiple level block diagram, showing contents of a storage node 150 and contents of a non-volatile solid state storage 152 of the storage node 150. Data is communicated to and from the storage node 150 by a network interface controller ('NIC') 202 in some embodiments. Each storage node 150 has a CPU 156, and one or more non-volatile solid state storage 152, as discussed above. Moving down one level in FIG. 2C, each non-volatile solid state storage 152 has a relatively fast non-volatile solid state memory, such as nonvolatile random access memory ('NVRAM') 204, and flash memory 206. In some embodiments, NVRAM 204 may be a component that does not require program/erase cycles (DRAM, MRAM, PCM), and can be a memory that can support being written vastly more often than the memory is read from. Moving down another level in FIG. 2C, the NVRAM 204 is implemented in one embodiment as high speed volatile memory, such as dynamic random access memory (DRAM) 216, backed up by energy reserve 218. Energy reserve 218 provides sufficient electrical power to keep the DRAM 216 powered long enough for contents to be transferred to the flash memory 206 in the event of power failure. In some embodiments, energy reserve 218 is a capacitor, super-capacitor, battery, or other device, that supplies a suitable supply of energy sufficient to enable the transfer of the contents of DRAM 216 to a stable storage medium in the case of power loss. The flash memory 206 is implemented as multiple flash dies 222, which may be referred to as packages of flash dies 222 or an array of flash dies 222. It should be appreciated that the flash dies 222 could be packaged in any number of ways, with a single die per package, multiple dies per package (i.e., multichip packages), in hybrid packages, as bare dies on a printed circuit board or other substrate, as encapsulated dies, etc. In the embodiment shown, the non-volatile solid state storage 152 has a controller 212 or other processor, and an input output (I/O) port 210 coupled to the controller 212. I/O port 210 is coupled to the CPU 156 and/or the network interface controller 202 of the flash storage node 150. Flash input output (I/O) port 220 is coupled to the flash dies 222, and a direct memory access unit (DMA) 214 is coupled to the controller 212, the DRAM 216 and the flash dies 222. In the embodiment shown, the I/O port 210, controller 212, DMA unit 214 and flash I/O port 220 are implemented on a programmable logic device ('PLD') 208, e.g., an FPGA. In this embodiment, each flash die 222 has pages, organized as sixteen kB (kilobyte) pages 224, and a register 226 through which data can be written to or read from the flash die 222. In further embodiments, other types of solid-state memory are used in place of, or in addition to flash memory illustrated within flash die 222.

Storage clusters 161, in various embodiments as disclosed herein, can be contrasted with storage arrays in general. The storage nodes 150 are part of a collection that creates the storage cluster 161. Each storage node 150 owns a slice of data and computing required to provide the data. Multiple storage nodes 150 cooperate to store and retrieve the data. Storage memory or storage devices, as used in storage arrays in general, are less involved with processing and manipulating the data. Storage memory or storage devices in a storage array receive commands to read, write, or erase data. The storage memory or storage devices in a storage array are not aware of a larger system in which they are embedded, or what the data means. Storage memory or storage devices in storage arrays can include various types of storage memory, such as RAM, solid state drives, hard disk drives, etc. The non-volatile solid state storage 152 units described herein have multiple interfaces active simultaneously and serving multiple purposes. In some embodiments, some of the functionality of a storage node 150 is shifted into a storage unit 152, transforming the storage unit 152 into a combination of storage unit 152 and storage node 150. Placing computing (relative to storage data) into the storage unit 152 places this computing closer to the data itself. The various system embodiments have a hierarchy of storage node layers with different capabilities. By contrast, in a storage array, a controller owns and knows everything about all of the data that the controller manages in a shelf or storage devices. In a storage cluster 161, multiple controllers in multiple solid state storage 152 units and/or storage nodes 150 can cooperate in various ways (e.g., for erasure coding, data sharding, metadata communication and redundancy, storage capacity expansion or contraction, data recovery, and so on).

FIG. 2D shows a storage server environment, which uses embodiments of the storage nodes 150 and storage 152 units of FIGS. 2A-C. In this version, each non-volatile solid state storage 152 unit has a processor such as controller 212 (see FIG. 2C), an FPGA, flash memory 206, and NVRAM 204 (which is super-capacitor backed DRAM 216, see FIGS. 2B and 2C) on a PCIe board in a chassis 138 (see FIG. 2A). The non-volatile solid state storage 152 unit may be implemented as a single board containing storage, and may be the largest tolerable failure domain inside the chassis. In some embodiments, up to two non-volatile solid state storage 152 units may fail and the device will continue with no data loss.

The physical storage is divided into named regions based on application usage in some embodiments. The NVRAM 204 is a contiguous block of reserved memory in the non-volatile solid state storage 152 DRAM 216, and is backed by NAND flash. NVRAM 204 is logically divided into multiple memory regions written for two as spool (e.g., spool_region). Space within the NVRAM 204 spools is managed by each authority 168 independently. Each device provides an amount of storage space to each authority 168. That authority 168 further manages lifetimes and allocations within that space. Examples of a spool include distributed transactions or notions. When the primary power to a non-volatile solid state storage 152 unit fails, onboard super-capacitors provide a short duration of power hold up. During this holdup interval, the contents of the NVRAM 204 are flushed to flash memory 206. On the next power-on, the contents of the NVRAM 204 are recovered from the flash memory 206.

As for the storage unit controller, the responsibility of the logical "controller" is distributed across each of the blades containing authorities 168. This distribution of logical control is shown in FIG. 2D as a host controller 242, mid-tier controller 244 and storage unit controller(s) 246. Management of the control plane and the storage plane are treated independently, although parts may be physically co-located on the same blade. Each authority 168 effectively serves as an independent controller. Each authority 168 provides its own data and metadata structures, its own background workers, and maintains its own lifecycle.

FIG. 2E is a blade 252 hardware block diagram, showing a control plane 254, compute and storage planes 256, 258, and authorities 168 interacting with underlying physical resources, using embodiments of the storage nodes 150 and storage units 152 of FIGS. 2A-C in the storage server environment of FIG. 2D. The control plane 254 is partitioned into a number of authorities 168 which can use the compute resources in the compute plane 256 to run on any of the blades 252. The storage plane 258 is partitioned into a set of devices, each of which provides access to flash 206 and NVRAM 204 resources. In one embodiment, the compute plane 256 may perform the operations of a storage array controller, as described herein, on one or more devices of the storage plane 258 (e.g., a storage array).

In the compute and storage planes 256, 258 of FIG. 2E, the authorities 168 interact with the underlying physical resources (i.e., devices). From the point of view of an authority 168, its resources are striped over all of the physical devices. From the point of view of a device, it provides resources to all authorities 168, irrespective of where the authorities happen to run. Each authority 168 has allocated or has been allocated one or more partitions 260 of storage memory in the storage units 152, e.g., partitions 260 in flash memory 206 and NVRAM 204. Each authority 168 uses those allocated partitions 260 that belong to it, for writing or reading user data. Authorities can be associated with differing amounts of physical storage of the system. For example, one authority 168 could have a larger number of partitions 260 or larger sized partitions 260 in one or more storage units 152 than one or more other authorities 168.

FIG. 2F depicts elasticity software layers in blades 252 of a storage cluster, in accordance with some embodiments. In the elasticity structure, elasticity software is symmetric, i.e., each blade's compute module 270 runs the three identical layers of processes depicted in FIG. 2F. Storage managers 274 execute read and write requests from other blades 252 for data and metadata stored in local storage unit 152 NVRAM 204 and flash 206. Authorities 168 fulfill client requests by issuing the necessary reads and writes to the blades 252 on whose storage units 152 the corresponding data or metadata resides. Endpoints 272 parse client connection requests received from switch fabric 146 supervisory software, relay the client connection requests to the authorities 168 responsible for fulfillment, and relay the authorities' 168 responses to clients. The symmetric three-layer structure enables the storage system's high degree of concurrency. Elasticity scales out efficiently and reliably in these embodiments. In addition, elasticity implements a unique scale-out technique that balances work evenly across all resources regardless of client access pattern, and maximizes concurrency by eliminating much of the need for inter-blade coordination that typically occurs with conventional distributed locking.

Still referring to FIG. 2F, authorities 168 running in the compute modules 270 of a blade 252 perform the internal operations required to fulfill client requests. One feature of elasticity is that authorities 168 are stateless, i.e., they cache active data and metadata in their own blades' 252 DRAMs for fast access, but the authorities store every update in their NVRAM 204 partitions on three separate blades 252 until the update has been written to flash 206. All the storage system writes to NVRAM 204 are in triplicate to partitions on three separate blades 252 in some embodiments. With triple-mirrored NVRAM 204 and persistent storage protected by parity and Reed-Solomon RAID checksums, the storage system can survive concurrent failure of two blades 252 with no loss of data, metadata, or access to either.

Because authorities 168 are stateless, they can migrate between blades 252. Each authority 168 has a unique identifier. NVRAM 204 and flash 206 partitions are associated with authorities' 168 identifiers, not with the blades 252 on which they are running in some embodiments. Thus, when an authority 168 migrates, the authority 168 continues to manage the same storage partitions from its new location. When a new blade 252 is installed in an embodiment of the storage cluster, the system automatically rebalances load by: partitioning the new blade's 252 storage for use by the system's authorities 168, migrating selected authorities 168 to the new blade 252, starting endpoints 272 on the new blade 252 and including them in the switch fabric's 146 client connection distribution algorithm.

From their new locations, migrated authorities 168 persist the contents of their NVRAM 204 partitions on flash 206, process read and write requests from other authorities 168, and fulfill the client requests that endpoints 272 direct to them. Similarly, if a blade 252 fails or is removed, the system redistributes its authorities 168 among the system's remaining blades 252. The redistributed authorities 168 continue to perform their original functions from their new locations.

FIG. 2G depicts authorities 168 and storage resources in blades 252 of a storage cluster, in accordance with some embodiments. Each authority 168 is exclusively responsible for a partition of the flash 206 and NVRAM 204 on each blade 252. The authority 168 manages the content and integrity of its partitions independently of other authorities 168. Authorities 168 compress incoming data and preserve it temporarily in their NVRAM 204 partitions, and then consolidate, RAID-protect, and persist the data in segments of the storage in their flash 206 partitions. As the authorities 168 write data to flash 206, storage managers 274 can perform flash translation to optimize write performance and maximize media longevity. In the background, authorities 168 can garbage collect space occupied by data that clients have made obsolete by overwriting the data. It should be appreciated that since authorities' 168 partitions are disjoint, there is no need for distributed locking to execute client and writes or to perform background functions.

The embodiments described herein may utilize various software, communication and/or networking protocols. In addition, the configuration of the hardware and/or software may be adjusted to accommodate various protocols. For example, the embodiments may utilize Active Directory, which is a database based system that provides authentication, directory, policy, and other services in a WINDOWS^{TM} environment. In these embodiments, LDAP (Lightweight Directory Access Protocol) is one example application protocol for querying and modifying items in directory service providers such as Active Directory. In some embodiments, a network lock manager ('NLM') is utilized as a facility that works in cooperation with the Network File System ('NFS') to provide a System V style of advisory file and record locking over a network. The Server Message Block ('SMB') protocol, one version of which is also known as Common Internet File System ('CIFS'), may be integrated with the storage systems discussed herein. SMB operates as an application-layer network protocol typically used for providing shared access to files, printers, and serial ports and miscellaneous communications between nodes on a network. SMB also provides an authenticated inter-process communication mechanism. AMAZON^{TM} S3 (Simple Storage Service) is a web service offered by Amazon Web Services, and the systems described herein may interface with Amazon S3 through web services interfaces (REST (representational state transfer), SOAP (simple object access protocol), and BitTorrent). A RESTful API (application programming interface) breaks down a transaction to create a series of small modules. Each module addresses a particular underlying part of the transaction. The control or permissions provided with these embodiments, especially for object data, may include utilization of an access control list ('ACL'). The ACL is a list of permissions attached to an object and the ACL specifies which users or system processes are granted access to objects, as well as what operations are allowed on given objects. The systems may utilize Internet Protocol version 6 ('IPv6'), as well as IPv4, for the communications protocol that provides an identification and location system for computers on networks and routes traffic across the Internet. The routing of packets between networked systems may include Equal-cost multi-path routing ('ECMP'), which is a routing strategy where next-hop packet forwarding to a single destination can occur over multiple "best paths" which tie for top place in routing metric calculations. Multi-path routing can be used in conjunction with most routing protocols, because it is a per-hop decision limited to a single router. The software may support Multi-tenancy, which is an architecture in which a single instance of a software application serves multiple customers. Each customer may be referred to as a tenant. Tenants may be given the ability to customize some parts of the application, but may not customize the application's code, in some embodiments. The embodiments may maintain audit logs. An audit log is a document that records an event in a computing system. In addition to documenting what resources were accessed, audit log entries typically include destination and source addresses, a timestamp, and user login information for compliance with various regulations. The embodiments may support various key management policies, such as encryption key rotation. In addition, the system may support dynamic root passwords or some variation dynamically changing passwords.

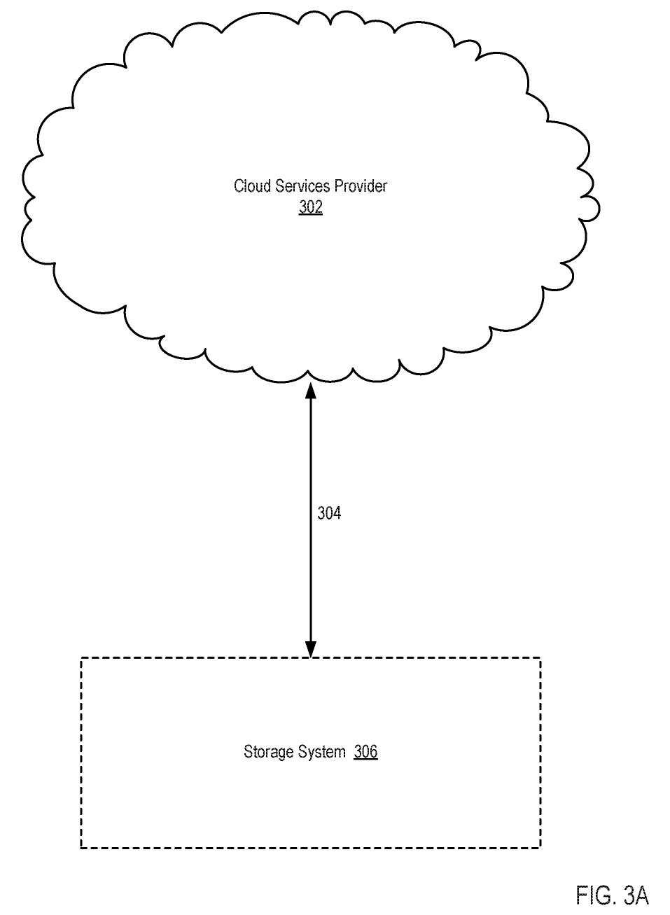

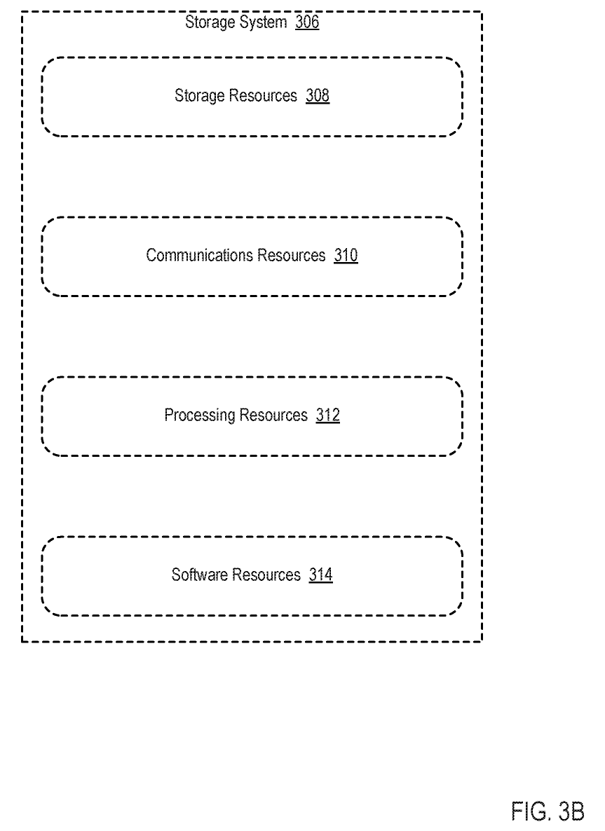

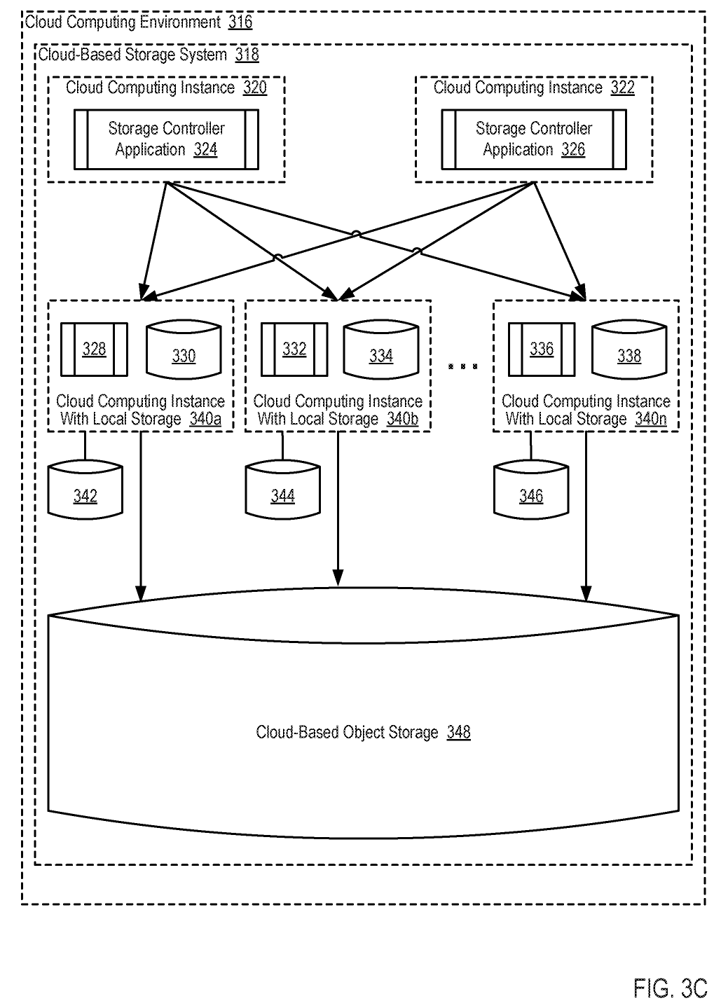

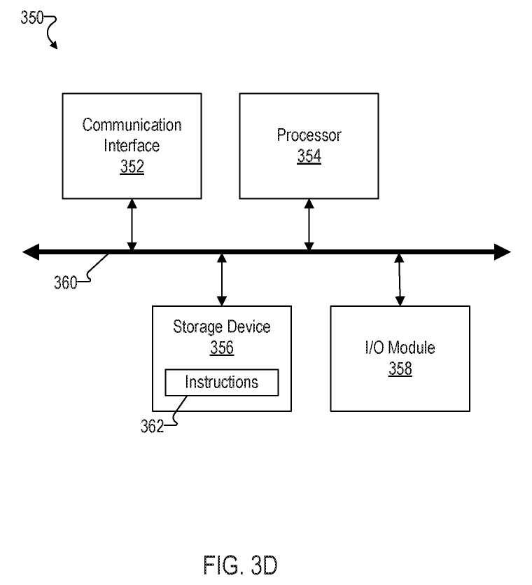

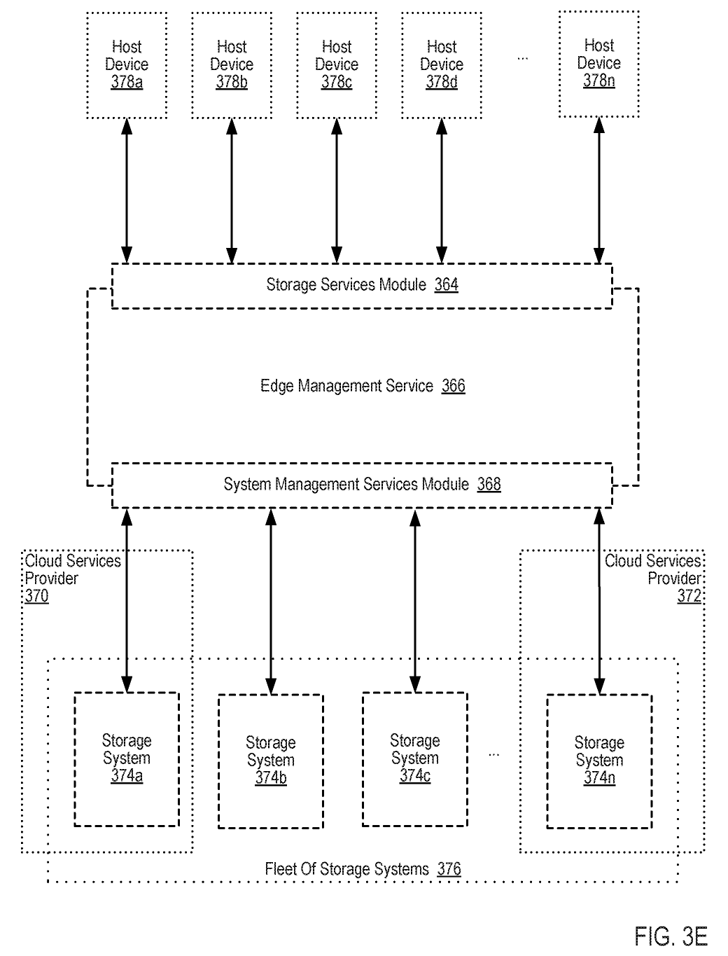

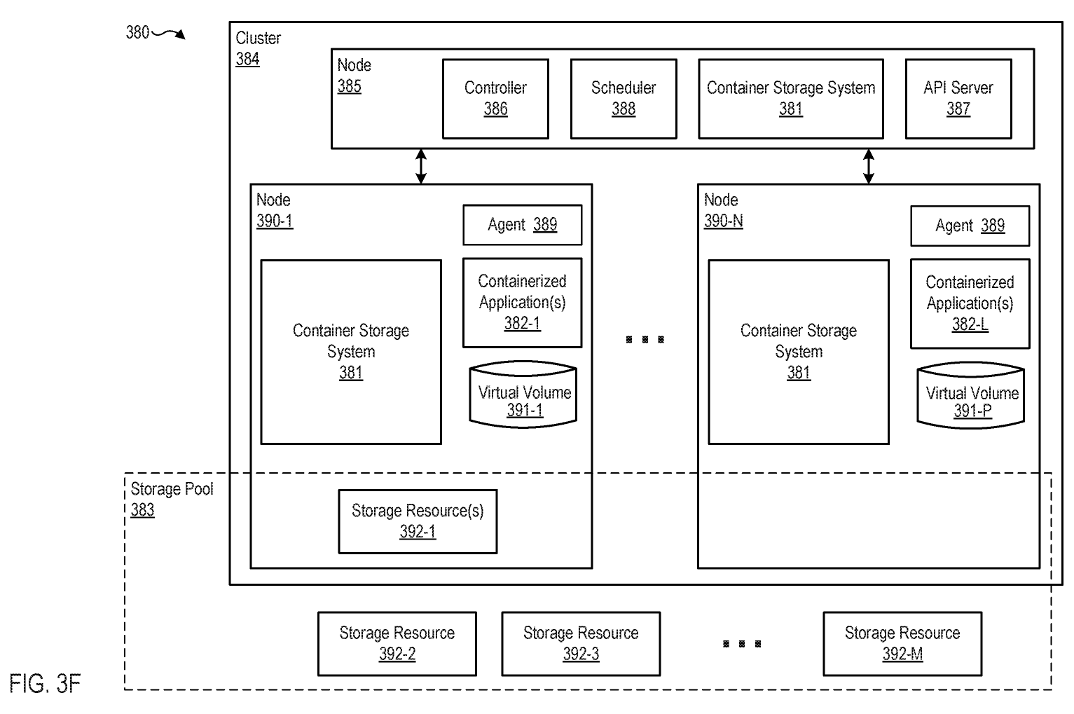

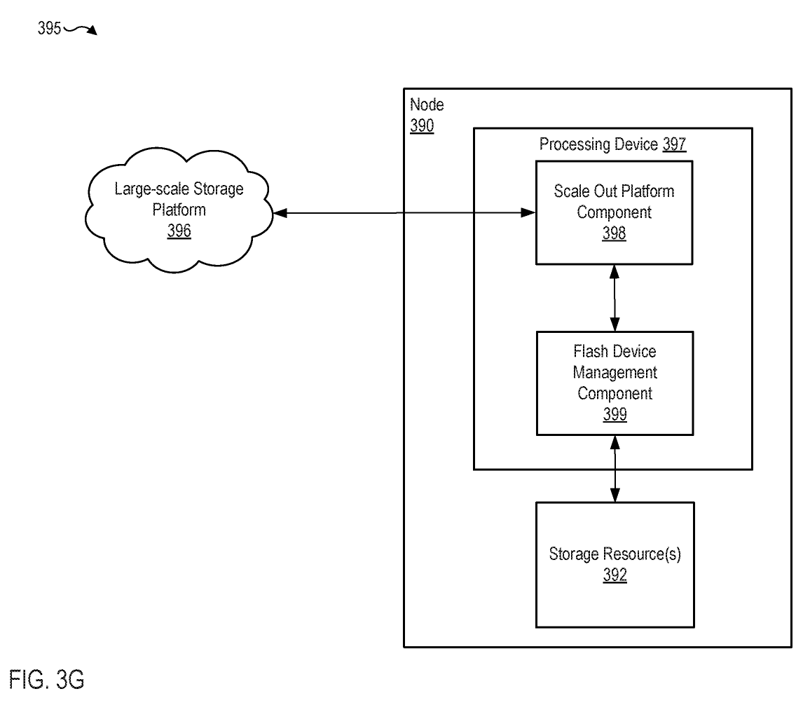

FIG. 3A sets forth a diagram of a storage system 306 that is coupled for data communications with a cloud services provider 302 in accordance with some embodiments. Although depicted in less detail, the storage system 306 depicted in FIG. 3A may be similar to the storage systems described above with reference to FIGS. 1A-1D and 2A-2G. In some embodiments, the storage system 306 depicted in FIG. 3A may be embodied as a storage system that includes imbalanced active/active controllers, as a storage system that includes balanced active/active controllers, as a storage system that includes active/active controllers where less than all of each controller's resources are utilized such that each controller has reserve resources that may be used to support failover, as a storage system that includes fully active/active controllers, as a storage system that includes dataset-segregated controllers, as a storage system that includes dual-layer architectures with front-end controllers and back-end integrated storage controllers, as a storage system that includes scale-out clusters of dual-controller arrays, as well as combinations of such embodiments.

In the example depicted in FIG. 3A, the storage system 306 is coupled to the cloud services provider 302 via a data communications link 304. In such an example, digital information may be exchanged between the storage system 306 and the cloud services provider 302 via the data communications link 304 using one or more data communications protocols. For example, digital information may be exchanged between the storage system 306 and the cloud services provider 302 via the data communications link 304.

The cloud services provider 302 depicted in FIG. 3A may be embodied, for example, as a system and computing environment that provides a vast array of services to users of the cloud services provider 302 through the sharing of computing resources via the data communications link 304. The cloud services provider 302 may provide on-demand access to a shared pool of configurable computing resources.

In the example depicted in FIG. 3A, the cloud services provider 302 may be configured to provide a variety of services to the storage system 306 and users of the storage system 306 through the implementation of various service models. For example, the cloud services provider 302 may be configured to provide services through the implementation of an infrastructure as a service ('IaaS') service model, platform as a service ('PaaS') service model, software as a service ('SaaS') service model, authentication as a service ('AaaS') service model, through the implementation of a storage as a service model, and so on.

In the example depicted in FIG. 3A, the cloud services provider 302 may be embodied, for example, as a private cloud, as a public cloud, or as a combination of a private cloud and public cloud. In an embodiment in which the cloud services provider 302 is embodied as a private cloud, the cloud services provider 302 may be dedicated to providing services to a single organization rather than providing services to multiple organizations. In an embodiment where the cloud services provider 302 is embodied as a public cloud, the cloud services provider 302 may provide services to multiple organizations. In some embodiments, the cloud services provider 302 may be embodied as a hybrid cloud deployment.

Although not explicitly depicted in FIG. 3A, readers will appreciate that a vast amount of additional hardware components and additional software components may be necessary to facilitate the delivery of cloud services to the storage system 306 and users of the storage system 306. For example, the storage system 306 may be coupled to (or even include) a cloud storage gateway. Such a cloud storage gateway may be embodied, for example, as hardware-based or software-based appliance that is located on premises with the storage system 306. Such a cloud storage gateway may operate as a bridge between local applications that are executing on the storage system 306 and remote, cloud-based storage that is utilized by the storage system 306. Through the use of a cloud storage gateway, organizations may move primary iSCSI or NAS to the cloud services provider 302, thereby enabling the organization to save space on their on-premises storage systems. Such a cloud storage gateway may be configured to emulate a disk array, a block-based device, a file server, or other storage system that can translate the SCSI commands, file server commands, or other appropriate command into REST-space protocols that facilitate communications with the cloud services provider 302. In the example depicted in FIG. 3A, the cloud services provider 302 may be configured to provide services to the storage system 306 and users of the storage system 306 through the usage of a SaaS service model.

Although the example depicted in FIG. 3A illustrates the storage system 306 being coupled for data communications with the cloud services provider 302, in other embodiments the storage system 306 may be part of a hybrid cloud deployment in which private cloud elements (e.g., private cloud services, on-premises infrastructure, and so on) and public cloud elements (e.g., public cloud services, infrastructure, and so on that may be provided by one or more cloud services providers) are combined to form a single solution, with orchestration among the various platforms. Such a hybrid cloud deployment may leverage hybrid cloud management software such as, for example, Azure^{TM} Arc from Microsoft^{TM}, that centralize the management of the hybrid cloud deployment to any infrastructure and enable the deployment of services anywhere. In such an example, the hybrid cloud management software may be configured to create, update, and delete resources (both physical and virtual) that form the hybrid cloud deployment, to allocate compute and storage to specific workloads, to monitor workloads and resources for performance, policy compliance, updates and patches, security status, or to perform other tasks.

Readers will appreciate that by pairing the storage systems described herein with one or more cloud services providers, various offerings may be enabled. For example, disaster recovery as a service ('DRaaS') may be provided where cloud resources are utilized to protect applications and data from disruption caused by disaster, including in embodiments where the storage systems may serve as the primary data store. In such embodiments, a total system backup may be taken that allows for business continuity in the event of system failure. Cloud data backup techniques (by themselves or as part of a larger DRaaS solution) may also be integrated into an overall solution that includes the storage systems and cloud services providers described herein.

The storage systems described herein, as well as the cloud services providers, may be utilized to provide a wide array of security features. For example, the storage systems may encrypt data at rest (and data may be sent to and from the storage systems encrypted) and may make use of Key Management-as-a-Service ('KMaaS') to manage encryption keys, keys for locking and unlocking storage devices, and so on. Likewise, cloud data security gateways or similar mechanisms may be utilized to ensure that data stored within the storage systems does not improperly end up being stored in the cloud as part of a cloud data backup operation. Furthermore, microsegmentation or identity-based-segmentation may be utilized in a data center that includes the storage systems or within the cloud services provider, to create secure zones in data centers and cloud deployments that enables the isolation of workloads from one another.

For further explanation, FIG. 3B sets forth a diagram of a storage system 306 in accordance with some embodiments of the present disclosure. Although depicted in less detail, the storage system 306 depicted in FIG. 3B may be similar to the storage systems described above with reference to FIGS. 1A-1D and 2A-2G.

The storage system 306 depicted in FIG. 3B may include a vast amount of storage resources 308, which may be embodied in many forms. For example, the storage resources 308 can include nano-RAM or another form of nonvolatile random access memory that utilizes carbon nanotubes deposited on a substrate, 3D crosspoint non-volatile memory, flash memory including single-level cell ('SLC') NAND flash having one bit of data per cell, multi-level cell ('MLC') NAND flash having two bits of data per cell, triple-level cell ('TLC') NAND flash having three bits of data per cell, quad-level cell ('QLC') NAND flash having four bits of data per cell, penta-level cell ('PLC') NAND flash having five bits of data per cell, or other programming modes having different numbers of bits of data per cell of flash memory. Likewise, the storage resources 308 may include non-volatile magnetoresistive random-access memory ('MRAM'), including spin transfer torque ('STT') MRAM. The example storage resources 308 may alternatively include non-volatile phase-change memory ('PCM'), quantum memory that allows for the storage and retrieval of photonic quantum information, resistive random-access memory ('ReRAM'), storage class memory ('SCM'), or other form of storage resources, including any combination of resources described herein. Readers will appreciate that other forms of computer memories and storage devices may be utilized by the storage systems described above, including DRAM, SRAM, EEPROM, universal memory, and many others. The storage resources 308 depicted in FIG. 3A may be embodied in a variety of form factors, including but not limited to, dual in-line memory modules ('DIMMs'), non-volatile dual in-line memory modules ('NVDIMMs'), M.2, U.2, and others. In some embodiments, the storage resources 308 may include one or more managed flash storage devices, as previously described.

The storage resources 308 depicted in FIG. 3B may include various forms of SCM. SCM may effectively treat fast, non-volatile memory (e.g., NAND flash) as an extension of DRAM such that an entire dataset may be treated as an in-memory dataset that resides entirely in DRAM. SCM may include non-volatile media such as, for example, NAND flash. Such NAND flash may be accessed utilizing NVMe that can use the PCIe bus as its transport, providing for relatively low access latencies compared to older protocols. In fact, the network protocols used for SSDs in all-flash arrays can include NVMe using Ethernet (ROCE, NVME TCP), Fibre Channel (NVMe FC), InfiniBand (iWARP), and others that make it possible to treat fast, non-volatile memory as an extension of DRAM. In view of the fact that DRAM is often byte-addressable and fast, non-volatile memory such as NAND flash is block-addressable, a controller software/hardware stack may be needed to convert the block data to the bytes that are stored in the media. Examples of media and software that may be used as SCM can include, for example, 3D XPoint, Intel Memory Drive Technology, Samsung's Z-SSD, and others.

The example storage system 306 depicted in FIG. 3B may implement a variety of storage architectures. For example, storage systems in accordance with some embodiments of the present disclosure may utilize block storage where data is stored in blocks, and each block essentially acts as an individual hard drive. Storage systems in accordance with some embodiments of the present disclosure may utilize object storage, where data is managed as objects. Each object may include the data itself, a variable amount of metadata, and a globally unique identifier, where object storage can be implemented at multiple levels (e.g., device level, system level, interface level). Storage systems in accordance with some embodiments of the present disclosure utilize file storage in which data is stored in a hierarchical structure. Such data may be saved in files and folders, and presented to both the system storing it and the system retrieving it in the same format.

The example storage system 306 depicted in FIG. 3B may leverage the storage resources described above in a variety of different ways. For example, some portion of the storage resources may be utilized to serve as a write cache, storage resources within the storage system may be utilized as a read cache, or tiering may be achieved within the storage systems by placing data within the storage system in accordance with one or more tiering policies.

The storage system 306 depicted in FIG. 3B also includes communications resources 310 that may be useful in facilitating data communications between components within the storage system 306, as well as data communications between the storage system 306 and computing devices that are outside of the storage system 306, including embodiments where those resources are separated by a relatively vast expanse. The communications resources 310 may be configured to utilize a variety of different protocols and data communication fabrics to facilitate data communications between components within the storage systems as well as computing devices that are outside of the storage system. For example, the communications resources 310 can include fibre channel ('FC') technologies such as FC fabrics and FC protocols that can transport SCSI commands over FC network, FC over ethernet ('FCoE') technologies through which FC frames are encapsulated and transmitted over Ethernet networks, InfiniBand ('IB') technologies in which a switched fabric topology is utilized to facilitate transmissions between channel adapters, NVMe technologies and NVMe over fabrics ('NVMeoF') technologies through which non-volatile storage media attached via a PCIe bus may be accessed, and others. In fact, the storage systems described above may, directly or indirectly, make use of neutrino communication technologies and devices through which information (including binary information) is transmitted using a beam of neutrinos.

The communications resources 310 can also include mechanisms for accessing storage resources 308 within the storage system 306 utilizing serial attached SCSI ('SAS'), serial ATA ('SATA') bus interfaces for connecting storage resources 308 within the storage system 306 to host bus adapters within the storage system 306, internet small computer systems interface ('iSCSI') technologies to provide block-level access to storage resources 308 within the storage system 306, and other communications resources that may be useful in facilitating data communications between components within the storage system 306, as well as data communications between the storage system 306 and computing devices that are outside of the storage system 306.

The storage system 306 depicted in FIG. 3B also includes processing resources 312 that may be useful in executing computer program instructions and performing other computational tasks within the storage system 306. The processing resources 312 may include one or more special purpose processing resources (ASICs, DSPs, FPGAs, SoCs) that are customized for some particular purpose as well as one or more CPUs. The storage system 306 may utilize the processing resources 312 to perform a variety of tasks including, but not limited to, supporting the execution of software resources 314 that will be described in greater detail below.

The storage system 306 depicted in FIG. 3B also includes software resources 314 that, when executed by processing resources 312 within the storage system 306, may perform a vast array of tasks. The software resources 314 may include, for example, one or more modules of computer program instructions that when executed by processing resources 312 within the storage system 306 are useful in carrying out various data protection techniques. Such data protection techniques may be carried out, for example, by system software executing on computer hardware within the storage system, by a cloud services provider, or in other ways. Such data protection techniques can include data archiving, data backup, data replication, data snapshotting, data and database cloning, and other data protection techniques.

The software resources 314 may also include software that is useful in implementing software-defined storage ('SDS'). In such an example, the software resources 314 may include one or more modules of computer program instructions that, when executed, are useful in policy-based provisioning and management of data storage that is independent of the underlying hardware. Such software resources 314 may be useful in implementing storage virtualization to separate the storage hardware from the software that manages the storage hardware.

The software resources 314 may also include software that is useful in facilitating and optimizing I/O operations that are directed to the storage system 306. For example, the software resources 314 may include software modules that perform various data reduction techniques such as, for example, data compression, data deduplication, and others. The software resources 314 may include software modules that intelligently group together I/O operations to facilitate better usage of the underlying storage resource 308, software modules that perform data migration operations to migrate from within a storage system, as well as software modules that perform other functions. Such software resources 314 may be embodied as one or more software containers or in many other ways.

For further explanation, FIG. 3C sets forth an example of a cloud-based storage system 318 in accordance with some embodiments of the present disclosure. In the example depicted in FIG. 3C, the cloud-based storage system 318 is created entirely in a cloud computing environment 316 such as Amazon Web Services ('AWS')^{TM}, Microsoft Azure^{TM}, Google Cloud Platform^{TM}, IBM Cloud^{TM}, Oracle Cloud^{TM}, and others. The cloud-based storage system 318 may be used to provide services similar to the services provided by the storage systems described above.

The cloud-based storage system 318 depicted in FIG. 3C includes two cloud computing instances 320, 322 that each are used to support the execution of a storage controller application 324, 326. The cloud computing instances 320, 322 may be embodied, for example, as instances of cloud computing resources (e.g., virtual machines) that may be provided by the cloud computing environment 316 to support the execution of software applications such as the storage controller application 324, 326. For example, each of the cloud computing instances 320, 322 may execute on an Azure VM, where each Azure VM may include high speed temporary storage that may be leveraged as a cache (e.g., as a read cache). In one embodiment, the cloud computing instances 320, 322 may be embodied as Amazon Elastic Compute Cloud ('EC2') instances. In such an example, an Amazon Machine Image ('AMI') that includes the storage controller application 324, 326 may be booted to create and configure a virtual machine that may execute the storage controller application 324, 326.

In the example method depicted in FIG. 3C, the storage controller application 324, 326 may be embodied as a module of computer program instructions that, when executed, carries out various storage tasks. For example, the storage controller application 324, 326 may be embodied as a module of computer program instructions that, when executed, carries out the same tasks as the controllers 110A, 110B in FIG. 1A described above such as writing data to the cloud-based storage system 318, erasing data from the cloud-based storage system 318, retrieving data from the cloud-based storage system 318, monitoring and reporting of storage device utilization and performance, performing redundancy operations, such as RAID or RAID-like data redundancy operations, compressing data, encrypting data, deduplicating data, and so forth. Readers will appreciate that because there are two cloud computing instances 320, 322 that each include the storage controller application 324, 326, in some embodiments one cloud computing instance 320 may operate as the primary controller as described above while the other cloud computing instance 322 may operate as the secondary controller as described above. The storage controller application 324, 326 depicted in FIG. 3C may include identical source code that is executed within different cloud computing instances 320, 322 such as distinct EC2 instances.

Readers will appreciate that other embodiments that do not include a primary and secondary controller are within the scope of the present disclosure. For example, each cloud computing instance 320, 322 may operate as a primary controller for some portion of the address space supported by the cloud-based storage system 318, each cloud computing instance 320, 322 may operate as a primary controller where the servicing of I/O operations directed to the cloud-based storage system 318 are divided in some other way, and so on. In fact, in other embodiments where costs savings may be prioritized over performance demands, only a single cloud computing instance may exist that contains the storage controller application.

The cloud-based storage system 318 depicted in FIG. 3C includes cloud computing instances 340a, 340b, 340n with local storage 330, 334, 338. The cloud computing instances 340a, 340b, 340n may be embodied, for example, as instances of cloud computing resources that may be provided by the cloud computing environment 316 to support the execution of software applications. The cloud computing instances 340a, 340b, 340n of FIG. 3C may differ from the cloud computing instances 320, 322 described above as the cloud computing instances 340a, 340b, 340n of FIG. 3C have local storage 330, 334, 338 resources whereas the cloud computing instances 320, 322 that support the execution of the storage controller application 324, 326 need not have local storage resources. The cloud computing instances 340a, 340b, 340n with local storage 330, 334, 338 may be embodied, for example, as EC2 M5 instances that include one or more SSDs, as EC2 R5 instances that include one or more SSDs, as EC2 I3 instances that include one or more SSDs, and so on. In some embodiments, the local storage 330, 334, 338 must be embodied as solid-state storage rather than storage that makes use of hard disk drives.

In the example depicted in FIG. 3C, each of the cloud computing instances 340a, 340b, 340n with local storage 330, 334, 338 can include a software daemon 328, 332, 336 that, when executed by a cloud computing instance 340a, 340b, 340n can present itself to the storage controller applications 324, 326 as if the cloud computing instance 340a, 340b, 340n were a physical storage device (e.g., one or more SSDs). In such an example, the software daemon 328, 332, 336 may include computer program instructions similar to those that would normally be contained on a storage device such that the storage controller applications 324, 326 can send and receive the same commands that a storage controller would send to storage devices. In such a way, the storage controller applications 324, 326 may include code that is identical to (or substantially identical to) the code that would be executed by the controllers in the storage systems described above. In embodiments, communications between the storage controller applications 324, 326 and the cloud computing instances 340a, 340b, 340n may utilize iSCSI, NVMe over TCP, messaging, a custom protocol, or in some other mechanism.

In the example depicted in FIG. 3C, each of the cloud computing instances 340a, 340b, 340n with local storage 330, 334, 338 may also be coupled to block storage 342, 344, 346 that is offered by the cloud computing environment 316 such as, for example, as Amazon Elastic Block Store ('EBS') volumes. In such an example, the block storage 342, 344, 346 that is offered by the cloud computing environment 316 may be utilized in a manner that is similar to how the NVRAM devices described above are utilized, as the software daemon 328, 332, 336 (or some other module) that is executing within a particular cloud computing instance 340a, 340b, 340n may, upon receiving a request to write data, initiate a write of the data to its attached EBS volume as well as a write of the data to its local storage 330, 334, 338 resources. In some alternative embodiments, data may only be written to the local storage 330, 334, 338 resources within a particular cloud computing instance 340a, 340b, 340n. In an alternative embodiment, rather than using the block storage 342, 344, 346 that is offered by the cloud computing environment 316 as NVRAM, actual RAM on each of the cloud computing instances 340a, 340b, 340n with local storage 330, 334, 338 may be used as NVRAM, thereby decreasing network utilization costs that would be associated with using an EBS volume as the NVRAM. In yet another embodiment, high performance block storage resources such as one or more Azure Ultra Disks may be utilized as the NVRAM.

When a request to write data is received by a particular cloud computing instance 340a, 340b, 340n with local storage 330, 334, 338, the software daemon 328, 332, 336 may be configured to not only write the data to its own local storage 330, 334, 338 resources and any appropriate block storage 342, 344, 346 resources, but the software daemon 328, 332, 336 may also be configured to write the data to cloud-based object storage 348 that is attached to the particular cloud computing instance 340a, 340b, 340n. The cloud-based object storage 348 that is attached to the particular cloud computing instance 340a, 340b, 340n may be embodied, for example, as Amazon Simple Storage Service ('S3'). In other embodiments, the cloud computing instances 320, 322 that each include the storage controller application 324, 326 may initiate the storage of the data in the local storage 330, 334, 338 of the cloud computing instances 340a, 340b, 340n and the cloud-based object storage 348. In other embodiments, rather than using both the cloud computing instances 340a, 340b, 340n with local storage 330, 334, 338 (also referred to herein as ‘virtual drives’) and the cloud-based object storage 348 to store data, a persistent storage layer may be implemented in other ways. For example, one or more Azure Ultra disks may be used to persistently store data (e.g., after the data has been written to the NVRAM layer). In an embodiment where one or more Azure Ultra disks may be used to persistently store data, the usage of a cloud-based object storage 348 may be eliminated such that data is only stored persistently in the Azure Ultra disks without also writing the data to an object storage layer.

While the local storage 330, 334, 338 resources and the block storage 342, 344, 346 resources that are utilized by the cloud computing instances 340a, 340b, 340n may support block-level access, the cloud-based object storage 348 that is attached to the particular cloud computing instance 340a, 340b, 340n supports only object-based access. The software daemon 328, 332, 336 may therefore be configured to take blocks of data, package those blocks into objects, and write the objects to the cloud-based object storage 348 that is attached to the particular cloud computing instance 340a, 340b, 340n.

In some embodiments, all data that is stored by the cloud-based storage system 318 may be stored in both: 1) the cloud-based object storage 348, and 2) at least one of the local storage 330, 334, 338 resources or block storage 342, 344, 346 resources that are utilized by the cloud computing instances 340a, 340b, 340n. In such embodiments, the local storage 330, 334, 338 resources and block storage 342, 344, 346 resources that are utilized by the cloud computing instances 340a, 340b, 340n may effectively operate as cache that generally includes all data that is also stored in S3, such that all reads of data may be serviced by the cloud computing instances 340a, 340b, 340n without requiring the cloud computing instances 340a, 340b, 340n to access the cloud-based object storage 348. Readers will appreciate that in other embodiments, however, all data that is stored by the cloud-based storage system 318 may be stored in the cloud-based object storage 348, but less than all data that is stored by the cloud-based storage system 318 may be stored in at least one of the local storage 330, 334, 338 resources or block storage 342, 344, 346 resources that are utilized by the cloud computing instances 340a, 340b, 340n. In such an example, various policies may be utilized to determine which subset of the data that is stored by the cloud-based storage system 318 should reside in both: 1) the cloud-based object storage 348, and 2) at least one of the local storage 330, 334, 338 resources or block storage 342, 344, 346 resources that are utilized by the cloud computing instances 340a, 340b, 340n.

One or more modules of computer program instructions that are executing within the cloud-based storage system 318 (e.g., a monitoring module that is executing on its own EC2 instance) may be designed to handle the failure of one or more of the cloud computing instances 340a, 340b, 340n with local storage 330, 334, 338. In such an example, the monitoring module may handle the failure of one or more of the cloud computing instances 340a, 340b, 340n with local storage 330, 334, 338 by creating one or more new cloud computing instances with local storage, retrieving data that was stored on the failed cloud computing instances 340a, 340b, 340n from the cloud-based object storage 348, and storing the data retrieved from the cloud-based object storage 348 in local storage on the newly created cloud computing instances. Readers will appreciate that many variants of this process may be implemented.

Readers will appreciate that various performance aspects of the cloud-based storage system 318 may be monitored (e.g., by a monitoring module that is executing in an EC2 instance) such that the cloud-based storage system 318 can be scaled-up or scaled-out as needed. For example, if the cloud computing instances 320, 322 that are used to support the execution of a storage controller application 324, 326 are undersized and not sufficiently servicing the I/O requests that are issued by users of the cloud-based storage system 318, a monitoring module may create a new, more powerful cloud computing instance (e.g., a cloud computing instance of a type that includes more processing power, more memory, etc…) that includes the storage controller application such that the new, more powerful cloud computing instance can begin operating as the primary controller. Likewise, if the monitoring module determines that the cloud computing instances 320, 322 that are used to support the execution of a storage controller application 324, 326 are oversized and that cost savings could be gained by switching to a smaller, less powerful cloud computing instance, the monitoring module may create a new, less powerful cloud computing instance that includes the storage controller application such that the new, less powerful cloud computing instance can begin operating as the primary controller.

The storage systems described above may carry out intelligent data backup techniques through which data stored in the storage system may be copied and stored in a distinct location to avoid data loss in the event of equipment failure or some other form of catastrophe. For example, the storage systems described above may be configured to examine each backup to avoid restoring the storage system to an undesirable state. Consider an example in which malware infects the storage system. In such an example, the storage system may include software resources 314 that can scan each backup to identify backups that were captured before the malware infected the storage system and those backups that were captured after the malware infected the storage system. In such an example, the storage system may restore itself from a backup that does not include the malware - or at least not restore the portions of a backup that contained the malware. In such an example, the storage system may include software resources 314 that can scan each backup to identify the presences of malware (or a virus, or some other undesirable), for example, by identifying write operations that were serviced by the storage system and originated from a network subnet that is suspected to have delivered the malware, by identifying write operations that were serviced by the storage system and originated from a user that is suspected to have delivered the malware, by identifying write operations that were serviced by the storage system and examining the content of the write operation against fingerprints of the malware, and in many other ways.

Readers will further appreciate that the backups (often in the form of one or more snapshots) may also be utilized to perform rapid recovery of the storage system. Consider an example in which the storage system is infected with ransomware that locks users out of the storage system. In such an example, software resources 314 within the storage system may be configured to detect the presence of ransomware and may be further configured to restore the storage system to a point-in-time, using the retained backups, prior to the point-in-time at which the ransomware infected the storage system. In such an example, the presence of ransomware may be explicitly detected through the use of software tools utilized by the system, through the use of a key (e.g., a USB drive) that is inserted into the storage system, or in a similar way. The presence of ransomware may be inferred in response to system activity meeting a predetermined fingerprint (e.g., no reads or writes coming into the system for a predetermined period of time).

Readers will appreciate that the various components described above may be grouped into one or more optimized computing packages as converged infrastructures. Such converged infrastructures may include pools of computers, storage and networking resources that can be shared by multiple applications and managed in a collective manner using policy-driven processes. Such converged infrastructures may be implemented with a converged infrastructure reference architecture, with standalone appliances, with a software driven hyper-converged approach (e.g., hyper-converged infrastructures), or in other ways.

Readers will appreciate that the storage systems described in this disclosure may be useful for supporting various types of software applications. In fact, the storage systems may be ‘application aware’ in the sense that the storage systems may obtain, maintain, or otherwise have access to information describing connected applications (e.g., applications that utilize the storage systems) to optimize the operation of the storage system based on intelligence about the applications and their utilization patterns. For example, the storage system may optimize data layouts, optimize caching behaviors, optimize ‘QoS’ levels, or perform some other optimization that is designed to improve the storage performance that is experienced by the application.

In view of the fact that the storage systems include compute resources, storage resources, and a wide variety of other resources, the storage systems may be well suited to support applications that are resource intensive such as, for example, AI applications. AI applications may be deployed in a variety of fields, including: predictive maintenance in manufacturing and related fields, healthcare applications such as patient data & risk analytics, retail and marketing deployments, supply chains solutions, fintech solutions such as business analytics & reporting tools, operational deployments such as real-time analytics tools, application performance management tools, IT infrastructure management tools, and many others.

The storage systems described above may also be well suited to support other types of applications that are resource intensive such as, for example, machine learning applications. Machine learning applications may perform various types of data analysis to automate analytical model building. Using algorithms that iteratively learn from data, machine learning applications can enable computers to learn without being explicitly programmed. One particular area of machine learning is referred to as reinforcement learning, which involves taking suitable actions to maximize reward in a particular situation.

In addition to the resources already described, the storage systems described above may also include graphics processing units ('GPUs'), occasionally referred to as visual processing unit ('VPUs'). Such GPUs may be embodied as specialized electronic circuits that rapidly manipulate and alter memory to accelerate the creation of images in a frame buffer intended for output to a display device. Such GPUs may be included within any of the computing devices that are part of the storage systems described above, including as one of many individually scalable components of a storage system, where other examples of individually scalable components of such storage system can include storage components, memory components, compute components (e.g., CPUs, FPGAs, ASICs), networking components, software components, and others. In addition to GPUs, the storage systems described above may also include neural network processors ('NNPs') for use in various aspects of neural network processing. Such NNPs may be used in place of (or in addition to) GPUs and may also be independently scalable.

As described above, the storage systems described herein may be configured to support artificial intelligence applications, machine learning applications, big data analytics applications, and many other types of applications. The rapid growth in these sort of applications is being driven by three technologies: deep learning (DL), GPU processors, and Big Data. Deep learning is a computing model that makes use of massively parallel neural networks inspired by the human brain. Instead of experts handcrafting software, a deep learning model writes its own software by learning from lots of examples. Such GPUs may include thousands of cores that are well-suited to run algorithms that loosely represent the parallel nature of the human brain.

Data is central to modern AI and deep learning algorithms. Before training can commence, a challenge that may need to be addressed involves collecting labeled data, which can be crucial for training an accurate AI model. In some cases, a full-scale AI deployment may be required to continuously collect, clean, transform, label, and store large volumes of data. The inclusion of additional high-quality data points can directly contribute to improved model accuracy and enhanced insights. Data samples may undergo a sequence of processing steps that can include ingesting data from external sources into the training system and storing it in raw form, cleaning and transforming the data into a training-ready format while associating it with appropriate labels, conducting parameter and model exploration by testing on smaller datasets and iterating to identify candidates for deployment, executing training phases that may randomly select from both recent and historical samples for processing on production GPU servers to update model parameters, and evaluating accuracy using a reserved portion of data not seen during training. This overall lifecycle may apply not only to deep learning or neural networks but also to any form of parallelized machine learning. For instance, traditional machine learning approaches may rely on CPU-based computation rather than GPUs, while still utilizing similar data ingestion and training workflows. A centralized, shared storage hub can serve as a coordination point across these stages, potentially reducing the need for duplicating data between ingestion, preprocessing, and training. Since ingested data is rarely used for a single purpose, shared storage can provide the flexibility to train multiple models or to apply traditional analytical methods without requiring redundant data handling.

It will be appreciated that each stage of the AI data pipeline may impose distinct demands on the data hub, such as the underlying storage system or systems. A scale-out storage solution must maintain high performance across varied access patterns and workloads, including both small, metadata-intensive and large files, as well as random and sequential access, with varying degrees of concurrency. The storage systems described herein may function as an effective AI data hub by supporting unstructured workloads. Ideally, data is ingested and stored on the same data hub that subsequent stages utilize, thereby reducing or eliminating unnecessary data copying. The intermediate processing stages may be executed on standard compute servers, which may optionally include GPUs, while the final training stage typically runs on GPU-accelerated servers. In some cases, a production pipeline may operate in parallel with an experimental pipeline on the same dataset. Additionally, GPU servers may be used independently to train separate models or combined to train a larger model, potentially across multiple systems for distributed execution. If the shared storage tier lacks sufficient speed, each phase may require local data copying, which can introduce delays due to repeated staging. An ideal data hub for AI training delivers performance comparable to local server storage while maintaining the simplicity and speed needed to support concurrent operation across all pipeline stages.

In order for the storage systems described above to serve as a data hub or as part of an AI deployment, in some embodiments the storage systems may be configured to provide DMA between storage devices that are included in the storage systems and one or more GPUs that are used in an AI or big data analytics pipeline. The one or more GPUs may be coupled to the storage system, for example, via NVMe-oF such that bottlenecks such as the host CPU can be bypassed and the storage system (or one of the components contained therein) can directly access GPU memory. In such an example, the storage systems may leverage API hooks to the GPUs to transfer data directly to the GPUs. For example, the GPUs may be embodied as Nvidia^{TM} GPUs and the storage systems may support GPUDirect Storage ('GDS') software, or have similar proprietary software, that enables the storage system to transfer data to the GPUs via RDMA or similar mechanism.

Readers will appreciate that, as part of an effort to support AI workloads, the storage systems described above may be configured to operate as a vector database that stores data as vectors (i.e., as mathematical representations of data), where the vector database is designed to efficiently store and query high-dimensional vector data. For example, the storage systems may operate as a vector database that stores vector embeddings that can be useful in machine learning and AI applications, including generative AI applications such as Large Language Models (‘LLMs’). In such embodiments, metadata that is managed by the storage system controllers or by some other entity may be used to manage and identify entries in the vector database. In such embodiments, the vector representations may not be directly stored in a database, but instead the metadata may describe how to generate the vector representations from the underlying data. Alternatively, the storage systems may be used to provide the storage for a vector database, such that the storage systems are effectively preconfigured to provide the functionality of a vector database. In such an example, the vector database may be accessed via APIs provided by the storage system controllers, via one or more APIs that are provided in some other way, via one or more CLIs, or in some other way.

The storage systems described above may, either alone or in combination with other computing devices, be used to support in-memory computing applications. In-memory computing involves the storage of information in RAM that is distributed across a cluster of computers. Readers will appreciate that the storage systems described above, especially those that are configurable with customizable amounts of processing resources, storage resources, and memory resources (e.g., those systems in which blades contain configurable amounts of each type of resource), may be configured in a way so as to provide an infrastructure that can support in-memory computing. Likewise, the storage systems described above may include component parts (e.g., NVDIMMs, 3D crosspoint storage that provide fast random access memory that is persistent) that can actually provide for an improved in-memory computing environment as compared to in-memory computing environments that rely on RAM distributed across dedicated servers.

Readers will further appreciate that in some embodiments, the storage systems described above may be paired with other resources to support the applications described above. For example, one infrastructure could include primary compute in the form of servers and workstations which specialize in using General-purpose computing on graphics processing units ('GPGPU') to accelerate deep learning applications that are interconnected into a computation engine to train parameters for deep neural networks. Each system may have Ethernet external connectivity, InfiniBand external connectivity, some other form of external connectivity, or some combination thereof. In such an example, the GPUs can be grouped for a single large training or used independently to train multiple models. The infrastructure could also include a storage system such as those described above to provide, for example, a scale-out all-flash file or object store through which data can be accessed via high-performance protocols such as NFS, S3, and so on. The infrastructure can also include, for example, redundant top-of-rack Ethernet switches connected to storage and compute via ports in MLAG port channels for redundancy. The infrastructure could also include additional compute in the form of whitebox servers, optionally with GPUs, for data ingestion, pre-processing, and model debugging. Readers will appreciate that additional infrastructures are also possible.

It will be appreciated that the storage systems described above may also be deployed at the network edge, where they may support edge computing by enabling data processing closer to the data source. Such edge deployments may optimize cloud computing systems by moving applications, data, and computing services toward the periphery of the network. These storage systems may provide local compute, storage, and networking capabilities, allowing computational tasks to be executed, data to be stored, and cloud services to be accessed through the edge system itself. By performing operations locally at the edge, the use of expensive cloud-based resources may be reduced, and in some cases, performance may improve compared to approaches that rely more heavily on centralized cloud infrastructure.

The storage systems may also function, either individually or together with other computing resources, as a network edge platform that integrates compute resources, storage capacity, networking functionality, cloud technologies, and network virtualization. Depending on the implementation, the edge platform may assume roles similar to various network facilities, including customer premises, backhaul aggregation nodes, Points of Presence, or regional data centers. Network workloads, such as Virtual Network Functions, may be executed on this platform using a combination of containers and virtual machines, potentially managed by controllers and schedulers that are not physically located with the underlying data resources. These functions may be decomposed into microservices that operate as control planes, user planes, data planes, or state machines, allowing each component to be independently optimized and scaled. The user and data planes may be supported by various types of hardware accelerators, including those embedded in server platforms such as Field Programmable Gate Arrays and Smart Network Interface Cards, as well as Software-Defined Networking-enabled merchant silicon and programmable Application-Specific Integrated Circuits.

In addition, the storage systems described above may be adapted for big data analytics, including use within composable analytics pipelines. Containerized analytics architectures may be employed to increase modularity and flexibility. Big data analytics may involve processing large and diverse data sets to identify patterns, correlations, trends, preferences, and other insights that support improved business decision-making. As part of this process, semi-structured and unstructured data sources (e.g., such as internet clickstream activity, web server logs, social media content, customer communications, survey responses, call-detail records, and sensor data from Internet-of-Things devices) may be transformed into structured forms suitable for analysis.

The storage systems may also support artificial intelligence platforms designed to enable autonomous storage management. These platforms may deliver predictive intelligence by collecting and analyzing extensive telemetry data generated by the storage systems. They may provide features for intelligent management, diagnostics, and operational insight, including the ability to predict capacity and performance needs, recommend workload deployments, and optimize system behavior. Incoming telemetry may be evaluated against a library of known issue signatures to proactively identify/resolve potential faults before environments are affected. Other performance-related variables may also be tracked to forecast system load and behavior.

Furthermore, the storage systems may support the sequential or concurrent execution of artificial intelligence, machine learning, data analytics, data transformation, and related computational tasks that collectively form an artificial intelligence ladder. This ladder may represent a complete data science pipeline in which each stage builds upon the capabilities of the previous one. For example, artificial intelligence functionality may depend on prior machine learning, which may in turn depend on analytics, which itself may rely on proper data modeling and organization. Each of these elements may serve as a distinct rung in the ladder that, when combined, supports the implementation of a sophisticated artificial intelligence solution.

The storage systems described above may also be part of a multi-cloud environment in which multiple cloud computing and storage services are deployed in a single heterogeneous architecture. In order to facilitate the operation of such a multi-cloud environment, DevOps tools may be deployed to enable orchestration across clouds. Likewise, continuous development and continuous integration tools may be deployed to standardize processes around continuous integration and delivery, new feature rollout and provisioning cloud workloads. By standardizing these processes, a multi-cloud strategy may be implemented that enables the utilization of the best provider for each workload.

The storage systems described above may also be paired with FPGA-accelerated servers as part of a larger AI or ML infrastructure. Such FPGA-accelerated servers may reside near (e.g., in the same data center) the storage systems described above or even incorporated into an appliance that includes one or more storage systems, one or more FPGA-accelerated servers, networking infrastructure that supports communications between the one or more storage systems and the one or more FPGA-accelerated servers, as well as other hardware and software components. Alternatively, FPGA-accelerated servers may reside within a cloud computing environment that may be used to perform compute-related tasks for AI and ML jobs. Any of the embodiments described above may be used to collectively serve as a FPGA-based AI or ML platform. Readers will appreciate that, in some embodiments of the FPGA-based AI or ML platform, the FPGAs that are contained within the FPGA-accelerated servers may be reconfigured for different types of ML models (e.g., LSTMs, CNNs, GRUs). The ability to reconfigure the FPGAs that are contained within the FPGA-accelerated servers may enable the acceleration of a ML or AI application based on the most optimal numerical precision and memory model being used. Readers will appreciate that by treating the collection of FPGA-accelerated servers as a pool of FPGAs, any CPU in the data center may utilize the pool of FPGAs as a shared hardware microservice, rather than limiting a server to dedicated accelerators plugged into it.

The FPGA-accelerated servers and the GPU-accelerated servers described above may implement a model of computing where, rather than keeping a small amount of data in a CPU and running a long stream of instructions over it as occurred in more traditional computing models, the machine learning model and parameters are pinned into the high-bandwidth on-chip memory with lots of data streaming through the high-bandwidth on-chip memory. FPGAs may even be more efficient than GPUs for this computing model, as the FPGAs can be programmed with only the instructions needed to run this kind of computing model.

The storage systems described above may be configured to provide parallel storage, for example, through the use of a parallel file system such as BeeGFS. Such parallel files systems may include a distributed metadata architecture. For example, the parallel file system may include a plurality of metadata servers across which metadata is distributed, as well as components that include services for clients and storage servers.

The systems described above can support the execution of a wide array of software applications. Such software applications can be deployed in a variety of ways, including container-based deployment models. Containerized applications may be managed using a variety of tools. For example, containerized applications may be managed using Docker Swarm, Kubernetes, and others. Containerized applications may be used to facilitate a serverless, cloud native computing deployment and management model for software applications. In support of a serverless, cloud native computing deployment and management model for software applications, containers may be used as part of an event handling mechanisms (e.g., AWS Lambdas) such that various events cause a containerized application to be spun up to operate as an event handler.

The storage systems described above may also be configured to implement NVMe Zoned Namespaces. Through the use of NVMe Zoned Namespaces, the logical address space of a namespace is divided into zones. Each zone provides a logical block address range that must be written sequentially and explicitly reset before rewriting, thereby enabling the creation of namespaces that expose the natural boundaries of the device and offload management of internal mapping tables to the host. In order to implement NVMe Zoned Name Spaces ('ZNS'), ZNS SSDs or some other form of zoned block devices may be utilized that expose a namespace logical address space using zones. With the zones aligned to the internal physical properties of the device, several inefficiencies in the placement of data can be eliminated. In such embodiments, each zone may be mapped, for example, to a separate application such that functions like wear levelling and garbage collection could be performed on a per-zone or per-application basis rather than across the entire device. In order to support ZNS, the storage controllers described herein may be configured with to interact with zoned block devices through the usage of, for example, the Linux^{TM} kernel zoned block device interface or other tools.

The storage systems described above may also be configured to implement zoned storage in other ways such as, for example, through the usage of shingled magnetic recording (SMR) storage devices. In examples where zoned storage is used, device-managed embodiments may be deployed where the storage devices hide this complexity by managing it in the firmware, presenting an interface like any other storage device. Alternatively, zoned storage may be implemented via a host-managed embodiment that depends on the operating system to know how to handle the drive, and only write sequentially to certain regions of the drive. Zoned storage may similarly be implemented using a host-aware embodiment in which a combination of a drive managed and host managed implementation is deployed.

The storage systems described herein may be used to form a data lake. A data lake may operate as the first place that an organization’s data flows to, where such data may be in a raw format. The storage systems described above may also be used to implement such a data warehouse. In addition, a data mart or data hub may allow for data that is even more easily consumed, where the storage systems described above may also be used to provide the underlying storage resources necessary for a data mart or data hub. In embodiments, queries the data lake may require a schema-on-read approach, where data is applied to a plan or schema as it is pulled out of a stored location, rather than as it goes into the stored location.

The storage systems described herein may also be configured to implement a recovery point objective (‘RPO’), which may be established by a user, established by an administrator, established as a system default, established as part of a storage class or service that the storage system is participating in the delivery of, or in some other way. A “recovery point objective” is a goal for the maximum time difference between the last update to a source dataset and the last recoverable replicated dataset update that would be correctly recoverable, given a reason to do so, from a continuously or frequently updated copy of the source dataset. An update is correctly recoverable if it properly takes into account all updates that were processed on the source dataset prior to the last recoverable replicated dataset update.

In synchronous replication, the RPO would be zero, meaning that under normal operation, all completed updates on the source dataset should be present and correctly recoverable on the copy dataset. In best effort nearly synchronous replication, the RPO can be as low as a few seconds. In snapshot-based replication, the RPO can be roughly calculated as the interval between snapshots plus the time to transfer the modifications between a previous already transferred snapshot and the most recent to-be-replicated snapshot.

If updates accumulate faster than they are replicated, then an RPO can be missed. If more data to be replicated accumulates between two snapshots, for snapshot-based replication, than can be replicated between taking the snapshot and replicating that snapshot’s cumulative updates to the copy, then the RPO can be missed. If, again in snapshot-based replication, data to be replicated accumulates at a faster rate than could be transferred in the time between subsequent snapshots, then replication can start to fall further behind which can extend the miss between the expected recovery point objective and the actual recovery point that is represented by the last correctly replicated update.

In some embodiments, updated portions of datasets that are being asynchronously replicated between a source storage system and a target storage system may be stored on a separate storage system that has a lower connection latency with the source storage system than the target storage system. For example, the separate storage system may be in a closer geographic location to the source storage system than the target storage system, resulting in a lower connection latency. In such an example, this may provide what is sometimes called “bunker” replication the storage system stores enough of a dataset for in-transit data and metadata but is not sized to store a complete dataset.

In this example, if the primary (complete) copy fails but the intermediate “bunker” storage survives, then the further distant non-synchronous target can be caught up by applying the updates that were stored synchronously on the bunker storage. Further, in this example, if both primary and bunker storage fail, then at least the longer-distance storage is consistent and within the longer distance RPO. Continuing with this example, the lightweight checkpoints may be formed and transferred by either the bunker storage system or by the primary storage system, or can be formed and transferred by a combination of the primary storage system and the bunker storage system. Once any updates to the dataset have been successfully replicated in the target storage system, the target storage system may transmit an indication to the bunker storage system that the updates have been successfully replicated. Upon receiving the indication, the bunker storage system may erase the updates, making the space available for the storage of any subsequent updates to the dataset that are received from the source storage system.

The storage systems described above may also be part of a shared nothing storage cluster. In a shared nothing storage cluster, each node of the cluster has local storage and communicates with other nodes in the cluster through networks, where the storage used by the cluster is (in general) provided only by the storage connected to each individual node. A collection of nodes that are synchronously replicating a dataset may be one example of a shared nothing storage cluster, as each storage system has local storage and communicates to other storage systems through a network, where those storage systems do not (in general) use storage from somewhere else that they share access to through some kind of interconnect. In contrast, some of the storage systems described above are themselves built as a shared-storage cluster, since there are drive shelves that are shared by the paired controllers. Other storage systems described above, however, are built as a shared nothing storage cluster, as all storage is local to a particular node (e.g., a blade) and all communication is through networks that link the compute nodes together.

In other embodiments, other forms of a shared nothing storage cluster can include embodiments where any node in the cluster has a local copy of all storage they need, and where data is mirrored through a synchronous style of replication to other nodes in the cluster either to ensure that the data isn't lost or because other nodes are also using that storage. In such an embodiment, if a new cluster node needs some data, that data can be copied to the new node from other nodes that have copies of the data.

In some embodiments, mirror-copy-based shared storage clusters may store multiple copies of all the cluster's stored data, with each subset of data replicated to a particular set of nodes, and different subsets of data replicated to different sets of nodes. In some variations, embodiments may store all of the cluster's stored data in all nodes, whereas in other variations nodes may be divided up such that a first set of nodes will all store the same set of data and a second, different set of nodes will all store a different set of data.

Readers will appreciate that RAFT-based databases (e.g., etcd) may operate like shared-nothing storage clusters where all RAFT nodes store all data. The amount of data stored in a RAFT cluster, however, may be limited so that extra copies don’t consume too much storage. A container server cluster might also be able to replicate all data to all cluster nodes, presuming the containers don’t tend to be too large and their bulk data (the data manipulated by the applications that run in the containers) is stored elsewhere such as in an S3 cluster or an external file server. In such an example, the container storage may be provided by the cluster directly through its shared-nothing storage model, with those containers providing the images that form the execution environment for parts of an application or service.

For further explanation, FIG. 3D illustrates an exemplary computing device 350 that may be specifically configured to perform one or more of the processes described herein. As shown in FIG. 3D, computing device 350 may include a communication interface 352, a processor 354, a storage device 356, and an input/output ("I/O") module 358 communicatively connected one to another via a communication infrastructure 360. While an exemplary computing device 350 is shown in FIG. 3D, the components illustrated in FIG. 3D are not intended to be limiting. Additional or alternative components may be used in other embodiments. Components of computing device 350 shown in FIG. 3D will now be described in additional detail.

Communication interface 352 may be configured to communicate with one or more computing devices. Examples of communication interface 352 include, without limitation, a wired network interface (such as a network interface card), a wireless network interface (such as a wireless network interface card), a modem, an audio/video connection, or other interface.

Processor 354 generally represents any type or form of processing unit capable of processing data and/or interpreting, executing, and/or directing execution of one or more of the instructions, processes, and/or operations described herein. Processor 354 may perform operations by executing computer-executable instructions 362 (e.g., an application, software, code, and/or other executable data instance) stored in storage device 356.

Storage device 356 may include one or more data storage media, devices, or configurations and may employ any type, form, and combination of data storage media and/or device. For example, storage device 356 may include, but is not limited to, any combination of the non-volatile media and/or volatile media described herein. Electronic data, including data described herein, may be temporarily and/or permanently stored in storage device 356. For example, data representative of computer-executable instructions 362 configured to direct processor 354 to perform any of the operations described herein may be stored within storage device 356. In some examples, data may be arranged in one or more databases residing within storage device 356.

I/O module 358 may include one or more I/O modules configured to receive user input and provide user output. I/O module 358 may include any hardware, firmware, software, or combination thereof supportive of input and output capabilities. For example, I/O module 358 may include hardware and/or software for capturing user input, including, but not limited to, a keyboard or keypad, a touchscreen component (e.g., touchscreen display), a receiver (e.g., an RF or infrared receiver), motion sensors, and/or one or more input buttons.

I/O module 358 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O module 358 is configured to provide graphical data to a display for presentation to a user. The graphical data may be representative of one or more graphical user interfaces and/or any other graphical content as may serve a particular implementation. In some examples, any of the systems, computing devices, and/or other components described herein may be implemented by computing device 350.

For further explanation, FIG. 3E illustrates an example of a fleet of storage systems 376 for providing storage services (also referred to herein as ‘data services’). The fleet of storage systems 376 depicted in FIG. 3E includes a plurality of storage systems 374a, 374b, 374c, through 374n that may each be similar to the storage systems described herein. The storage systems 374a, 374b, 374c, through 374n in the fleet of storage systems 376 may be embodied as identical storage systems or as different types of storage systems. For example, two of the storage systems 374a, 374n depicted in FIG. 3E are depicted as being cloud-based storage systems, as the resources that collectively form each of the storage systems 374a, 374n are provided by distinct cloud services providers 370, 372. For example, the first cloud services provider 370 may be Amazon AWS^{TM} whereas the second cloud services provider 372 is Microsoft Azure^{TM}, although in other embodiments one or more public clouds, private clouds, or combinations thereof may be used to provide the underlying resources that are used to form a particular storage system in the fleet of storage systems 376.

The example depicted in FIG. 3E includes an edge management service 366 for delivering storage services in accordance with some embodiments of the present disclosure. The storage services (also referred to herein as ‘data services’) that are delivered may include, for example, services to provide a certain amount of storage to a consumer, services to provide storage to a consumer in accordance with a predetermined service level agreement, services to provide storage to a consumer in accordance with predetermined regulatory requirements, and many others.

The edge management service 366 depicted in FIG. 3E may be embodied, for example, as one or more modules of computer program instructions executing on computer hardware such as one or more computer processors. Alternatively, the edge management service 366 may be embodied as one or more modules of computer program instructions executing on a virtualized execution environment such as one or more virtual machines, in one or more containers, or in some other way. In other embodiments, the edge management service 366 may be embodied as a combination of the embodiments described above, including embodiments where the one or more modules of computer program instructions that are included in the edge management service 366 are distributed across multiple physical or virtual execution environments.

The edge management service 366 may operate as a gateway for providing storage services to storage consumers, where the storage services leverage storage offered by one or more storage systems 374a, 374b, 374c, through 374n. For example, the edge management service 366 may be configured to provide storage services to host devices 378a, 378b, 378c, 378d, 378n that are executing one or more applications that consume the storage services. In such an example, the edge management service 366 may operate as a gateway between the host devices and the storage systems 374a, 374b, 374c, through 374n, rather than requiring that the host devices directly access the storage systems.

The edge management service 366 of FIG. 3E exposes a storage services module 364 to the host devices of FIG. 3E, although in other embodiments the edge management service 366 may expose the storage services module 364 to other consumers of the various storage services. The various storage services may be presented to consumers via one or more user interfaces, via one or more APIs, or through some other mechanism provided by the storage services module 364. As such, the storage services module 364 depicted in FIG. 3E may be embodied as one or more modules of computer program instructions executing on physical hardware, on a virtualized execution environment, or combinations thereof, where executing such modules causes enables a consumer of storage services to be offered, select, and access the various storage services.

The edge management service 366 of FIG. 3E also includes a system management services module 368. The system management services module 368 of FIG. 3E includes one or more modules of computer program instructions that, when executed, perform various operations in coordination with the storage systems to provide storage services to the host devices. The system management services module 368 may be configured, for example, to perform tasks such as provisioning storage resources from the storage systems via one or more APIs exposed by the storage systems, migrating datasets or workloads amongst the storage systems via one or more APIs exposed by the storage systems, setting one or more tunable parameters (i.e., one or more configurable settings) on the storage systems via one or more APIs exposed by the storage systems, and so on. For example, many of the services described below relate to embodiments where the storage systems are configured to operate in some way. In such examples, the system management services module 368 may be responsible for using APIs (or some other mechanism) provided by the storage systems to configure the storage systems to operate in the ways described below.

In addition to configuring the storage systems, the edge management service 366 itself may be configured to perform various tasks required to provide the various storage services. Consider an example in which the storage service includes a service that, when selected and applied, causes personally identifiable information (‘PII’) contained in a dataset to be obfuscated when the dataset is accessed. In such an example, the storage systems may be configured to obfuscate PII when servicing read requests directed to the dataset. Alternatively, the storage systems may service reads by returning data that includes the PII, but the edge management service 366 itself may obfuscate the PII as the data is passed through the edge management service 366 on its way from the storage systems to the host devices.

The storage systems depicted in FIG. 3E may be embodied as one or more of the storage systems described above with reference to FIGS. 1A-3D, including variations thereof. In fact, the storage systems may serve as a pool of storage resources where the individual components in that pool have different performance characteristics, different storage characteristics, and so on. For example, one of the storage systems 374a may be a cloud-based storage system, another storage system 374b may be a storage system that provides block storage, another storage system 374c may be a storage system that provides file storage, another storage system 374d may be a relatively high-performance storage system while another storage system 374n may be a relatively low-performance storage system, and so on. In alternative embodiments, only a single storage system may be present.

The storage systems depicted in FIG. 3E may also be organized into different failure domains so that the failure of one storage system 374a should be totally unrelated to the failure of another storage system 374b. For example, each of the storage systems may receive power from independent power systems, each of the storage systems may be coupled for data communications over independent data communications networks, and so on. Furthermore, the storage systems in a first failure domain may be accessed via a first gateway whereas storage systems in a second failure domain may be accessed via a second gateway. For example, the first gateway may be a first instance of the edge management service 366 and the second gateway may be a second instance of the edge management service 366, including embodiments where each instance is distinct, or each instance is part of a distributed edge management service 366.

As an illustrative example of available storage services, storage services may be presented to a user that are associated with different levels of data protection. For example, storage services may be presented to the user that, when selected and enforced, guarantee the user that data associated with that user will be protected such that various recovery point objectives (‘RPO’) can be guaranteed. A first available storage service may ensure, for example, that some dataset associated with the user will be protected such that any data that is more than 5 seconds old can be recovered in the event of a failure of the primary data store whereas a second available storage service may ensure that the dataset that is associated with the user will be protected such that any data that is more than 5 minutes old can be recovered after failure of the primary data store.

An additional example of storage services that may be presented to a user, selected by a user, and ultimately applied to a dataset associated with the user can include one or more data compliance services. Such data compliance services may be embodied, for example, as services that may be provided to consumers (i.e., a user) the data compliance services to ensure that the user’s datasets are managed in a way to adhere to various regulatory requirements. For example, one or more data compliance services may be offered to a user to ensure that the user’s datasets are managed in a way so as to adhere to the General Data Protection Regulation (‘GDPR’), one or more data compliance services may be offered to a user to ensure that the user’s datasets are managed in a way so as to adhere to the Sarbanes–Oxley Act of 2002 (‘SOX’), or one or more data compliance services may be offered to a user to ensure that the user’s datasets are managed in a way so as to adhere to some other regulatory act. In addition, the one or more data compliance services may be offered to a user to ensure that the user’s datasets are managed in a way so as to adhere to some non-governmental guidance (e.g., to adhere to best practices for auditing purposes), the one or more data compliance services may be offered to a user to ensure that the user’s datasets are managed in a way so as to adhere to a particular clients or organizations requirements, and so on.

In order to provide this particular data compliance service, the data compliance service may be presented to a user (e.g., via a GUI) and selected by the user. In response to receiving the selection of the particular data compliance service, one or more storage services policies may be applied to a dataset associated with the user to carry out the particular data compliance service. For example, a storage services policy may be applied requiring that the dataset be encrypted prior to being stored in a storage system, prior to being stored in a cloud environment, or prior to being stored elsewhere. In order to enforce this policy, a requirement may be enforced not only requiring that the dataset be encrypted when stored, but a requirement may be put in place requiring that the dataset be encrypted prior to transmitting the dataset (e.g., sending the dataset to another party). In such an example, a storage services policy may also be put in place requiring that any encryption keys used to encrypt the dataset are not stored on the same system that stores the dataset itself. Readers will appreciate that many other forms of data compliance services may be offered and implemented in accordance with embodiments of the present disclosure.

The storage systems in the fleet of storage systems 376 may be managed collectively, for example, by one or more fleet management modules. The fleet management modules may be part of or separate from the system management services module 368 depicted in FIG. 3E. The fleet management modules may perform tasks such as monitoring the health of each storage system in the fleet, initiating updates or upgrades on one or more storage systems in the fleet, migrating workloads for load balancing or other performance purposes, and many other tasks. As such, and for many other reasons, the storage systems may be coupled to each other via one or more data communications links in order to exchange data between the storage systems.

In some embodiments, one or more storage systems or one or more elements of storage systems (e.g., features, services, operations, components, etc. of storage systems), such as any of the illustrative storage systems or storage system elements described herein, may provide one or more storage services (e.g., any of the illustrative storage services described herein) to one or more container systems, which may include a container storage system providing persistent storage to one or more containerized applications running or to be run in a container system.. A container system may include any system that supports execution of one or more containerized applications or services. Such a service may be software deployed as infrastructure for building applications, for operating a run-time environment, and/or as infrastructure for other services. In the discussion that follows, descriptions of containerized applications generally apply to containerized services as well.

A container may combine one or more elements of a containerized software application together with a runtime environment for operating those elements of the software application bundled into a single image. For example, each such container of a containerized application may include executable code of the software application and various dependencies, libraries, and/or other components, together with network configurations and configured access to additional resources, used by the elements of the software application within the particular container in order to enable operation of those elements. A containerized application can be represented as a collection of such containers that together represent all the elements of the application combined with the various run-time environments needed for all those elements to run. As a result, the containerized application may be abstracted away from host operating systems as a combined collection of lightweight and portable packages and configurations, where the containerized application may be uniformly deployed and consistently executed in different computing environments that use different container-compatible operating systems or different infrastructures. In some embodiments, a containerized application shares a kernel with a host computer system and executes as an isolated environment (an isolated collection of files and directories, processes, system and network resources, and configured access to additional resources and capabilities) that is isolated by an operating system of a host system in conjunction with a container management framework. When executed, a containerized application may provide one or more containerized workloads and/or services.

The container system may include and/or utilize a cluster of nodes. For example, the container system may be configured to manage deployment and execution of containerized applications on one or more nodes in a cluster. The containerized applications may utilize resources of the nodes, such as memory, processing and/or storage resources provided and/or accessed by the nodes. The storage resources may include any of the illustrative storage resources described herein and may include on-node resources such as a local tree of files and directories, off-node resources such as external networked file systems, databases or object stores, or both on-node and off-node resources. Access to additional resources and capabilities that could be configured for containers of a containerized application could include specialized computation capabilities such as GPUs and AI/ML engines, or specialized hardware such as sensors and cameras.

In some embodiments, the container system may include a container orchestration system (which may also be referred to as a container orchestrator, a container orchestration platform, etc.) designed to make it reasonably simple and for many use cases automated to deploy, scale, and manage containerized applications. In some embodiments, the container system may include a storage management system configured to provision and manage storage resources (e.g., virtual volumes) for private or shared use by cluster nodes and/or containers of containerized applications.

FIG. 3F illustrates an example container system 380. In this example, the container system 380 includes a container storage system 381 that may be configured to perform one or more storage management operations to organize, provision, and manage storage resources for use by one or more containerized applications 382-1 through 382-L of container system 380. In particular, the container storage system 381 may organize storage resources into one or more storage pools 383 of storage resources for use by containerized applications 382-1 through 382-L. The container storage system may itself be implemented as a containerized service.

The container system 380 may include or be implemented by one or more container orchestration systems, including Kubernetes™, Mesos™, Docker Swarm™, among others. The container orchestration system may manage the container system 380 running on a cluster 384 through services implemented by a control node, depicted as 385, and may further manage the container storage system or the relationship between individual containers and their storage, memory and CPU limits, networking, and their access to additional resources or services.

A control plane of the container system 380 may implement services that include: deploying applications via a controller 386, monitoring applications via the controller 386, providing an interface via an API server 387, and scheduling deployments via scheduler 388. In this example, controller 386, scheduler 388, API server 387, and container storage system 381 are implemented on a single node, node 385. In other examples, for resiliency, the control plane may be implemented by multiple, redundant nodes, where if a node that is providing management services for the container system 380 fails, then another, redundant node may provide management services for the cluster 384.

A data plane of the container system 380 may include a set of nodes that provides container runtimes for executing containerized applications. An individual node within the cluster 384 may execute a container runtime, such as Docker™, and execute a container manager, or node agent, such as a kubelet in Kubernetes (not depicted) that communicates with the control plane via a local network-connected agent (sometimes called a proxy), such as an agent 389. The agent 389 may route network traffic to and from containers using, for example, Internet Protocol (IP) port numbers. For example, a containerized application may request a storage class from the control plane, where the request is handled by the container manager, and the container manager communicates the request to the control plane using the agent 389.

Cluster 384 may include a set of nodes that run containers for managed containerized applications. A node may be a virtual or physical machine. A node may be a host system.

The container storage system 381 may orchestrate storage resources to provide storage to the container system 380. For example, the container storage system 381 may provide persistent storage to containerized applications 382-1-382-L using the storage pool 383. The container storage system 381 may itself be deployed as a containerized application by a container orchestration system.

For example, the container storage system 381 application may be deployed within cluster 384 and perform management functions for providing storage to the containerized applications 382. Management functions may include determining one or more storage pools from available storage resources, provisioning virtual volumes on one or more nodes, replicating data, responding to and recovering from host and network faults, or handling storage operations. The storage pool 383 may include storage resources from one or more local or remote sources, where the storage resources may be different types of storage, including, as examples, block storage, file storage, and object storage.

The container storage system 381 may also be deployed on a set of nodes for which persistent storage may be provided by the container orchestration system. In some examples, the container storage system 381 may be deployed on all nodes in a cluster 384 using, for example, a Kubernetes DaemonSet. In this example, nodes 390-1 through 390-N provide a container runtime where container storage system 381 executes. In other examples, some, but not all nodes in a cluster may execute the container storage system 381.

The container storage system 381 may handle storage on a node and communicate with the control plane of container system 380, to provide dynamic volumes, including persistent volumes. A persistent volume may be mounted on a node as a virtual volume, such as virtual volumes 391-1 and 391-P. After a virtual volume 391 is mounted, containerized applications may request and use, or be otherwise configured to use, storage provided by the virtual volume 391. In this example, the container storage system 381 may install a driver on a kernel of a node, where the driver handles storage operations directed to the virtual volume. In this example, the driver may receive a storage operation directed to a virtual volume, and in response, the driver may perform the storage operation on one or more storage resources within the storage pool 383, possibly under direction from or using additional logic within containers that implement the container storage system 381 as a containerized service.

The container storage system 381 may, in response to being deployed as a containerized service, determine available storage resources. For example, storage resources 392-1 through 392-M may include local storage, remote storage (storage on a separate node in a cluster), or both local and remote storage. Storage resources may also include storage from external sources such as various combinations of block storage systems, file storage systems, and object storage systems. The storage resources 392-1 through 392-M may include any type(s) and/or configuration(s) of storage resources (e.g., any of the illustrative storage resources described above), and the container storage system 381 may be configured to determine the available storage resources in any suitable way, including based on a configuration file. For example, a configuration file may specify account and authentication information for cloud-based object storage 348 or for a cloud-based storage system 318. The container storage system 381 may also determine availability of one or more storage devices 356 or one or more storage systems. An aggregate amount of storage from one or more of storage device(s) 356, storage system(s), cloud-based storage system(s) 318, edge management services 366, cloud-based object storage 348, or any other storage resources, or any combination or sub-combination of such storage resources may be used to provide the storage pool 383. The storage pool 383 is used to provision storage for the one or more virtual volumes mounted on one or more of the nodes 390 within cluster 384.

In some implementations, the container storage system 381 may create multiple storage pools. For example, the container storage system 381 may aggregate storage resources of a same type into an individual storage pool. In this example, a storage type may be one of: a storage device 356, a storage array 102, a cloud-based storage system 318, storage via an edge management service 366, or a cloud-based object storage 348. Or it could be storage configured with a certain level or type of redundancy or distribution, such as a particular combination of striping, mirroring, or erasure coding.

The container storage system 381 may execute within the cluster 384 as a containerized container storage system service, where instances of containers that implement elements of the containerized container storage system service may operate on different nodes within the cluster 384. In this example, the containerized container storage system service may operate in conjunction with the container orchestration system of the container system 380 to handle storage operations, mount virtual volumes to provide storage to a node, aggregate available storage into a storage pool 383, provision storage for a virtual volume from a storage pool 383, generate backup data, replicate data between nodes, clusters, environments, among other storage system operations. In some examples, the containerized container storage system service may provide storage services across multiple clusters operating in distinct computing environments. For example, other storage system operations may include storage system operations described herein. Persistent storage provided by the containerized container storage system service may be used to implement stateful and/or resilient containerized applications.

The container storage system 381 may be configured to perform any suitable storage operations of a storage system. For example, the container storage system 381 may be configured to perform one or more of the illustrative storage management operations described herein to manage storage resources used by the container system.

In some examples, container storage system 381 may be configured to interact with a separate storage system that provides any of storage resources 392 in a manner that allows container storage system 381 to leverage functionality of the separate storage system. For example, container storage system 381 may be configured to offload storage operations such as replication, garbage collection, etc. to the separate storage system based on a special, defined relationship between container storage system 381 and the separate storage system, which relationship allows container storage system 381 to delegate certain storage management operations to the separate storage system. In some embodiments, the separate storage system may include any of the storage systems described above, where the separate storage system is configured to function as a backend storage system for container storage system 381. Container storage system 381 and the separate storage system may be configured to interface with one another in any way suitable that allows container storage system 381 to use storage resources 392 and/or functionality provided by the separate storage system.

FIG. 3G illustrates an example of a storage node of a storage system architecture 395 for a large-scale storage platform, in accordance with embodiments of the disclosure. The storage system architecture 395 includes node 390, as previously described at FIG. 3F, and a large-scale storage platform 396. It should be noted that in some embodiments, storage system architecture 395 may include other storage system components as previously described at FIGS. 1A-3F in addition to or instead of the components shown in storage system architecture 395. For illustrative purposes, some components of storage system architecture 395 are not shown.

Node 390 includes a processing device 397 that executes a scale out platform component 398 and a flash device management component 399, which are described in further detail below. Node 390 may also include storage resources 392, as previously described at FIG. 3F.

Large-scale storage platform 396 may be a cloud-scale or hyperscaler storage platform that is operatively coupled to node 390 via one or more network connections (not shown). The large-scale storage platform 396 may provide computing and/or storage resources across multiple data centers to consumers at an enterprise level. In embodiments, node 390 may store data at storage resources 392 on behalf of the large-scale storage platform 396.

In some embodiments, large-scale storage platform 396 may operate as a storage layer of a large-scale cloud platform. The large-scale cloud platform may provide a variety of storage, network, and/or compute services and these services may operate across multiple datacenters as well as on a significant geographic scale within and across multiple geographic regions. In embodiments, large-scale storage platform 396 may operate as a storage layer for a large-scale supercomputer or artificial intelligence (AI) cluster and may operate in large ranges of data, such as hundreds of petabytes or many exabytes.

Node 390 may be optimized for use by the large-scale storage platform 396 by moving the handling of large blocks of data from individual storage resources 392 to processing device 397 (e.g., flash device management component 399). This may be used to form a simple storage node service that separates the software that ties node 390 into the large-scale storage platform 396, which has similarities but many specific differences between other large-scale storage platforms, with software that can optimize the use of directly managed and abstraction based managed flash storage devices, such as storage resources 392.

In embodiments, node 390 for large-scale storage platform 396 may be a server with a large number of slots for inserting coupled storage devices (e.g., storage resources 392). In embodiments, node 390 may be configured with processing device 397 that executes a flexible server operating system with a large amount of available RAM and network connections for connecting node 390 with the rest of the large-scale storage platform 396 within and across the data centers and geographies of the large-scale storage platform 396. In some embodiments, node 390 may operate according to the needs of the large-scale storage platform 396. Although node 390 may generally store individual shards of widely distributed and erasure coded stripes of data, as well as serving additional needs related to databases, logging, and being compute that is available to run various services that aid in the operation of the large-scale storage service.

In some embodiments, node 390 may have a large number of connected flash storage devices, including directly and abstraction-based managed storage devices, and a processing device and memory (not shown) running software (e.g., scale out platform component 398 and/or flash device management component 399) on the processing device. In embodiments, the scale out platform component 398 may interact with the large-scale storage platform 396 and other large-scale storage platform management infrastructure. The flash device management component 399 may manage the storage resources 392 present the storage resources in some form to the scale out platform component 398.

In embodiments, a flexible large-block model may be implemented within node 390 utilizing directly or abstraction-based managed flash storage devices may improve the performance of a storage system for large-scale storage platform 396. In a conventional storage system, the storage devices generally have fixed-sized DRAM for storing tables. This makes the storage devices inflexible in terms of balancing block sizes and DRAM because it is easier to manufacture a range of DRAM configurations for the server parts of the storage nodes than to manufacture a range of DRAM configurations for pluggable storage devices to insert into hot pluggable drive bays for servers. Furthermore, DRAM takes up valuable space on a circuit board of the pluggable storage device, while placing the DRAM in an enclosure’s motherboard instead migrates that part of the storage node/storage device combination into a place where the DRAMs relative inaccessibility is less of an issue.

In an example embodiment, flash device management component 399 can interface with and manage the managed flash storage devices (e.g., storage resources 392). The flash device management component 399 may provide services to make optimal use of the storage resources 392, for managing the capacity, performance, durability, longevity, and/or localized hardware faults of the storage resources 392. The flash device management component 399 may be able to utilize processing device 397 and memory of node 390 to provide a large-block storage service. For example, the flash device management component 399 may present a set of block volumes to other software layers of the node 390. In another example, a large-scale storage platform 396 can implement software within and across server and storage nodes, such as node 390, that are within and across data centers of the large-scale storage platform 396. The storage nodes may interact with a distributed storage platform to store and retrieve data blocks on behalf of the large-scale storage platform 396. The node 390 can then utilize the set of block volumes provided by the flash device management component 399 to write data segments into large blocks according to a large-block model.

In embodiments, the flash device management component 399 of the node 390 can provide a set of differently optimized storage, such as providing some volumes supporting an amount of large-block optimized storage and other volumes presenting an amount of small-random-write optimized storage for use with tables or databases needed by the scale out platform component 398. In some embodiments, the flash device management component 399 may provide an amount of SLC storage intended for the storage of data that has a heavier overwrite rate. In embodiments, the flash device management component 399 may provide an amount of archive-grade storage that uses less DRAM on the presumption that reads of data stored in the archive-grade storage are infrequent and do not require low latency.

In some embodiments, node 390 may require storage for logs, which may be sequential-write files written in variable-sized data segments. This can end up being similar in write pattern to large blocks that are filled in piecemeal similarly to a large-block allocation model, as long as the file system writing the logs can be coaxed into allocating log file blocks that are appropriately large and appropriately aligned by logical block address.

In embodiments, one mode that the large-scale storage platform 396 may operate their storage nodes, such as node 390, is to run the services that integrate with the rest of the large-scale storage platform on top of a simple file system, such as a XFS file system, that can be configured to prefer aligned extent allocations for regular files, such as logs, and that can further be configured to support fixed alignment and fixed-sized extents on a separate volume for certain types of files (e.g., files that XFS calls real-time files) and where several of those fixed alignment/fixed-sized extents can be written in parallel for higher performance. The storage node then receives shards or pieces of shards, as well as chunks of log data, and/or random-write blocks for various types of databases and turns that data into writes for example to one or more XFS file systems, potentially with writes for one or more shards being written as parallel writes to aligned blocks of XFS real-time files which are then stored by XFS into a volume optimized for those writes. The scale out platform component 398 may further utilize other XFS properties to write log chunks to preferred alignment extents. The shards are part of much larger and very wide stripes with large numbers of parity shards within and across data centers, as previously described. It is the role of the flash device management component 399 of the node 390 to receive the various writes, store them as optimally as is reasonably possible, and support reading any previously written data.

XFS file systems also support issuing TRIM/UNMAP for deleted blocks. In some embodiments, this may be leveraged by the flash device management component 399 to eliminate the potential need to read prior data for partially written large blocks.

In some embodiments, node 390 may also require an amount of storage for booting an operating system. This may be provided by a separate storage resource, such as an SSD, or on-motherboard flash storage. In some embodiments, this may be provided by the storage resources 392 if the BIOS of the storage node is able to read the boot blocks without use of the flash device management component 399, as this layer may not be available until the operating system has booted and execution of the flash device management component 399 has begun. To support this, a storage device controller on one or more of the flash storage devices of storage resources 392 could be configured to provide a namespace supporting random access to a relatively small boot file system. If only reads need be supported, this may be provided by a simple translation table that is updated into the flash storage device while the node 390 is running with flash device management component 399 intact but that is then used to support reads for booting prior to the flash device management component 399 being brought up later in the bootup sequence.

It should be noted that while storage system architecture 395 is shown as having a single node 390 and a single large-scale storage platform 396, embodiments of the disclosure may include any number of nodes and/or large-scale storage platforms.

To further provide reliability and performance for storage systems, stored devices, storage services, and so forth, embodiments may provide predictive device wear and failure detection to proactively identify and notify about potential or imminent device failures. Embodiments may include a system to monitor key metrics over time related to device degradation, including tracking the number of block degradation events, frequency, number, or pattern of P/E cycles, number of writes to new blocks, and so forth to identify the contribution of various operations or operating parameters to the device or component wear over time. In addition to the operations and operating parameters, embodiments may gather data on storage device degradation over time as well as block, die, or device fault events, such as uncorrectable faults, to correlate the operations and operating parameters with storage device health and failures. In some embodiments, the system may further provide the information collected above to generate a framework (e.g., a model produced through various machine learning methods, a set of heuristics, or a combination thereof) for using sequential data of the collected information to predict device degradation and eventual failures.

Local storage systems or storage devices may record detailed data for all constituent components and maintain such data for a period of time after which some portion of the data may be deleted or removed. In some examples, up to a few tens of millions of data samples for locally recorded data on everything on a storage system or even an individual storage device may be collected and maintained at any given time. In other words, the sampled data may be maintained as a rolling window of data such that the data immediately preceding a failure can be compared with time windows that didn’t result in a fault with the combination used to train the model.

In some embodiments, the data sampled from storage devices and components may include voltage table changes, read errors that can be corrected using ECC, read errors that can be corrected after adjusting voltage levels, including the history of the specific voltage levels for writes and for reads and which voltage levels did and did not work for reads, read patterns, power failure/restarts with included clock values or with measured durations of run-time and down time, programming modes, patterns of programming the flash, patterns of erases, latency jitters in programming or erase operations or in read requests, wear level imbalances, interrupted programs or erases, monitored temperatures using whatever temperature sensors are available, voltage fluctuations on the storage devices themselves or in the power supplies supplying power to the storage devices, or any other measurements or operational parameters associated with a storage device or component. Similarly, the data sampled may further include a position or location within a flash strings that a failed component is located and the position or location within an overall geometry of a storage component and storage device (e.g., NAND geometry), the states of neighboring components at a time of failure of a component, time intervals between PE cycles, and counts of reads including read disturb tracking. Furthermore, as storage devices are tuned during operation, data may be read and flash pages or flash word lines that are operating abnormally can be identified and tracked. Another aspect that may be tracked includes power loss protection (PLP) health of the storage devices, including for example supercapacitors and regular capacitors. For example, declines in available energy or changes in charging times can be tracked and can be associated with particular modules, models, or batches, or differences between expected available energy and actual available energy can be measured and used as an indicator. Additionally, embodiments may also monitor on-board humidity and magnetic fields at various physical locations within a storage system as well as acoustic and other vibration data such as using microphones or accelerometers as well as radiation such as counting high energy particles. The collected data may also include data from additional sensors in the operating environment, including rack voltage levels, voltage jitter and spikes, temperatures, and humidity.

Additionally, external sensors for collecting environmental condition data for devices and components may include low-power sensors running on battery power that can gather temperature, humidity and magnetic fields data during transport, such as during shipment to a customer or transport between data centers. Furthermore, collected data may include data on when and where the storage devices were manufactured and what the temperatures, humidity levels, and/or magnetic fields were throughout the manufacturing process. Accordingly, embodiments may collect and consider various operational and environmental metrics to train and deploy a device and component failure prediction model to provide notifications of imminent failures, reducing storage system downtime, maintaining consistent storage capacity, avoiding data loss, reducing expensive data rebuild times, and providing additional efficiencies in storage system hardware management.

In some examples, operating data, environmental data, failure data, and the like, may be collected at the storage system level, storage node level, storage device level, and/or from the individual storage component level, all or a portion of which, may be used to train a machine learning model.

In some embodiments, a data collection component may collect storage operation and environmental metrics, and device health metrics, as well as device and component failures from a large number of storage systems, storage nodes, storage devices, and storage components. The storage operation metrics may include both internally tracked metrics associated with a storage device and storage components, such as read/write voltages, error correction, and so forth, in addition to external and environmental metrics (e.g., detected by internal and external sensors during operation) that indicate an operating environment and any other variables that may affect the lifespan of a storage device and its components. The device health metrics may include device or component wear levels, block level wear, device or component faults (e.g., device and component faults), performance and performance anomalies, indications of device or component data loss, or any other indicators of device health and remaining device or component lifespan.

For example, operating data and metrics may be collected from various sources within a storage system (e.g., for training of and use by a failure prediction model or other applications). In some embodiments, a storage system may include one or more chassis, storage nodes, and storage devices including storage components. Sensors may be deployed at any, or all, of these levels to collect operating and environmental data. For example, chassis level sensors may be deployed to collect data at the chassis level, such as temperature, humidity, electromagnetic fields, acoustic levels (e.g., noise), vibration, etc., of the chassis. Similarly, node level sensors may be deployed on one or more nodes of the storage system to collect data, such as temperature, humidity, electromagnetic fields, acoustic levels (e.g., noise), vibration, orientation, etc., of the corresponding node. Furthermore, node level operation metrics may be collected for one or more nodes of the storage system, such as I/O operations received and performed, patterns of I/O operations, and so forth. More granular data for one or more devices may be collected at the device level and for one or more components of the device, such as buses, capacitors, storage device controllers, and flash die. For example, device level sensors may collect and monitor data, such as temperature, humidity, electromagnetic fields, acoustic levels (e.g., noise), vibration, etc., of each device while device level operating metrics that are collected may include voltage table changes, read errors that can be corrected using ECC, read errors that can be corrected after adjusting voltage levels, including the history of the specific voltage levels for writes and for reads and which voltage levels did and did not work for reads, read patterns, power failure/restarts with included clock values or with measured durations of run-time and down time, programming modes, patterns of programming the flash, patterns of erases, latency jitters in programming or erase operations or in read requests, wear level imbalances, interrupted programs or erases, or any other monitored operating metrics.

Additionally, component level sensors may monitor environmental conditions of components, such as temperature, humidity, electromagnetic fields, acoustic levels (e.g., noise), vibration, etc., of the components. Component level operating metrics may include similar data as collected at the device level, in addition to any additional data that may be collected. Similarly, the device and component level operating metrics may further include a position or location within a flash string where a failed page or word line or erase block is located and the position or location within an overall geometry of a storage component and storage device (e.g., NAND geometry), the states of neighboring components at a time of failure of a component, time intervals between PE cycles, and counts of PE cycles and/or reads, including read disturb tracking. Furthermore, as storage devices are tuned during operation, data may be read and pages or word lines that are operating abnormally can be identified and tracked based on the read data. For example, when tuning voltage levels for a block, NAND characterization may be used to identify pages or word lines that are likely to be weak spots. The pages or word lines may then be tracked for a period of time after the tuning to determine the quality of the tuning (e.g., if the tuning was poor) which may indicate degradation of tuned voltage levels. Pages or word lines identified as yielding poor results from the tuning can then be used as part of a profile history that can be used herein to further train a model or be used to infer a time to failure, as described herein. Another aspect that may be tracked includes power loss protection (PLP) health of storage devices (e.g., how often PLP is necessary for a device and its components and the effectiveness of the PLP operations). For example, embodiments may monitor particular capacitor modules, models, or batches of capacitors (supercapacitor, regular capacitor, etc.), which may be used to detect patterns of certain variations of modules failing earlier than others. In particular, failures of particular modules, models, or batches of capacitors may be identified as being tied with other tracked parameters that may result in the failures, or degraded performance, of different module variants. Thus, PLP may assist with recognition of patterns of the collected data that indicate failures for particular capacitor modules, models, batches, etc.

In some embodiments, one or more data aggregation systems may be deployed within a large-scale storage platform, such as large-scale storage platform 396 of FIG. 3G. For example, data may be collected from sensors located at storage nodes, as described herein, and aggregated by data aggregation system located within the large-scale storage platform. In some embodiments, the local aggregation system may provide summarized data (e.g., the down-sampled data set) to a storage node of the large-scale storage platform, or to a storage device vendor.

The storage systems described herein may support various forms of data replication. For example, two or more of the storage systems may synchronously replicate a dataset between each other. In synchronous replication, distinct copies of a particular dataset may be maintained by multiple storage systems, but all accesses (e.g., a read) of the dataset should yield consistent results regardless of which storage system the access was directed to. For example, a read directed to any of the storage systems that are synchronously replicating the dataset should return identical results. As such, while updates to the version of the dataset need not occur at exactly the same time, precautions must be taken to ensure consistent accesses to the dataset. For example, if an update (e.g., a write) that is directed to the dataset is received by a first storage system, the update may only be acknowledged as being completed if all storage systems that are synchronously replicating the dataset have applied the update to their copies of the dataset. In such an example, synchronous replication may be carried out through the use of I/O forwarding (e.g., a write received at a first storage system is forwarded to a second storage system), communications between the storage systems (e.g., each storage system indicating that it has completed the update), or in other ways.

In other embodiments, a dataset may be replicated through the use of checkpoints. In checkpoint-based replication (also referred to as ‘nearly synchronous replication’), a set of updates to a dataset (e.g., one or more write operations directed to the dataset) may occur between different checkpoints, such that a dataset has been updated to a specific checkpoint only if all updates to the dataset prior to the specific checkpoint have been completed. Consider an example in which a first storage system stores a live copy of a dataset that is being accessed by users of the dataset. In this example, assume that the dataset is being replicated from the first storage system to a second storage system using checkpoint-based replication. For example, the first storage system may send a first checkpoint (at time t=0) to the second storage system, followed by a first set of updates to the dataset, followed by a second checkpoint (at time t=1), followed by a second set of updates to the dataset, followed by a third checkpoint (at time t=2). In such an example, if the second storage system has performed all updates in the first set of updates but has not yet performed all updates in the second set of updates, the copy of the dataset that is stored on the second storage system may be up-to-date until the second checkpoint. Alternatively, if the second storage system has performed all updates in both the first set of updates and the second set of updates, the copy of the dataset that is stored on the second storage system may be up-to-date until the third checkpoint. Readers will appreciate that various types of checkpoints may be used (e.g., metadata only checkpoints), checkpoints may be spread out based on a variety of factors (e.g., time, number of operations, an RPO setting), and so on.

In other embodiments, a dataset may be replicated through snapshot-based replication (also referred to as ‘asynchronous replication’). In snapshot-based replication, snapshots of a dataset may be sent from a replication source such as a first storage system to a replication target such as a second storage system. In such an embodiment, each snapshot may include the entire dataset or a subset of the dataset such as, for example, only the portions of the dataset that have changed since the last snapshot was sent from the replication source to the replication target. Readers will appreciate that snapshots may be sent on-demand, based on a policy that takes a variety of factors into consideration (e.g., time, number of operations, an RPO setting), or in some other way.

The storage systems described above may, either alone or in combination, be configured to serve as a continuous data protection store. A continuous data protection store is a feature of a storage system that records updates to a dataset in such a way that consistent images of prior contents of the dataset can be accessed with a low time granularity (often on the order of seconds, or even less), and stretching back for a reasonable period of time (often hours or days). These allow access to very recent consistent points in time for the dataset, and also allow access to points in time for a dataset that might have just preceded some event that, for example, caused parts of the dataset to be corrupted or otherwise lost, while retaining close to the maximum number of updates that preceded that event. Conceptually, they are like a sequence of snapshots of a dataset taken very frequently and kept for a long period of time, though continuous data protection stores are often implemented quite differently from snapshots. A storage system implementing a data continuous data protection store may further provide a means of accessing these points in time, accessing one or more of these points in time as snapshots or as cloned copies, or reverting the dataset back to one of those recorded points in time.

Over time, to reduce overhead, some points in the time held in a continuous data protection store can be merged with other nearby points in time, essentially deleting some of these points in time from the store. This can reduce the capacity needed to store updates. It may also be possible to convert a limited number of these points in time into longer duration snapshots. For example, such a store might keep a low granularity sequence of points in time stretching back a few hours from the present, with some points in time merged or deleted to reduce overhead for up to an additional day. Stretching back in the past further than that, some of these points in time could be converted to snapshots representing consistent point-in-time images from only every few hours.

In some examples, a data protection system may be configured to perform various operations configured to protect data stored by a storage system from one or more security threats (e.g., ransomware attacks, malware, etc.). The data protection system may be implemented by the storage system itself (e.g., a controller within the storage system) and/or by a remote monitoring system communicatively coupled to the storage system by way of a network (e.g., the Internet).

For example, the data protection system may direct the storage system to generate (e.g., periodically and/or in response to an occurrence of certain events) one or more provisional snapshots (also referred to as ransomware recovery structures or datasets). These provisional snapshots may be configured such that they can only be deleted or modified in accordance with one or more ransomware recovery parameters. For example, the one or more ransomware recovery parameters may specify a number or a collection of types of authenticated entities that have to approve a deletion or modification of a provisional snapshot before the provisional snapshot can be deleted or modified. As another example, the one or more ransomware recovery parameters may specify a minimum retention duration before which the provisional snapshot can be deleted or modified.

In some examples, any of the snapshots generated herein (e.g., a provisional snapshot) may be converted to or otherwise set to be a protected snapshot (also referred to as a locked-down snapshot). A protected snapshot may have more protection than a provisional snapshot. For example, a protected snapshot may have a policy associated therewith that prevents the protected snapshot from being eradicated (deleted) or modified by any entity, even an administrator with full privileges, for a retention time period. As another example, a protected snapshot may require an additional level of approval (compared to that of a provisional snapshot) by one or more authenticated entities before being eradicated or modified. As another example, maintenance operations, such as garbage collection and merges, may be put on hold for a protected snapshot until the retention time period expires.

In some examples, the data protection system may apply multiple thresholds when monitoring a metric for a possible security threat against data stored within the storage system. For example, the data protection system may maintain data representative of two thresholds – a first threshold amount and a second threshold amount greater than the first threshold amount. In response to determining that the metric changes by more than the first threshold amount, the data protection system may perform a first remedial action (e.g., convert one or more recent snapshots into provisionally protected snapshots). Subsequently, if the data protection system determines that the metric changes by more than the second threshold amount, the data protection system may perform a second remedial action (e.g., convert the provisionally protected snapshot into a fully protected snapshot that has more protection than the provisionally protected snapshot). In some examples, if the second threshold amount is not reached within a predetermined time period, one or more provisionally protected snapshots may be converted back to regular snapshots or may be deleted.

In some examples, a storage system, such as any of the illustrative storage systems described herein, may be configured to organize and present data stored at storage resources for access by one or more clients via a file system. The file system may organize the data using a hierarchy of various directories and subdirectories, such as a root directory and subdirectories within the directory tree of the root directory.

The file system may be configured to provide managed directories and features associated with managed directories. To this end, one or more directories of the file system may be associated with various managed entities that are used to provide storage management functionality to the content of the respective directories. For example, a managed entity may be configured to apply storage management functionality of a storage system to the content of a directory to which the managed entity is associated. Consequently, the directory may be considered a managed directory. The content of the managed directory may be a tree of files and/or directories within the directory tree of the managed directory that, through association with the managed entity, all share an association with management metadata such that one or more storage management functions may be applied to the tree of files and/or directories as a group. For example, the tree of files and/or directories within the directory tree of the management directory may be replicated, cloned, versioned, and/or snapshotted as a group. Management metadata may include quotas and other limits on capacity consumption, quality of service grouping, capacity and performance reporting, user access controls, and/or user-based visibility to the content (or even existence) of the managed directory and its encompassed tree of files and/or directories. Thus, the managed directory provides a management structure shared by all files and directories within the directory tree of the managed directory. For example, the directory tree of files and directories is linked to common metadata that is used to apply policies and/or management functions to everything in the directory tree.

A managed entity may facilitate the application of storage management functionality to the content of its associated directory in any suitable way. For example, the managed entity may include, maintain, and/or use management metadata for the content of the directory to apply storage management functionality to the content of the directory as a group. In some embodiments, one or more policies may be associated with (e.g., may be attached to or included in) the managed entity such that those policies are applied by storage management functionality to the content of the directory as a group. The one or more policies may include any suitable type of policy, including for example policies for snapshots, replication, backup, cloning, versioning, garbage collection, compression, encryption, retention, quota management, consumption management, user access controls, user-based visibility filtering, exporting, etc. In some examples, metadata of the files and directories within the directory tree of a managed directory may include references to the managed entity associated with the managed directory, for example as metadata associated with the individual files and directories.

The file system may include one or more managed directories. As an example, the root directory may be a managed directory, any subdirectory within the root directory may be a managed directory, and/or any subdirectory at any hierarchical level within the directory tree of the root directory may be a managed directory.

In some implementations, managed directories may be hierarchical, where a managed directory can be within another managed directory. In general, the “inner” managed directory is considered part of the “outer” managed directory for “outer” managed directory reporting, limits, and operations, but the “outer” managed directory is not considered part of the “inner” managed directory for reporting, limits, and operations applied separately to the “inner” managed directory.

The storage system may create a managed directory by creating and associating a managed entity with a directory. The storage system may perform such operations based on user input, in response to a command, (e.g., a command to create a directory, a command to create a managed directory, a command to convert a directory into a managed directory), and/or in response to detecting that one or more managed directory criteria are satisfied.

The storage systems described above may be managed or accessed via a variety of interfaces. Such interfaces may include, for example, command line interfaces, graphical user interfaces, various management consoles, and so on. Such interfaces may be paired with (or include) AI or generative AI capabilities including, for example, generative AI assistants, generative AI tools to create policies (e.g., security policies, data protection policies, replication policies), generative AI tools to analyze and summarize system performance, or generative AI tools to perform any other type of diagnostic investigation, and many others.

In some embodiments, a generative AI tool such as an LLM may operate as an interface to the storage systems. In fact, multiple LLMs may be available, or special purpose Small Language Models (SLMs) may be deployed for specific purposes. For example, one SLM may be deployed to operate as a generative AI assistant that can be specially trained on documents such as user manuals for the storage system, help pages for the storage system, support tickets for the storage systems, and so on. In this example, the generative AI assistant may be specially trained to answer user questions regarding managing the storage system, configuring the storage system, and the like. In another example, a second SLM may be trained on security-related information (e.g., ransomware documentation and best practices, information provided via the MITRE ATT&CK framework) such that the second SLM can be used to help a storage admin understand best practices and current threats to secure their storage systems. Readers will appreciate that many other SLMs or LLMs may be used for many purposes such as expanding analytics capabilities, improving oversight, understanding best practices, and so on. Depending on the specific purpose, models may be specially trained and/or leverage topic-specific RAG knowledge bases.

The storage systems described above may also be used as a part of a larger framework for enabling AI applications, as the storage systems may be paired with one or more GPUs and may implement different interfaces (e.g., GPUDirect) that are used to optimize storage access and storage operations for AI workloads. Likewise, the storage systems may be configured with software and other tools (e.g., vector databases) to better condition data for usage in AI workloads. In such a way, various versions of the storage systems described above may be specifically configured to better service AI workloads, versus how a storage system might be configured to service general I/O-based workloads. This can be true of hardware-based storage systems as well as the cloud-based storage systems described above. For example, the cloud-based storage systems may even leverage AI-focused cloud resources (e.g., the virtualized storage system controllers may be implemented using (or coupled to) GPU-enabled virtual machines such as Azure NC-series that provide for accelerated data exchanges amongst GPUs and GPUs-storage), or be configured in some other way that is aimed at improving the performance of AI workloads that leverage the cloud-based storage systems.

Recent advancements in generative artificial intelligence (GenAI) and the emergence of agentic AI architectures have fundamentally transformed infrastructure requirements. GenAI models are designed to synthesize, generate, or translate high-dimensional data such as text, images, audio, and code. Agentic AI systems go further by exhibiting autonomous and goal-directed behaviors that interact dynamically with data, services, and digital environments. These capabilities introduce new challenges for storage infrastructure, which must handle diverse datasets while also supporting intelligent and adaptive mechanisms for data access, movement, and orchestration.

Generative AI workloads require access to vast volumes of both static and dynamic data, including prompts, embeddings, model checkpoints, and output artifacts. As such, the storage platforms described here can be optimized for high throughput and low latency across both structured and unstructured formats. For example, flash-based systems described herein can provide the responsiveness necessary for real-time inference, while the object storage platforms described herein can offer scalable architectures with rich metadata capabilities that suit the complex data representations used in multimodal AI models. In embodiments where a hybrid environment is deployed, intelligent data placement strategies help ensure that frequently accessed data resides near compute resources, while infrequently accessed content is moved to more efficient archival systems that remain available on demand.

The introduction of agentic AI systems adds an additional layer of operational complexity. These systems function independently of human operators and are capable of forming objectives, issuing commands, and carrying out tasks based on dynamic conditions. To support such behavior, the storage platforms described here provide comprehensive programming interfaces and telemetry mechanisms. These allow agents to discover relevant data, conduct metadata queries, initiate snapshot creation, transfer data between storage tiers, and trigger workflow automation based on evolving goals or contextual feedback.

The storage systems described here can be enhanced with internal AI capabilities. For example, embedded models can be used to summarize logs, identify anomalies, generate configuration files, and recommend performance policies. By learning from observed access patterns and workload behavior, the storage systems described here can optimize caching, manage data distribution, and scale resources proactively in response to user demand. These intelligent adjustments create an adaptive feedback loop that minimizes manual intervention and improves system efficiency over time.

As AI becomes more autonomous and pervasive, the role of governance and accountability frameworks within storage environments becomes increasingly important. The storage platforms described here can therefore play a critical role in enforcing policy compliance, tracking data lineage, managing retention schedules, and supporting transparency across regulatory domains. As such, the storage systems disclosure here can integrate governance features such as tamper-resistant audit records, role-aware access controls, automated labeling mechanisms, and geographically aware data residency enforcement to help ensure that stored content remains trustworthy and aligned with legal or organizational requirements. These protections are especially vital when autonomous agents operate across distributed systems or manage sensitive content without direct human oversight.

To further support intelligent behavior and contextual awareness, the storage platforms described herein can incorporate semantic indexing and knowledge graph technologies. Rather than relying on traditional folder structures or keyword searches, these storage systems can apply structured models to express meaning, relationships, and metadata associations among data elements. For instance, an object in a storage platform might be annotated with a topic, author information, sensitivity classification, and links to related data sets, forming a graph-based representation. When integrated with GenAI and agentic systems, these semantic layers can enable advanced forms of content discovery, contextual inference, and dynamic workflow construction. This approach supports storage interactions that go beyond simple retrieval to include reasoning, learning, and autonomous navigation of knowledge-rich environments.

The rapid evolution of quantum computing presents another long-term consideration for secure storage. Because quantum processors can be capable of breaking widely used cryptographic methods, the storage platforms of the present disclosure can support quantum-resistant encryption technologies and adhere to emerging post-quantum cryptographic standards. These adaptations may include hardware-secure implementations of quantum-safe key exchanges, updates to encryption libraries, and the ability to re-encrypt archived content using quantum-resilient algorithms. Such measures may be important for sectors that require durable confidentiality, such as healthcare, finance, and national defense, and for applications where stored data must remain protected for decades.

The convergence of generative and agentic AI with modern storage infrastructure marks a critical shift in how data is managed, utilized, and safeguarded. Flash arrays, hybrid cloud environments, object-based repositories, and block-based systems are no longer limited to static data storage. In some embodiments, the systems described herein can be active participants in intelligent ecosystems, supporting semantic understanding, adaptive behavior, secure operations, and autonomous collaboration. They provide the foundation for scalable, policy-compliant, future-ready systems capable of supporting the next generation of AI-driven workloads.

The storage systems described above may be further configured to include computer program instructions to impact the operation of the storage systems described above. For example, the storage system controllers or other entity (such as one or more physical/virtual computing devices that sit above a layer of storage systems) may execute computer program instructions that effectively provide for various performance tiers within the storage systems, where certain volumes, files, objects, or other entity is provided with performance guarantees that are enforced at the software-level (rather than being placed in high-performance storage, placed close to a processor, and so on). Likewise, such software may be used to offer different types of data storage (e.g., file storage, object storage, block storage) using a pool of underlying, back-end storage resources via a single control plane (i.e., a single global namespace). In other embodiments, other aspects of system performance may also be enforced at the software-level rather than placing data in some way to achieve some desired service or performance outcome.

In some embodiments, the storage systems described above may be used to form a data lake (or data lakehouse). Given that the storage systems can provide parallel file systems, one or more of the storage systems may be used to provide a scalable, machine-learning-based AI processing and analytics data storage platform. Such systems may be configured to support GPU Direct Storage (GDS) or similar technologies to enable the direct transfer of data between storage and GPUs to provide a unified data platform for analytics and AI, and may even support retrieval-augmented generation (RAG).

Readers will appreciate that many of the embodiments described above relate to embodiments where various functions are performed by storage system controllers that are distinct from the underlying storage media (e.g., flash core modules, direct flash modules, vendor-specific flash storage devices or modules, purpose built flash storage devices or modules, SSDs, Storage class memory (SCM), or other non-volatile storage media). In other embodiments, however, the underlying storing media may include processing devices such as FPGAs, ASICs, CPUs, processing cores, or some other processing device that can be used to execute computer program instructions that carry out the functions described above. Such computer program instructions may be stored in flash memory or some other storage that can be accessed by the processing devices. In such a way, any of the functions described above may be carried out by processing logic that is more closely coupled to the underlying storage media, rather than being performed by the storage system controllers that are described above.

Although some embodiments are described largely in the context of a storage system, readers of skill in the art will recognize that embodiments of the present disclosure may also take the form of a computer program product that includes instructions that, when executed, cause a computing device (e.g., one or more of the computing devices described herein) to perform a process that includes any of the operations or steps described herein. In some examples, the computer program product is embodied in or disposed upon a non-transitory computer readable storage medium for use with any suitable processing system. The non-transitory computer readable storage medium may be any storage medium for machine-readable information, including magnetic media, optical media, solid-state media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps described herein as embodied in a computer program product. Persons skilled in the art will recognize also that, although some of the embodiments described in this specification are oriented to software installed and executing on computer hardware, nevertheless, alternative embodiments implemented as firmware or as hardware are well within the scope of the present disclosure.

In some examples, a non-transitory computer-readable medium storing computer-readable instructions may be provided in accordance with the principles described herein. The instructions, when executed by a processor of a computing device, may direct the processor and/or computing device to perform one or more operations, including one or more of the operations described herein. Such instructions may be stored and/or transmitted using any of a variety of known computer-readable media.

A non-transitory computer-readable medium as referred to herein may include any non-transitory storage medium that participates in providing data (e.g., instructions) that may be read and/or executed by a computing device (e.g., by a processor of a computing device). For example, a non-transitory computer-readable medium may include, but is not limited to, any combination of non-volatile storage media and/or volatile storage media. Exemplary non-volatile storage media include, but are not limited to, read-only memory, flash memory, a solid-state drive, a magnetic storage device (e.g., a hard disk, a floppy disk, magnetic tape, etc.), ferroelectric random-access memory ("RAM"), and an optical disc (e.g., a compact disc, a digital video disc, a Blu-ray disc, etc.). Exemplary volatile storage media include, but are not limited to, RAM (e.g., dynamic RAM).

Advantages and features of the present disclosure can be further described by the following statements:

One or more embodiments may be described herein with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

While particular combinations of various functions and features of the one or more embodiments are expressly described herein, other combinations of these features and functions are likewise possible. The present disclosure is not limited by the particular examples disclosed herein and expressly incorporates these other combinations.

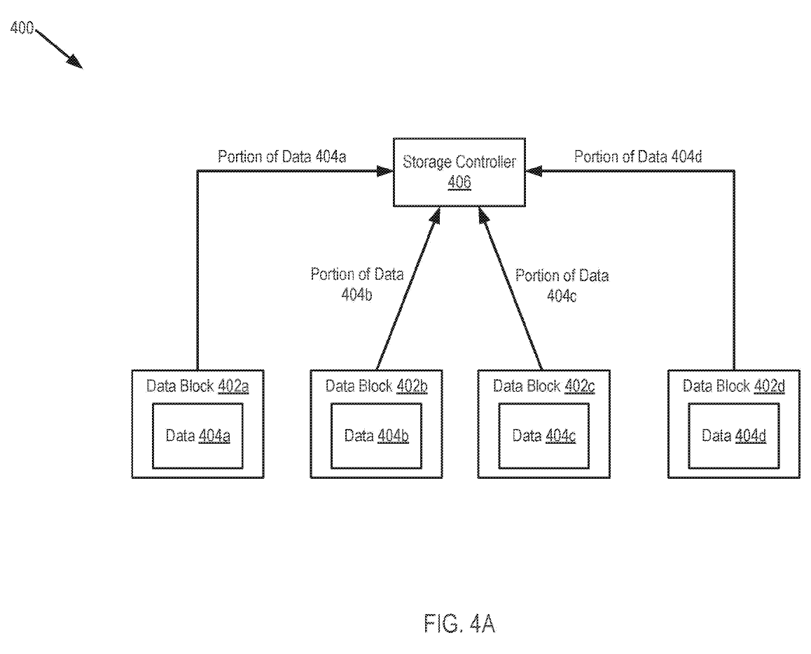

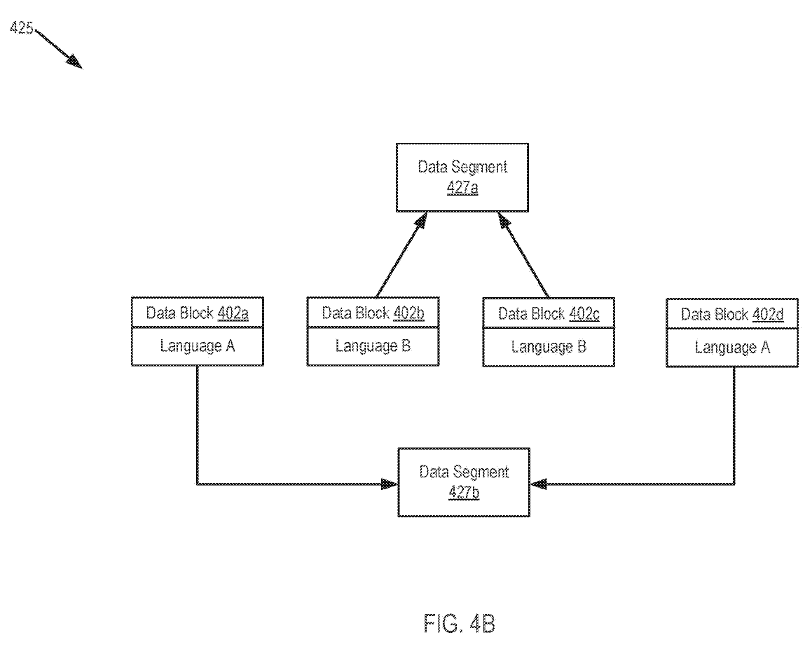

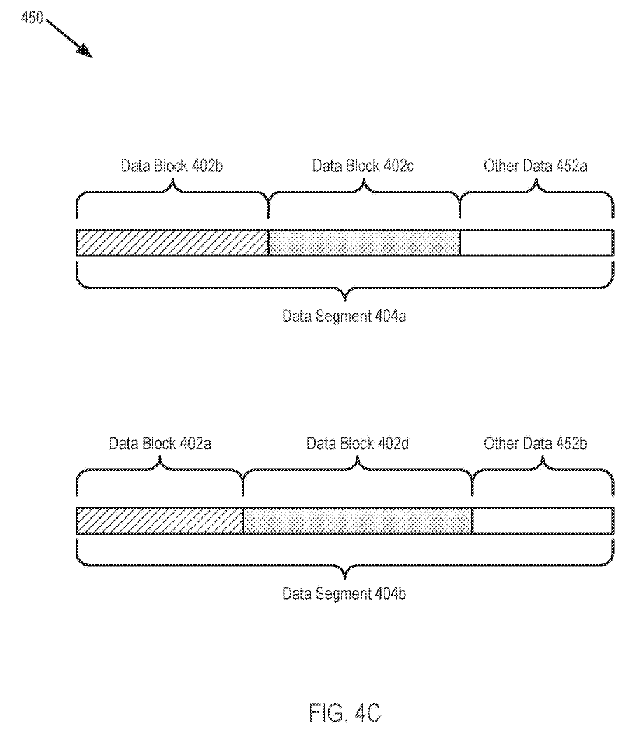

FIG. 4A is an illustration 400 of an example of storing data blocks to data segments based on languages associated with the data blocks in accordance with embodiments of the disclosure. Illustration 400 includes data blocks 402 a-d of one or more storage devices of a storage system, such as one of the storage systems as previously described at FIGS. 1A-3D. Data blocks 402 a-d may each store data 404 a-d that consists of multiple bits of data stored at each of data blocks 402 a-d. It should be noted that data 404 a-d are shown for illustrative purposes only and are not physical components of the storage system.

In embodiments, illustration 400 may be a part of a garbage collection process of the storage system. For example, data blocks 402 a-d may include data read from one or more data segments of the storage system that is to be relocated to a different location of the storage system as part of a garbage collection process. In other embodiments, data 404 a-d may correspond to new data received from a host system that is to be stored at the storage system.

A storage controller 406 of the storage system may identify data blocks 402a-d that each store data 404 a-d. Upon identifying the data blocks 402 a-d, the storage controller 406 may read a portion of each of data 404 a-d. In embodiments, the portion of data 404 a-d may correspond to one or more top bits of data of each of data 404 a-d. For example, the portion of data 404 a-d may correspond to the top three bits of each of data 404 a-d. The portion of the data (e.g., portions of data 404 a-d) read by the storage controller 406 may serve as an indicator of the properties of the underlying data (e.g., data 404 a-d). For example, if the top 3 bits of data correspond to American Standard Code for Information Interchange (ASCII) code for English characters, then the top 3 bits indicate that the underlying data likely contains mostly English text.

FIG. 4B is an illustration 425 of an example of a storage controller assigning data blocks to data segments based on an associated property in accordance with embodiments of the disclosure. Upon reading the portions of the data from data blocks 402 a-d, as previously described at FIG. 4A, the storage controller (not shown) may determine one or more properties of data blocks 402 a-d using the portions of the data as indicators of the data stored at data blocks 402a-d. For example, the storage controller may determine that a first data block includes mostly English text, a second data block includes mostly x86 code and a third data block includes mostly database tables.

In illustration 425, the storage controller has determined that data block 402 a and data block 402d include mostly Language A text, while data block 402 b and data block 402 c include mostly Language B text. Because both data block 402b and data block 402 c include mostly Language B text, the storage controller may assign data block 402 b and data block 402 c to data segment 427a. Similarly, because both data block 402 a and data block 402d include mostly Language A text, the storage controller may assign data block 402 a and data block 402 d to data segment 427 b. Although shown as assigning data blocks to data segments based on languages associated with the data stored at the data blocks, in embodiments the data blocks may be assigned to data segments based on other properties associated with the data.

FIG. 4C is an illustration 450 of an example of storing data blocks within data segments in accordance with embodiments of the present disclosure. Upon assigning data block 402 b and data block 402c to data segment 427a, data block 402b and data block 402 c may be stored within data segment 427 a along with other data 452a. Similarly, upon assigning data block 402 a and data block 402d to data segment 427b, data block 402a and data block 402 d may be stored within data segment 427b along with other data 452b.

As previously described, in lossless compression, the efficiency of the compression operation is based, in part, on the proximity of data to other, similar data. Data having similar properties, such as similar languages, will likely have more redundancies than data having dissimilar properties. Therefore, by storing data block 402 b in close proximity to data block 402 c (which both have mostly Language B text) within data segment 427a, the efficiency of a compression operation performed on the data stored at data block 402b and data block 402 c is increased. Similarly, by storing data block 402 a in close proximity to data block 402d (which both have mostly Language A text) within data segment 427b, the efficiency of a compression operation performed on the data stored at data block 402a and data block 402d is increased.

In some embodiments, the other data 452a may have similar properties to data block 402 b and data block 402 c and/or the other data 452b may have similar properties to data block 402 a and data block 402d. For example, the other data 452 a may include mostly Language B text and the other data 452b may include mostly Language A text. In embodiments, the other data 452a and the other data 452b may have dissimilar properties to data block 402 b and 402 c and/or the other data 452 b may have dissimilar properties to data block 402 a and data block 402 d. For example, the other data 452 a may include one or more data blocks that include data having mostly Language C text.

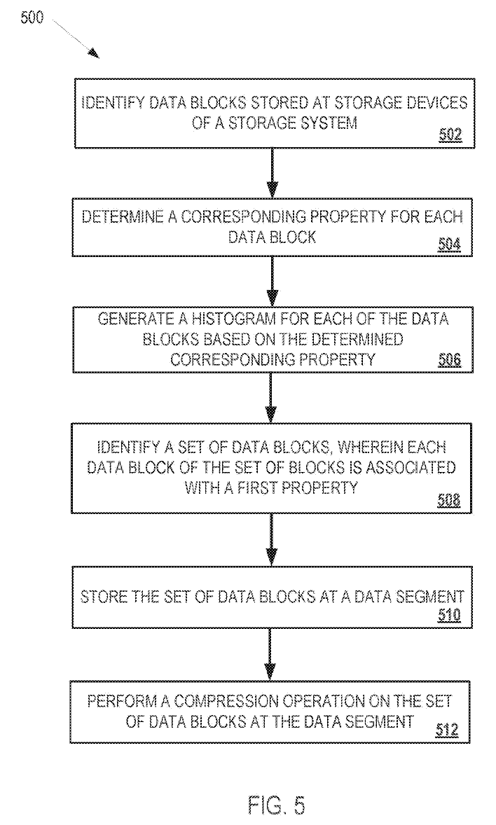

FIG. 5 is an example method 500 to store data blocks having similar properties within a data segment in accordance with embodiments of the disclosure. In general, the method 500 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a storage controller of a storage system, as previously described at FIGS. 1A-3D, may perform the method 500.

Method 500 begins at block 502, where the processing logic identifies data blocks stored at one or more storage devices of a storage system. In some embodiments, the processing logic may identify the data blocks during a garbage collection process. For example, the processing logic may identify the data blocks that include data that is to be kept from data segments that are being garbage collected.

At block 504, the processing logic determines a corresponding property for each data block. In embodiments, the processing logic may determine the corresponding property for each data block by reading a portion of data stored at each of the data blocks, as previously described. In some embodiments, the property may correspond to a language/programming language associated with the data stored at the data block. For example, the property may correspond to the data including mostly English text, mostly x86 code, etc. In embodiments, the property may correspond to a type of data stored at the data block. For example, the property may correspond to the data including mostly database tables, metadata, user data, etc. In an embodiment, the property may correspond to whether or not the data in the data block is compressible. For example, certain types of data, such as image or video files, may not be compressible.

Accordingly, for these types of data, the property may indicate that the data of a data block is uncompressible. In embodiments, multiple properties of the data stored at each data block may be used.

At block 506, the processing logic generates a histogram for each of the data blocks based on the determined corresponding property. The histogram may be a representation where data associated with the properties is grouped into ranges and plotted. In embodiments, the groups of the histogram may correspond to groups of 8-bit ASCII code, which consists of 255 different numbers that correspond to various control codes and printable characters (e.g., letters, digits, punctuation marks). For example, the first group of the histogram may correspond to ASCII numbers 0-31, the second group of the histogram may correspond to ASCII numbers 32-63, etc. The histogram for the data blocks may be normalized into a 0-255 range for the 8-bit ASCII code. Using 8 groups for the histogram of the 8-bit ASCII code and counts from the 0-255 range, the histogram may be represented as a 64-bit number.

At block 508, the processing logic identifies a set of data blocks that are each associated with a first property. For example, the processing logic may identify a set of data blocks that each include mostly English text. In some embodiments, the processing logic may identify the set of data blocks based on the histograms generated for each of the data blocks at block 506. For example, the processing logic may sort the data blocks using the 64-bit number representing the histogram and identify data blocks based on the data blocks having a same or similar 64-bit number. Because each of the groups of the histogram represents a different type of characters in the ASCII code, data blocks having the same or similar number will likely use similar types of characters and therefore will likely have similar properties and/or use a similar language.

At block 510, the processing logic stores the set of data blocks at a data segment, as previously described.

At block 512, the processing logic performs a compression operation on the set of data blocks at the data segment. The compression operation may utilize a lossless compression algorithm. In some embodiments, the compression operation may be a tar command that creates a tar archive and compresses the set of data blocks at the data segment. In embodiments, the compression operation may be a dictionary compression operation. In a dictionary compression operation, one of the data blocks of the set of data blocks is selected as a dictionary. The remaining data blocks of the set of data blocks may be compressed based on finding matches in the text of the data block selected as the dictionary. In an embodiment, the compression operation may be any type of operation that compresses the data of the set of data blocks.

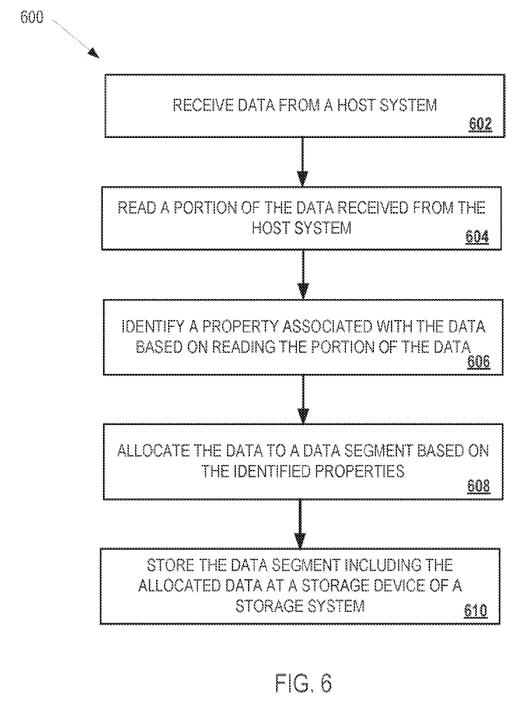

FIG. 6 is an example method 600 to allocate received data blocks to data segments based on associated properties in accordance with embodiments of the disclosure. In general, the method 600 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a storage controller of a storage system, as previously described at FIGS. 1A-3D, may perform the method 600.

Method 600 begins at block 602, where the processing logic receives data from a host system. As previously described, in some embodiments, the processing logic of the storage controller may determine properties for new data received from a host system that is to be stored at the storage system.

Upon receiving data from the host system, at block 604, the processing logic reads a portion of the data received from the host system. As discussed above, the portion of the data may serve as an indicator for one or more properties associated with the underlying data received from the host system. In some embodiments, the processing logic may generate a histogram for the data received from the host system, as previously described at FIG. 5.

At block 606, the processing logic identifies a property associated with the data based on reading the portion of the data. In embodiments, the processing logic may identify the property based on the numerical representation of the generated histogram associated with the data.

At block 608, the processing logic allocates the data to a data segment based on the identified property. The processing logic may allocate the data to a data segment that includes other data allocated to the data segment that has one or more similar properties. For example, the processing logic may allocate data including mostly database tables to a data segment that includes other data that includes mostly database tables. In another example, the processing logic may allocate uncompressible data (e.g., images, videos, etc.) to a data segment that includes other data that is uncompressible.

At block 610, the processing logic stores the data segment that includes the allocated data at a storage device of a storage system.

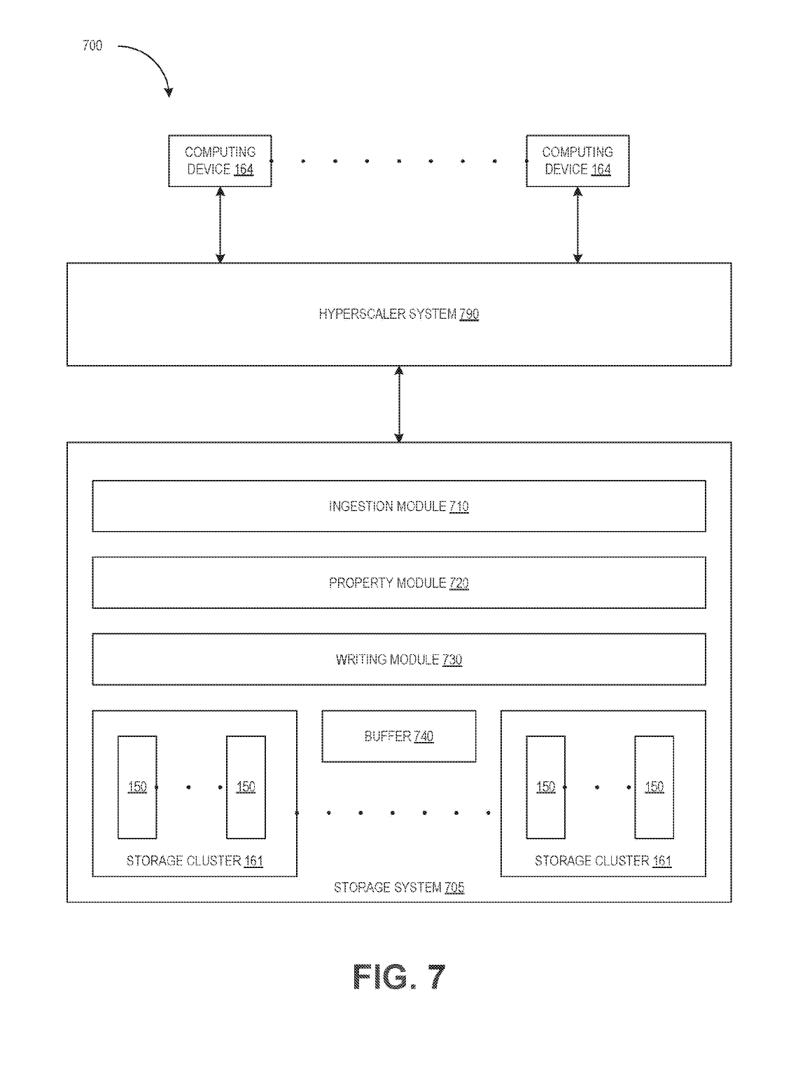

FIG. 7 is a block diagram illustrating an example system architecture 700 for storing data based on properties, in accordance with embodiments of the present disclosure. The system architecture 700 includes a hyperscaler system 790 and a storage system 705 (e.g., a data storage system). The hyperscaler system 790 may be a system/architecture that is able to scale (e.g., add and/or remove) computing, networking, and/or storage resources as need by users of the system/architecture. For example, the hyperscaler system 790 may be able to add computing power/resources to process data for hundreds, thousands, millions, billions, etc., of computing devices 164. The hyperscaler system 790 may be a distributed system that includes hardware, software, infrastructures, etc., to provide and/or scale the various resources used by the computing devices 164. The storage system 705 may store data for the hyperscaler system 790, as discussed in more detail below.

As illustrated in FIG. 7, the storage system 705 includes an ingestion module 710, a property module 720, and a writing module 730. The ingestion module 710 may receive data from the hyperscaler system 790 at a scale/volume that is appropriate for the hyperscaler system 790 (e.g., may receive terabytes, petabytes, exabytes, etc., of data at a time). The property module 720 may determine one or more properties for the data blocks, as discussed in more detail below. The storage system also includes a buffer 740, and one or more storage clusters 161 and each storage cluster 161 includes one or more storage nodes 150. The components of the storage clusters 161 and the storage nodes 150 are configured similarly to their counterparts described in connection with FIGS. 1-3F.

In one embodiment the storage system 705 may be a storage system utilizing zoned storage devices such as storage devices using and/or based on the Zoned Namespace model. For example, storage nodes 150 and/or the storage clusters 161 may include zoned storage devices. A zoned storage device may be a storage device (e.g., a flash drive, non-volatile memory, flash memory, etc.) that supports the uses of zones and/or that includes zones.

In one embodiment, the storage system 705 (e.g., the ingestion module 710 of the storage system 705) may receive a plurality of data blocks from the hyperscaler system 790 (e.g., the hyperscaler system 790 may provide, transmit, forward, etc., the data received from the computing devices 164 to the storage system 705.). For example, one or more of the computing devices 164 (e.g., laptop computers, desktop computers, server computers, tablets, tablet computers, smartphones, gaming consoles, smart devices, IoT devices, wearable devices, etc.) may transmit, send, or otherwise provide data to the hyperscaler system 790. The hyperscaler system 790 may transmit, forward, etc., the data (received from the computing devices 164) to the storage system 700 for storage within the storage system 700.

In one embodiment, the ingestion module 710 may store the plurality of data blocks (that were received from the hyperscaler system 790) in the buffer 740 (e.g., NVRAM, SLC flash memory, etc.). As discussed above, the buffer 740 may operate or function as a cache (e.g., temporary storage) for the data that will be stored in the storage system 705. The buffer 740 may store/hold the plurality of data blocks while the property module 720 determines one or more properties for the plurality of data blocks (e.g., one or more properties for each data block).

In one embodiment, the storage system 705 (e.g., the property module 720) may determine one or more properties for each data block in a plurality of data blocks received by the ingestion module 710. For example, the property module 720 may analyze, inspect, evaluate, probe, scan, etc., portions of the data blocks and/or metadata to determine one or more properties for each data block in the plurality of data blocks, as discussed in more detail below. A data block may have and/or may be associated with multiple properties.

As discussed above, a property may correspond to a language associated with the data stored at the data block, a type of data stored at the data block (e.g., media data such as video data, audio data, image data, etc., database data, data blocks filtered through a deduplication process/engine, virtual machine images, files from a file system that are stored as objects/blocks in a hyperscaler system, etc.), whether or not the data in the data block is compressible, etc. Another property may correspond to or may indicate a longevity (e.g., an estimated longevity) of the data stored at the data block. For example, a property of the data block may indicate an estimated amount of time that the data will remain in the storage system 700. In other examples, a property may indicate one or more of: a type of application that created the data block, an owner of the data block (e.g., a tenant or user account associated with the data block), a geographic region/location from which the data block was received, data governance policies associated with the data block, the size of data objects (e.g., files) that the data block is part of, etc. The properties of a data block may be determined (e.g., inferred, estimated, calculated, etc.) based on prior behavior observed from combinations of one or more properties. For example, a longevity of a data block may be determined based on how long previous data blocks from a particular user, tenant, file type, etc., were kept in the storage system 705. Various thresholds, criteria, parameters, etc., may be used to determine (e.g., calculate, estimate, etc.) the longevity of a data block. For example, the property module 720 may analyze metadata associated with a set of blocks (e.g., one or more files). In another example, the property module 720 may analyze the type of data in the set of blocks (e.g., image data, text data, video data, etc.). In a further example, machine learning may be used to analyze data blocks to determine a longevity of a data block (e.g., a property of the data block) based on previous longevities and/or storage patterns of previous data blocks. The longevity of a data block may be represented in various ways. For example, the longevity may be represented using a number, where a higher number indicates more longevity, or vice versa. In another example, the longevity may be represented using an alphanumeric string, such as short, medium, long, etc.

In one embodiment, the property module 720 may determine one or more properties for the plurality of data blocks (e.g., for each data block) based on metadata associated with the plurality of data blocks. For example, the property module 720 may analyze the metadata to determine the type of data, the owner of the data, etc. The property module 720 may determine one or more properties of a data block based on the type of data, owner of the data, etc. For example, the property module 720 may determine that a block of data may have a longer longevity because the block of data includes video data (e.g., the block of data is part of a video recording that may be stored for a longer period of time, or might be video data from a user account that has a detected pattern of delete videos after a week).

In one embodiment, the metadata for the data blocks may include or indicate one or more properties for the data blocks. For example, when a computing device 164 provides the data to the hyperscaler system 790, the computing device 164 may indicate a property (e.g., a longevity of the data blocks, such as short term, longer term, or some other appropriate period of time) when the computing device 164 transmits the data blocks to the hyperscaler system 790. The hyperscaler system 790 may include that property in metadata associated with the data blocks or the computing device 164 may transmit the metadata indicating the one or more properties. The property module 720 may determine the one or more properties of the data blocks (e.g., a longevity of a data block) based on the metadata.

In one embodiment, the property module 720 may determine one or more properties for a data block by reading a portion of the data block. The portion of the data block may be less or smaller than all of the data block. For example, the property module 720 may read one or more top bits of data (e.g., most significant bits, etc.) a data block, to determine one or more properties of the data block. The property module 720 may also analyze data/information separate from the content of the data block (e.g., other properties, metadata associated with a data block, etc.) to determine one or more properties for a data block. For example, the geographic region, user/tenant associated with the data block, application from which the data block originated, etc., may be used to determine a property of the data block (e.g., the longevity of the data block).

In one embodiment, storage system 705 (e.g., the writing module 730 of the storage system 705) may identify a set of data blocks from the plurality of data blocks. Each data block of the set of data blocks may be associated with a particular property (e.g., each data block may have a first property). For example, the writing module 730 may identify data blocks that have a property indicating that the data may shorter term data (e.g., that the data may be stored for less than a first threshold period of time). In another example, the writing module 730 may identify data blocks (e.g., a set of data blocks, one or more data blocks, etc.) that have a property which indicate that the data within the data blocks is multimedia data (e.g., audio data, image data, video data, etc.).

In one embodiment, the writing module 730 may store the set of data blocks in a first zone of the storage system 705. As discussed above, the storage system 705 may include one or more zones. The writing module 730 may instantiate or open a zone in the storage system 705 and may write the set of data blocks in the zone (e.g., may store the set of data blocks in the zone). The zone may be distributed across one or more storage nodes 150 and/or storage clusters 161.

In one embodiment, the writing module 730 may store the set of data blocks in the zone (of the storage system 705) by moving the set of data blocks from the buffer 740 to the zone of the storage system 705 (e.g., a zoned storage system). For example, the writing module 730 may copy the set of data blocks from the buffer 740 to the zone, and then delete the set of data blocks from the buffer 740.

In one embodiment, the writing module 730 may perform a garbage collection operation on a set of data blocks. For example, the writing module 730 may delete the set of data blocks during the data collection operation. As discussed above, the set of data blocks in a zone may have one or more shared properties. For example, the set of data blocks in the zone may have the same longevity (e.g., all of the data blocks may have a short term longevity). This may allow the writing module 730 to delete the data blocks in the zone at the same time. For example, the writing module 730 may be able to delete a whole zone at the same time, while writing little if any of the data elsewhere as part of garbage collection (e.g., removing most or all of the data blocks in the zone from the system entirely and deleting the zone) because most or all of the data blocks in that zone have the same longevity.

In one embodiment, the garbage collection operation may be delayed for a period/amount of time. For example, based on the longevity that was measured, recorded, etc., for the other similar data blocks, the garbage collection of the data blocks in the zone may be delayed until a threshold amount (e.g., a majority, 75%, 95%, etc.) of the data blocks in the zone are invalid. A data block may be invalid when it is no longer used, will no longer be accessed (e.g., retrieved), etc. Delaying the garbage collection based on the longevity of some of the data blocks in the zone may allow the storage system 705 to leverage invalidations of additional data blocks in the zone that may occur when the expected longevity expires. For example, delaying the garbage collection for a zone may result in additional data blocks in the zone becoming invalid (during the delay) which may allow for fewer data blocks to be rewritten during the garbage collection operation.

In some embodiments, deleting all of the data blocks in the zone at the same time may help reduce and/or prevent write amplification. For example, if some of the data in the zone is deleted but other data in the zone should not be deleted, the writing module 730 may need to copy the other data to another zone and/or portion of the storage system 705. This increase the amount of time to delete the data/zone and/or may increase the amount of wear levelling in the storage system 705. However, if all of the data in the zone has the same longevity (e.g., is stored in the storage system 705 for the same amount/period of time), then the data blocks in the zone can be deleted more efficiently since it does not require copying portions of the data to another.

In one embodiment, the writing module 730 may perform a compression operation on one or more data blocks stored in a zone. For example, the writing module 730 may identify redundancies in the data blocks for compression. Compressing the one or more data may reduce the number of bits needed to represent data stored at the storage system and may save storage capacity of the storage system.

Each of the ingestion module 710, property module 720, and writing module 730 may include hardware (e.g., a processor, FPGA, a circuit, etc.), software, and/or firmware for performing the various operations, actions, functions, etc., described herein. For example, each of the ingestion module 710, property module 720, and writing module 730 may include computing devices or processors that may read data, determine properties of data, and/or store data in the storage system 705. In some embodiments, the operations, actions, functions, may be performed by one or more processors of one or more storage nodes 150. For example, the ingestion module 710, property module 720, and writing module 730 may include processors that are in one or more storage nodes 150.

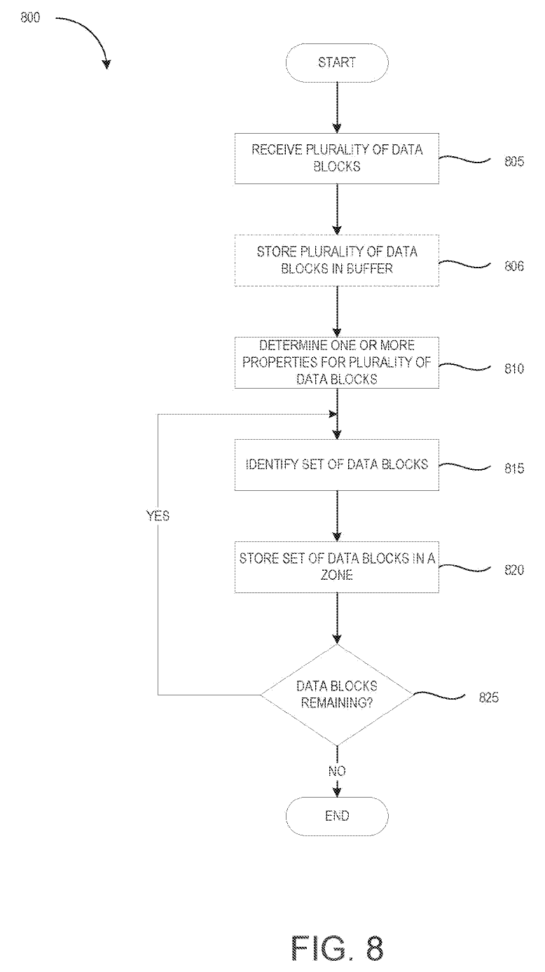

FIG. 8 is an example method 800 to store data blocks in a storage system, in accordance with embodiments of the disclosure. In general, the method 800 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a storage controller of a storage system, as previously described at FIGS. 1-3E may perform the method 800.

With reference to FIG. 8, method 800 illustrates example functions used by various embodiments. Although specific function blocks (“blocks”) are disclosed in method 800, such blocks are examples. That is, embodiments are well suited to performing various other blocks or variations of the blocks recited in method 800. It is appreciated that the blocks in method 800 may be performed in an order different than presented, and that not all of the blocks in method 800 may be performed, and other blocks (which may not be included in FIG. 8 ) may be performed between the blocks illustrated in FIG. 8.

Method 800 begins at block 805, where the method 800 receives a plurality of data blocks to be stored in the storage system. The plurality of data blocks may be received from a hyperscaler system, as discussed above. The method 800 may store the plurality of data blocks in a buffer at lock 806. For example, the method 800 may store the plurality of data blocks in NVRAM, SLC flash, etc.

At block 810, the method 800 may determine one or more properties the plurality of data blocks. For example, the method 800 may analyze metadata and/or portions of the data blocks to determine the one or more properties. The method 800 may determine one or more properties of each of the plurality of data blocks.

At block 815, the method 800 may identify a set of data blocks (from the plurality of data blocks) based on one or more properties. For example, the method 800 may identify a set of data blocks that has a same and/or similar longevity. In another example, the method 800 the method 800 may identify a set of data blocks that has a same longevity and include video data.

At block 820, the method 800 may store the set of data blocks in a zone of the storage system. As discussed above, the storage system may be a zoned storage system that includes one or more zoned storage devices and/or may support the use of zones. The method 800 may store the set of data blocks in the zone by moving (e.g., copying) the set of data blocks from the buffer to the zone.

At block 825, the method 800 may determine whether there are any remaining data blocks to be stored in the storage system. For example, the method 800 may determine whether all of the blocks in the plurality of data blocks (received at block 805) have been stored. If there are data blocks remaining, the method 800 may proceed back to block 815), where the method 800 may identify one or more additional sets of data blocks based on one or more additional properties (e.g., at block 815) and store the one or more additional sets of data blocks in the storage array (e.g., at block 820).

While this specification contains many specific implementation details, these should not be construed as limitations on the scope of any inventions or of what may be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

Advantages and features of the present disclosure can be further described by the following statements.

A method of determining, by a storage system controller, a group size for grouping a plurality of data blocks stored on a plurality of storage devices, the group size based on one or more garbage collection performance parameters; grouping the plurality of data blocks into a plurality of groups having the determined group size based on corresponding lifespans associated with the plurality of data blocks; and selecting one or more of the plurality of groups for garbage collection.

The method of statement 1, wherein the corresponding lifespans are based on corresponding ages of the plurality of data blocks.

The method of statement 2 or statement 1, wherein grouping the plurality of data blocks comprises assigning different corresponding lifespan ranges to the plurality of groups and grouping a set of data blocks into a particular group based on the corresponding lifespans falling within a corresponding lifespan range of the particular group.

The method of statement 3, statement 2, or statement 1, wherein the one or more garbage collection performance parameters comprise data block occupancy.

The method of statement 4, statement 3, statement 2, or statement 1, further comprising prioritizing grouping, for garbage collection, data blocks having lower data block occupancy relative to data blocks having higher data block occupancy.

The method of statement 5, statement 4, statement 3, statement 2, or statement 1, wherein the group size corresponds to a number of data blocks selected as a batch for garbage collection.

The method of statement 6, statement 5, statement 4, statement 3, statement 2, or statement 1, further comprising adjusting the group size based on an eviction pattern corresponding to one or more prior garbage collection cycles.

A storage system comprising a plurality of storage devices and a storage system controller operatively coupled to the plurality of storage devices, the storage system controller configured to determine a group size based on one or more garbage collection performance parameters; group a plurality of data blocks into a plurality of groups having the determined group size based on corresponding lifespans; and select one or more of the plurality of groups for garbage collection.

The storage system of statement 8, wherein the corresponding lifespans are based on corresponding ages of the plurality of data blocks.

The storage system of statement 9 or statement 8, wherein the storage system controller is configured to assign different corresponding lifespan ranges to the plurality of groups and group data blocks into a particular group based on the corresponding lifespans falling within a corresponding lifespan range.

The storage system of statement 10, statement 9, or statement 8, wherein the one or more garbage collection performance parameters comprise data block occupancy.

The storage system of statement 11, statement 10, statement 9, or statement 8, wherein the storage system controller is further configured to prioritize grouping, for garbage collection, data blocks having lower data block occupancy relative to data blocks having higher data block occupancy.

The storage system of statement 12, statement 11, statement 10, statement 9, or statement 8, wherein the group size corresponds to a number of data blocks selected as a batch for garbage collection.

The storage system of statement 13, statement 12, statement 11, statement 10, statement 9, or statement 8, wherein the storage system controller is further configured to adjust the group size based on an eviction pattern corresponding to prior garbage collection cycles.

A non-transitory computer readable storage medium storing instructions that, when executed, cause a storage system controller to determine a group size based on one or more garbage collection performance parameters; group a plurality of data blocks into a plurality of groups having the determined group size based on corresponding lifespans; and select one or more of the plurality of groups for garbage collection.

The non-transitory computer readable storage medium of statement 15, wherein the corresponding lifespans are based on corresponding ages of the plurality of data blocks.

The non-transitory computer readable storage medium of statement 16 or statement 15, wherein grouping comprises assigning different lifespan ranges to the plurality of groups and grouping data blocks based on the corresponding lifespan ranges.

The non-transitory computer readable storage medium of statement 17, statement 16, or statement 15, wherein the one or more garbage collection performance parameters comprise data block occupancy.

The non-transitory computer readable storage medium of statement 18, statement 17, statement 16, or statement 15, wherein the instructions further cause the storage system controller to prioritize grouping of data blocks having lower data block occupancy.

The non-transitory computer readable storage medium of statement 19, statement 18, statement 17, statement 16, or statement 15, wherein the group size corresponds to a batch size for garbage collection.

Embodiments of the disclosure provide for a storage system controller configured to dynamically group data blocks for garbage collection based on data characteristics and system performance parameters.

Conventional storage systems typically rely on rigid allocation and reclamation strategies for organization of data blocks. For example, data blocks are often written sequentially or placed into segments based primarily on availability rather than underlying data characteristics, resulting in segments that contain heterogeneous data with varying types, compressibility, and lifespans. During garbage collection, these conventional systems may select segments for reclamation based on simple thresholds, such as overall occupancy or age, without regard to the similarity of data within the segment. As a result, valid data is frequently intermixed with invalid or stale data, requiring the system to relocate and rewrite large portions of still-valid data during reclamation operations. These conventional techniques lead to increased write amplification, higher latency, and inefficient utilization of storage resources.

Embodiments of the disclosure remedy the above and other deficiencies by providing a storage system controller that is configured to dynamically group data blocks for efficient garbage collection based on data characteristics and system performance parameters.

In some embodiments, the storage system controller is configured to determine a group size for grouping data blocks that are stored across storage devices in the storage system. The group size may be based on one or more garbage collection performance parameters. The storage system controller groups data blocks into groups having the determined group size based on corresponding lifespans associated with the data blocks and selects one or more of the groups for garbage collection. By dynamically determining grouping parameters and selecting groups for reclamation, the storage system controller improves garbage collection efficiency and overall storage system performance.

In some embodiments, the storage system controller determines corresponding lifespans associated with the data blocks using metadata maintained for the data blocks. The metadata may include, for example, data block age, invalidation history, update frequency, or other indicators of expected data longevity. In some embodiments, the corresponding lifespans are based on corresponding ages of the data blocks. The storage system controller groups data blocks having similar lifespans into the same group, thereby enabling more efficient reclamation of invalid or stale data.

In some embodiments, the storage system controller assigns different lifespan ranges to respective groups and groups data blocks according to the assigned lifespan ranges. For example, the storage system controller may group a set of data blocks into a particular group when corresponding lifespans of the set of data blocks fall within a corresponding lifespan range of the particular group. In this manner, data blocks having similar expected invalidation times are co-located within groups, which improves the likelihood that a group selected for garbage collection contains a higher proportion of reclaimable storage.

In some embodiments, the storage system controller determines the group size based on one or more garbage collection performance parameters, including data block occupancy. The storage system controller may assign higher priority to groups having lower data block occupancy relative to groups having higher data block occupancy when selecting groups for garbage collection. By prioritizing groups with lower occupancy, the storage system controller improves reclamation efficiency and reduces unnecessary data movement. In some embodiments, the storage system controller dynamically adjusts the group size based on an eviction pattern corresponding to prior garbage collection cycles. The eviction pattern may include patterns of invalidation, reclamation efficiency, or observed performance characteristics associated with previously selected groups. The storage system controller aggregates information from prior garbage collection cycles and modifies the group size to improve subsequent garbage collection operations. For example, the storage system controller may increase the group size when prior garbage collection cycles indicate low reclamation efficiency or decrease the group size when latency constraints or resource utilization thresholds are exceeded.

Aspects of the disclosure provide an improved storage system that enables adaptive, lifespan-aware grouping of data blocks for garbage collection. Through the use of group size determination, lifespan-based grouping, occupancy-aware selection, and adaptive tuning, the storage system achieves improved resource utilization, enhanced performance, and more consistent behavior across diverse storage environments.

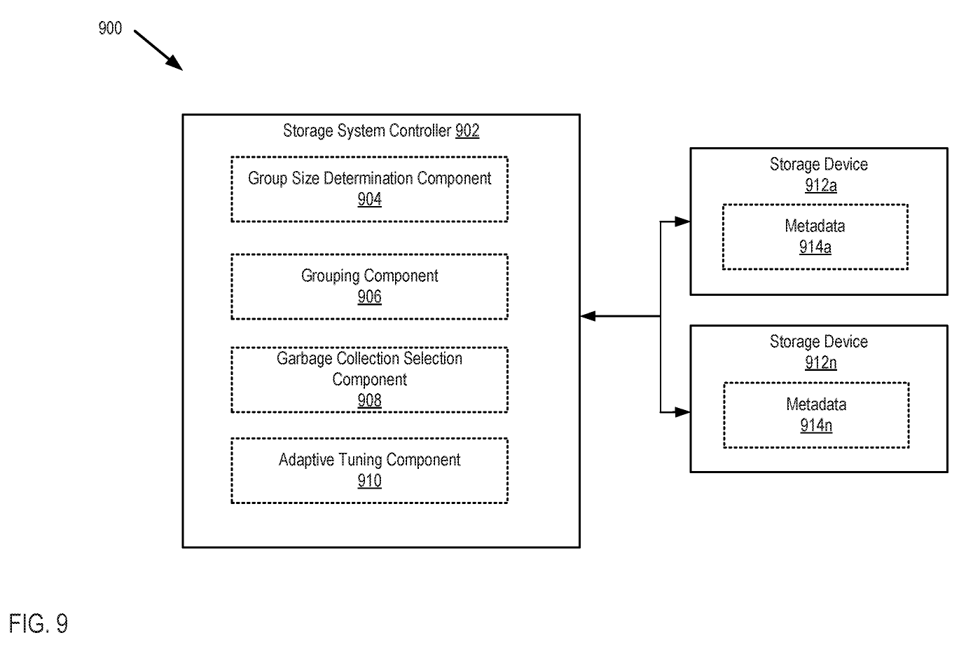

Referring now to FIG. 9, an example storage system 900 that is configured to perform adaptive grouping of data blocks for garbage collection is illustrated in accordance with embodiments of the disclosure. Storage system 900 may correspond to any of the storage systems previously described in FIGS. 1A-3G. For clarity, some components of storage system 900 are not shown.

The storage system 900 includes storage devices 912a-912n and a storage system controller 902 operatively coupled to the storage devices 912a-912n. The storage devices 912a-912n may include non-volatile memory devices, such as NAND flash memory, and may store data blocks across multiple memory regions. In some embodiments, each of the storage devices 912a-912n includes associated metadata 914a-914n that describes characteristics of stored data blocks, including, for example, data block age, occupancy, validity, update frequency, or other attributes relevant to garbage collection operations.

The storage system controller 902, or any processing logic as described above, may be configured to determine grouping strategies for garbage collection. In some embodiments, the storage system controller 902 includes a group size determination component 904 configured to determine a group size for grouping data blocks stored on the storage devices 912a-912n. The group size may correspond to a number of data blocks selected as a batch for garbage collection. The group size determination component 904 may determine the group size based on one or more garbage collection performance parameters, including, for example, data block occupancy, reclaim efficiency, latency, write amplification, or device utilization.

The storage system controller 902 further includes a grouping component 906 configured to group the data blocks into groups having the determined group size. In some embodiments, the grouping component 906 groups data blocks based on corresponding lifespans associated with the data blocks. The corresponding lifespans may be determined using metadata maintained by the storage system, including, for example, data block age or historical invalidation patterns. In some embodiments, the corresponding lifespans may be determined, estimated, or predicted based on metadata, historical behavior, or one or more models trained to estimate data longevity. In some embodiments, the grouping component 906 groups data blocks having similar lifespans into the same group so that data blocks expected to become invalid within similar timeframes are co-located.

In some embodiments, the grouping component 906 assigns different lifespan ranges to respective groups and groups data blocks according to the assigned lifespan ranges. For example, the grouping component 906 may group a set of data blocks into a particular group when corresponding lifespans of the set of data blocks fall within a corresponding lifespan range of that group. In some embodiments, the grouping component 906 may utilize metadata structures, mapping tables, or historical statistics to determine lifespan ranges and assign data blocks accordingly.

The storage system controller 902 further includes a garbage collection selection component 908 configured to select one or more of the groups for garbage collection. In some embodiments, the storage system controller 902 may evaluate characteristics of the groups, including data block occupancy, proportion of invalid data, or expected reclaimable storage. The storage system controller 902 may prioritize grouping, for garbage collection, data blocks having lower data block occupancy in comparison to data blocks having higher data block occupancy, thereby improving reclamation efficiency.

The storage system controller 902 further includes an adaptive tuning component 910 configured to adjust the group size based on an eviction pattern corresponding to prior garbage collection cycles. The eviction pattern may include patterns of invalidation, reclamation efficiency, or other performance characteristics observed during prior garbage collection operations. In some embodiments, the storage system controller 902 aggregates information from prior garbage collection cycles and adjusts the group size to improve subsequent garbage collection performance.

In some embodiments, the storage system controller 902 may dynamically update grouping decisions as system conditions change, including as new data is written, data blocks are invalidated, or garbage collection operations are completed. The storage system controller 902 may recompute group sizes, regroup data blocks, and update selection decisions to adapt to changing workload conditions and storage system characteristics.

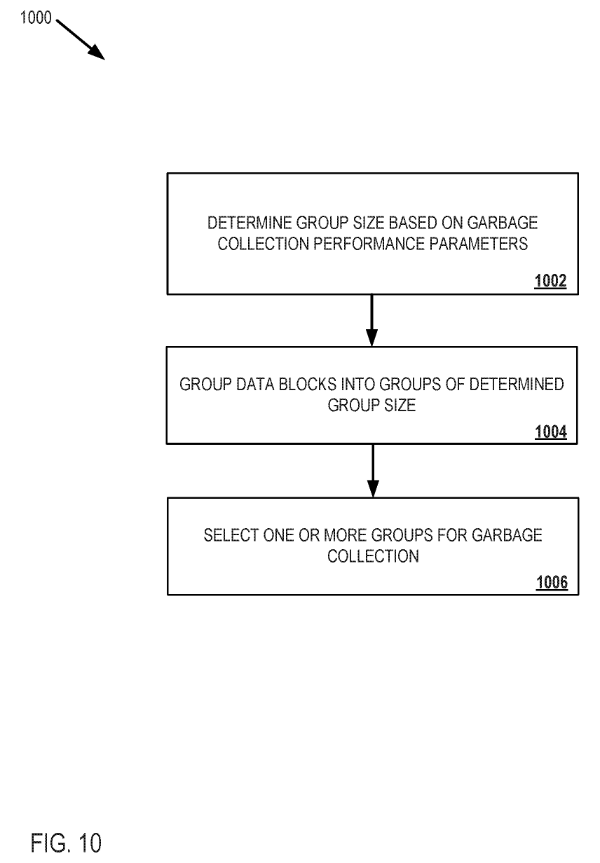

The storage system controller 902 may determine the group size by analyzing a combination of a distribution of valid data block counts and corresponding lifespans associated with the data blocks. For example, the group size determination component 904 may generate a histogram or distribution curve representing valid data block counts, such as, for example, occupancy levels, across data blocks stored on the storage devices 912a–912n while also maintaining lifespan-related metadata (e.g., age, invalidation likelihood, or predicted longevity) for those data blocks. The storage system controller 902 may analyze the histogram to identify structural characteristics such as gradients, inflection points, or clustering of low-occupancy regions, and correlate these regions with lifespan distributions (e.g., concentrations of short-lived or soon-to-be-invalid data). In some embodiments, adaptive tuning is performed by weighting portions of the histogram based on associated lifespan characteristics, such that regions dominated by shorter-lifespan or rapidly invalidating data blocks are emphasized in determining candidate group boundaries. The storage system controller 902 may further apply smoothing functions and compute localized rates of change in both occupancy and lifespan distributions to detect transition regions that separate high-reclaim-potential data from more stable data. Based on this joint analysis, the storage system controller 902 determines a group size that preferentially includes data blocks exhibiting both low valid data block counts and shorter expected lifespans, while excluding data blocks beyond identified transition thresholds. In this manner, grouping decisions are adaptively tuned using both occupancy-based statistical structure and temporal lifespan behavior, thereby improving expected reclamation efficiency when the garbage collection selection component 908 selects groups for garbage collection, as described in detail in the method 1000 described by FIG. 10.

By dynamically grouping data blocks based on corresponding lifespans and adjusting grouping parameters based on garbage collection performance parameters and eviction patterns, the storage system provides improved garbage collection efficiency, reduced write amplification, and enhanced overall storage system performance. In some embodiments, the disclosed techniques enable the storage system to adapt to varying data characteristics and workload conditions without requiring static grouping strategies.

FIG. 10 is an example method 1000 for grouping data blocks and selecting groups for garbage collection in accordance with embodiments of the disclosure. In general, the method 1000 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a storage node of a storage system, as previously described, may perform the method 1000. In some example embodiments, the method 1000 may be performed by the storage system controller 902 operatively coupled to storage devices 912a-912n as described above with respect to FIG. 9.

The method 1000 begins by the processing logic identifying data blocks stored across one or more storage devices. In some embodiments, the data blocks may correspond to user data, metadata, parity data, or other stored information distributed across multiple memory regions, dies, or channels of the storage devices.

At block 1002, the processing logic determines a group size for grouping the data blocks. In some embodiments, the group size is determined based on one or more garbage collection performance parameters, including, for example, data block occupancy, reclaim efficiency, write amplification, latency, throughput, or device utilization. The group size may correspond to a number of data blocks selected as a batch for garbage collection.

At block 1004, the processing logic groups the data blocks into groups having the determined group size. In some embodiments, the processing logic groups the data blocks based on corresponding lifespans associated with the data blocks. The corresponding lifespans may be determined using metadata associated with the data blocks, including, for example, data block age or historical invalidation patterns. In some embodiments, the processing logic groups data blocks having similar lifespans into the same group to improve reclamation efficiency.

At block 1006, the processing logic selects one or more of the groups for garbage collection. In some embodiments, the processing logic evaluates characteristics of the groups, including data block occupancy or proportion of invalid data, and prioritizes groups having lower data block occupancy in comparison to groups having higher data block occupancy. Selection of groups for garbage collection may be performed periodically, in response to threshold conditions, or as part of a background maintenance process.

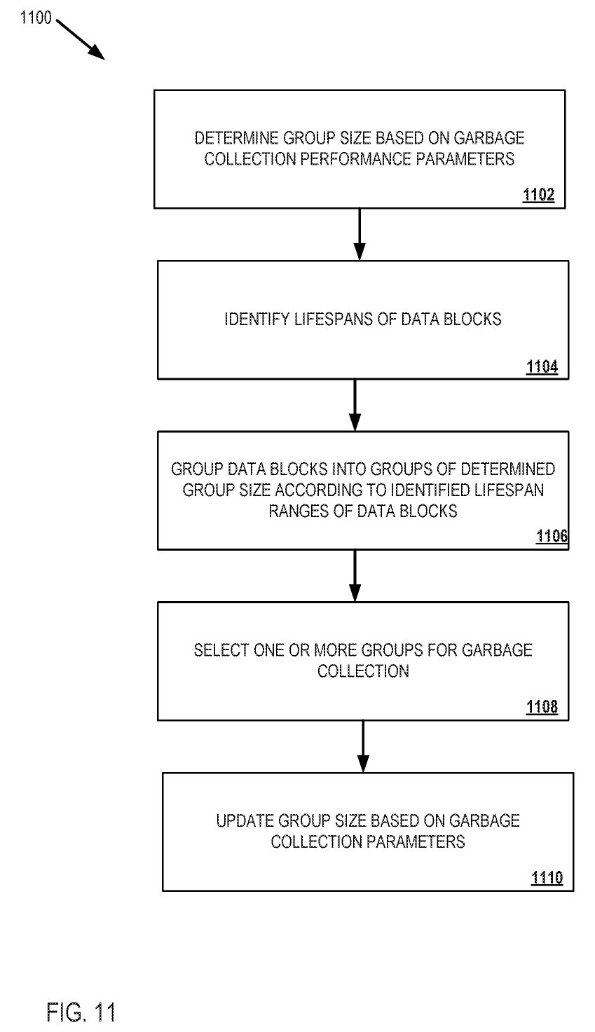

FIG. 11 is an example method 1100 for adaptively grouping data blocks for garbage collection in accordance with embodiments of the disclosure. The method 1100 may be performed by processing logic similar to that described above with respect to method 1000. In some embodiments, processing logic of a storage node of a storage system, as previously described, may perform the method 1100. In some example embodiments, the method 1100 may be performed by the storage system controller 902 operatively coupled to storage devices 912a-912n as described above with respect to FIG. 9.

The method 1100 begins by the processing logic identifying data blocks and determining corresponding lifespans associated with the data blocks. In some embodiments, the lifespans are based on corresponding ages of the data blocks or other metadata indicative of expected data longevity.

At block 1102, the processing logic determines a group size based on one or more garbage collection performance parameters. At block 1104, the processing logic assigns different lifespan ranges to respective groups. In some embodiments, the lifespan ranges correspond to classifications of data blocks based on expected invalidation times or update frequency.

At block 1106, the processing logic groups the data blocks into groups such that corresponding lifespans of the data blocks fall within the assigned lifespan ranges. In some embodiments, the processing logic groups a set of data blocks into a particular group when corresponding lifespans of the set of data blocks are within the corresponding lifespan range of the particular group.

At block 1108, the processing logic adjusts the group size based on an eviction pattern corresponding to prior garbage collection cycles. In some embodiments, the eviction pattern includes patterns of invalidation, reclamation efficiency, or performance characteristics observed during prior garbage collection operations. The processing logic may increase or decrease the group size based on the observed eviction pattern to improve subsequent garbage collection performance.

At block 1110, the processing logic selects one or more groups for garbage collection based on the grouping and adjusted group size. In some embodiments, the processing logic continues to monitor system conditions and dynamically update grouping decisions, group size, and selection criteria as new data is written, data blocks are invalidated, or garbage collection operations are completed.

In some embodiments, the methods 1000 and 1100 may be performed iteratively or continuously as part of a garbage collection management loop within the storage system. By dynamically grouping data blocks based on corresponding lifespans and adjusting grouping parameters based on garbage collection performance parameters and eviction patterns, the disclosed methods improve garbage collection efficiency, reduce write amplification, and enhance overall storage system performance.

One or more embodiments may be described herein with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

While particular combinations of various functions and features of the one or more embodiments are expressly described herein, other combinations of these features and functions are likewise possible. The present disclosure is not limited by the particular examples disclosed herein and expressly incorporates these other combinations.

What is claimed is:

1. A storage system comprising:
a plurality of storage devices; and
a storage system controller, operatively coupled to the plurality of storage devices, configured to:
determine a group size for grouping a plurality of data blocks stored on the plurality of storage devices, the group size based on one or more garbage collection performance parameters;
group the plurality of data blocks into a plurality of groups having the determined group size based on corresponding lifespans associated with the plurality of data blocks; and
select one or more of the plurality of groups for garbage collection.

2. The storage system of claim 1, wherein the corresponding lifespans are based on corresponding ages of the plurality of data blocks.

3. The storage system of claim 1, wherein groups the plurality of groups are assigned different corresponding lifespan ranges and wherein grouping the plurality of data blocks comprises:
grouping a set of data blocks of the plurality of data blocks into a particular group of the plurality of groups, wherein the corresponding lifespans of the set of data blocks are within the corresponding lifespan range of the particular group.

4. The storage system of claim 1, wherein the one or more garbage collection performance parameters comprises data block occupancy.

5. The storage system of claim 4, wherein the storage system controller is further configured to prioritize grouping, for garbage collection, data blocks having a lower data block occupancy in comparison to data blocks having a higher data block occupancy.

6. The storage system of claim 1, wherein the group size corresponds to a number of data blocks selected as a batch for the garbage collection.

7. The storage system of claim 1, wherein the storage system controller is further configured to:
adjust the group size based on an eviction pattern corresponding to prior garbage collection cycles.

8. A method comprising:
determining, by a storage system controller, a group size for grouping a plurality of data blocks stored on the plurality of storage devices, the group size based on one or more garbage collection performance parameters;
grouping the plurality of data blocks into a plurality of groups having the determined group size based on corresponding lifespans associated with the plurality of data blocks; and
selecting one or more of the plurality of groups for garbage collection.

9. The method of claim 8, wherein the corresponding lifespans are based on corresponding ages of the plurality of data blocks.

10. The method of claim 8, wherein groups the plurality of groups are assigned different corresponding lifespan ranges and wherein grouping the plurality of data blocks comprises:
grouping a set of data blocks of the plurality of data blocks into a particular group of the plurality of groups, wherein the corresponding lifespans of the set of data blocks are within the corresponding lifespan range of the particular group.

11. The method of claim 8, wherein the one or more garbage collection performance parameters comprises data block occupancy.

12. The method of claim 11, further comprising:
prioritizing grouping, for garbage collection, data blocks having a lower data block occupancy in comparison to data blocks having a higher data block occupancy.

13. The method of claim 8, wherein the group size corresponds to a number of data blocks selected as a batch for the garbage collection.

14. The method of claim 8, further comprising:
adjusting the group size based on an eviction pattern corresponding to prior garbage collection cycles.

15. A non-transitory computer readable storage medium storing instructions that, when executed, cause a storage system controller to:
determine a group size for grouping a plurality of data blocks stored on the plurality of storage devices, the group size based on one or more garbage collection performance parameters;
group the plurality of data blocks into a plurality of groups having the determined group size based on corresponding lifespans associated with the plurality of data blocks; and
select one or more of the plurality of groups for garbage collection.

16. The non-transitory computer readable storage medium of claim 15, wherein the corresponding lifespans are based on corresponding ages of the plurality of data blocks.

17. The non-transitory computer readable storage medium of claim 15, wherein groups the plurality of groups are assigned different corresponding lifespan ranges and wherein grouping the plurality of data blocks comprises:
grouping a set of data blocks of the plurality of data blocks into a particular group of the plurality of groups, wherein the corresponding lifespans of the set of data blocks are within the corresponding lifespan range of the particular group.

18. The non-transitory computer readable storage medium of claim 15, wherein the one or more garbage collection performance parameters comprises data block occupancy.

19. The non-transitory computer readable storage medium of claim 18, wherein the storage system controller is further configured to prioritize grouping, for garbage collection, data blocks having a lower data block occupancy in comparison to data blocks having a higher data block occupancy.

20. The non-transitory computer readable storage medium of claim 15, wherein the group size corresponds to a number of data blocks selected as a batch for the garbage collection.
